(19) United States
(12) Patent Application Publication
(10) Pub. No.: US 2026/0255634 A1
(43) Pub. Date: Aug. 27, 2026

(54) METAL OXIDE ELECTRONIC DEVICE AND ITS FABRICATING METHOD

(71) Applicant: City University of Hong Kong, Kowloon (HK)

(72) Inventors: Dangyuan Lei, Kowloon (HK); Xinge Yu, Kowloon (HK); Zhan Gao, Kowloon (HK); Yang Fu, Kowloon (HK)

(21) Appl. No.: 19/448,364

(22) Filed: Jan. 14, 2026

Related U.S. Application Data
(60) Provisional application No. 63/763,359, filed on Feb. 26, 2025.

(51) Int. Cl. H10D 30/67; H10D 30/01; H10P 14/20; H10P 14/40; H10P 14/60; H10P 14/692

(52) U.S. Cl. CPC H10D 30/6756; H10D 30/6739; H10P 14/203; H10P 14/3434; H10P 14/418; H10P 14/6319; H10P 14/69391; H10D 30/0314

(57) ABSTRACT

A method for fabricating a metal oxide (MO) thin film for an electronic device includes providing a plasmonic material on a metal oxide (MO) precursor film, and illuminating the plasmonic material with a laser source to convert the underlying MO precursor film to an MO film.

### TECHNICAL FIELD

The present invention relates to electronic devices including metal oxide (MO) thin films and their fabricating methods.

### BACKGROUND

Metal oxide (MO) thin films are a promising alternative to silicon for next-generation electronics¹⁻³. Their high mobility, transparency, uniformity, and flexibility enable applications in displays², biosensors⁴, solar cells⁵ and logic circuits⁶. Unlike silicon electronics using capital-intensive vacuum-based technologies, the solution processability of MO thin films offers great possibilities in high-throughput, low-cost and large-scale printing⁷. However, the challenge of printing high-quality MO lies in the requirement of prolonged high-temperature annealing at >400° C., which is not suitable for efficient, continuous additive manufacture^{7, 8}. This also hinders patterning MO into high-channel-count transistor arrays¹.

To lower the processing temperature, various materials synthesis and processing methods such as combustion synthesis, alkoxide precursors and photoactivation process were developed⁸⁻¹⁷. Despite important technical progress, grand challenges remain. For example, thermal annealing at >200° C. is still needed with long periods of multiple processing steps, and no standardized method exists for producing high-quality, solution-processed MO thin-films under room temperature and ambient conditions³. Moreover, existing printing techniques cannot offer high-throughput, high-resolution processes for high-performance all-MO devices^{7, 18, 19}. A recently developed promising method allows processing Ga-based liquid metal into large-area, flexible conductive GaOₓ films under ambient conditions. While it can print various MO films, such as GaOₓ, alumina (AlOₓ) and indium oxide (InOₓ), this approach seems challenging, since Ga-based liquid metals lack key precursors²⁰.

### SUMMARY OF THE INVENTION

Solution-processed metal oxide (MO) thin-film transistors present significant promise for next generation large-area, low-cost electronics. However, challenges like prolonged high-temperature annealing (>400° C.) and a lack of universal, high-resolution printing technology hinder their widespread applications. Here some embodiments of the invention report a processing technology, termed ‘plasmonic printing’, for fabricating high-performance, solution-processed all-MO thin-film electronics under room temperature and ambient conditions. This process leverages femtosecond-laser-excited silver nanowires to induce plasmonic local heating, facilitating rapid (<0.3 s) and localized conversion of MO precursors into high-quality MO thin films, including conductor, dielectric and semiconductor. Remarkably, these MO thin films exhibit superior performance without the requirement of special gases or high-temperature treatment, thereby enhancing the fabrication efficiency. Furthermore, precise pattern control is demonstrated, enabling the fabrication of high-density solution-processed all-MO transistor arrays (48,400 transistors per square centimetre) and integrated logic gates with uniformity and precision. This technology presents a promising pathway for the cost-effective and high-throughput printing of high-density, complex, multilayered solution-processed MO electronics, delivering performance on par with vacuum-based counterparts.

According to a first aspect of the invention, there is provided a method for fabricating a metal oxide (MO) thin film for an electronic device, which includes the steps of providing a plasmonic material on a metal oxide (MO) precursor film, and illuminating the plasmonic material with a laser source to convert the underlying MO precursor film to an MO film.

In some embodiments, the plasmonic material may include plasmonic nanostructures, preferably silver nanostructures, or more preferably silver nanowires.

In some embodiments, the MO film may include a conductor, an insulator or a semiconductor.

In some embodiments, the MO film may include indium tin oxide (ITO), alumina (AlOₓ), indium-gallium-zinc oxide (IGZO), indium-zinc oxide (IZO), or indium oxide (InOₓ).

In some embodiments, the step of illuminating the plasmonic material may be conducted under room temperature and ambient conditions.

In some embodiments, the laser source may include a femtosecond (fs) laser.

In some embodiments, the laser source may provide a mixed laser beam.

In some embodiments, the mixed laser beam may include 800 nm+400 nm fs laser beam.

In some embodiments, the step of illuminating the plasmonic material may include manipulating size and displacement of laser spot to control size and shape of the MO film.

In some embodiments, the step of providing the plasmonic material on the MO precursor film may be conducted by spray coating.

In some embodiments, the method may further include, before the step of providing the plasmonic material on the MO precursor film, patterning the MO precursor film.

In some embodiments, the method may further include, before the step of illuminating the plasmonic material, patterning the plasmonic material to manipulate pattern of the MO film.

In some embodiments, electrical performance of the MO film may be adjusted based on one or more of laser source type, wavelength of the laser source, intensity of the laser source, laser scanning step length, spot dwell time per step, and/or thickness of the plasmonic material.

In some embodiments, the electrical performance of the MO film may include conductivity, dielectric property, or semiconducting performance.

According to a second aspect of the invention, there is provided an electronic device, which includes one or more thin films of a metal oxide (MO) fabricated by the method of the first aspect.

In some embodiments, the electronic device may include an MO thin film transistor (TFT).

According to a third aspect of the invention, there is provided a method for fabricating metal oxide (MO) thin film transistor (TFT) arrays, which includes (a) fabricating indium tin oxide (ITO) gate array, (b) fabricating dielectric layers of alumina (AlOₓ), and (c) fabricating semiconductor layers of indium-gallium-zinc oxide (IGZO) to provide IGZO based TFTs. Each step (a), (b) and/or (c) is conducted by the method of the first aspect.

Other features and aspects of the invention will become apparent by consideration of the detailed description and accompanying drawings. Any feature(s) described herein in relation to one aspect or embodiment may be combined with any other feature(s) described herein in relation to any other aspect or embodiment as appropriate and applicable.

### BRIEF DESCRIPTION OF DRAWINGS

Embodiments of the invention will now be described, by way of example, with reference to the accompanying drawings in which:

FIGS. 1a-1h show plasmonic printing of solution-processed MO thin-film electronics according to an embodiment of the invention.

FIG. 1a is a schematic illustration of the plasmonic printing process. Ultrafast, high-quality, localized MO conversion can be rapidly achieved under room temperature and ambient condition, through the plasmon excitation of Ag NWs by a mixed fs laser beam to generate local heat for activating the formation of MO. After printing, excess Ag NWs can be physically wiped away, whereas the unconverted precursor can be etched away by 3% w/v oxalic acid (OA). A printed transistor structure with a bottom gate and a top contact is illustrated in the bottom-right corner.

FIG. 1b is a schematic of the chemical bonds within the illuminated area and unilluminated area of the MO thin film. M, metal cation; O, oxygen; H, hydrogen; R, alkyl group.

FIG. 1c is a diagram of a four-inch wafer-scale transparent MO array fabricated by the plasmonic printing process. Scale bar, 1 cm (inset).

FIG. 1d shows the plasmonic printing approach for MO thin films according to an embodiment of the invention.

FIG. 1e shows a conventional fabrication method of MO thin films.

FIG. 1f shows Radar comparison of the plasmonic printing process and three representative low-temperature solution processes for MO in terms of low-temperature processing, efficiency (time to achieve complete MO condensation), performance (conductivity, dielectric constant and mobility), printability (capability of pattern control of MO), universality (applicability across a wide range of MOs) and environment (processing atmosphere: the maximum value represents ambient conditions).

FIG. 1g shows O1s XPS results of 40° C.-annealed ITO (M-O-M lattice, 530.1 eV; M-OH metal hydroxide, 531.1 eV; M-OR bonds, 532.1 eV).

FIG. 1h shows O1s XPS results of plasmonically printed ITO (M-O-M lattice, 530.1 eV; M-OH metal hydroxide, 531.1 eV; M-OR bonds, 532.1 eV).

FIG. 2a shows temporal temperature and IR photographs of Ag NWs under fs laser irradiation captured by a thermal imaging camera.

FIGS. 2b-2e are SEM micrographs showing the morphology evolution of Ag NWs, from a pristine network structure before light illumination (FIG. 2b) to the hierarchical Ag particles after laser illumination for 0.1 s (FIG. 2c), 1 s (FIG. 2d) and 10 s (FIG. 2e).

FIGS. 2f-2i show simulated light absorption intensity (top) and corresponding heat generation (bottom) for the structures in FIGS. 2b-2e, respectively.

FIG. 2j shows calculated local temperature rise for a single Ag particle with varied sizes and shapes.

FIG. 2k shows estimated collective local-temperature rise for an array of Ag particles with varied sizes and periods.

FIG. 2l shows estimated collective local-temperature rise for an array of Ag particles with varied sizes and particle density.

FIGS. 3a-3l show plasmonically printed MO thin-film devices according to an embodiment of the invention.

FIG. 3a shows a diagram of a thin film of Ag NWs (on an ITO precursor film) after ‘CITYU’-patterned laser illumination (Top), and a diagram showing that the same pattern is grafted onto the ITO precursor film through plasmonic printing to produce the printed ITO channel by laser scanning (Bottom).

FIG. 3b shows conductivity of the plasmonically printed ITO under different light-spot dwell times. Individual data points (n=5 per group) are overlaid to show the data distribution. Each point represents an independent ITO channel. Bar height, mean; error bars, standard deviation.

FIG. 3c shows optical surface profiles of the plasmonically printed ITO channels under varied light-spot dwell times.

FIG. 3d shows J-E characteristics of a plasmonically printed AlOₓ under different light illumination intensities.

FIG. 3e shows C-V characteristics of a plasmonically printed AlOₓ under different light illumination intensities.

FIG. 3f shows C-F characteristics of a plasmonically printed AlOₓ under different light illumination intensities.

FIG. 3g shows transfer characteristics (V_{ds}=8 V) and output characteristics of transistors based on plasmonically printed IGZO channels, with its device configuration shown in the inset.

FIG. 3h shows transfer characteristics (V_{ds}=8 V) and output characteristics of transistors based on plasmonically printed IZO channels, with its device configuration shown in the inset.

FIG. 3i shows transfer characteristics (V_{ds}=8 V) and output characteristics of transistors based on plasmonically printed InOₓ channels, with its device configuration shown in the inset.

FIG. 3j shows comparison of the conductivity of ITO between the proposed plasmonically printed samples and previously reported vacuum-based lowtemperature-processed MO as a function of the processing temperature.

FIG. 3k shows comparison of the dielectric constant of AlOₓ between the proposed plasmonically printed samples and previously reported vacuum-based lowtemperature-processed MO as a function of the processing temperature.

FIG. 3l shows comparison of the saturation mobility of IGZO between the proposed plasmonically printed samples and previously reported vacuum-based lowtemperature-processed MO as a function of the processing temperature. Note that all the mobility values are derived from IGZO transistors with AlOₓ as the dielectric layer.

FIG. 4a shows plasmonically printed all-MO transistor arrays according to an embodiment of the invention, in particular, a diagram of a plasmonically printed ITO gate/AlOₓ dielectric/IGZO semiconductor transistor in a 10×10 array.

FIG. 4b shows resistance values of the plasmonically printed 10×10 ITO gates, which were measured at the diagonal positions of each ITO square with a two-probe method. Resistance value is presented as mean±standard deviation.

FIG. 4c shows C-F characteristics of the plasmonically printed 10×10 AlOₓ dielectrics, with the solid line representing a typical measurement curve. The capacitance value is presented as mean±standard deviation.

FIG. 4d shows C-V characteristics of the plasmonically printed 10×10 AlOₓ dielectrics, with the solid line representing a typical measurement curve. The capacitance value is presented as mean±standard deviation.

FIG. 4e shows transfer characteristics of the plasmonically printed 10×10 all-MO transistors, with the solid line representing a typical measurement curve. Saturation mobility is presented as mean±standard deviation.

FIG. 4f shows statistical distributions of resistance of the 10×10 plasmonically printed all-MO transistor array.

FIG. 4g shows statistical distributions of dielectric constant of the 10×10 plasmonically printed all-MO transistor array.

FIG. 4h shows statistical distributions of mobility of the 10×10 plasmonically printed all-MO transistor array.

FIG. 4i is a photograph of the plasmonically printed high-density all-MO transistor array.

FIG. 4j is an enlarged microscopy photograph of the plasmonically printed high-density all-MO transistor array of FIG. 4i.

FIG. 4k is an enlarged microscopy photograph of FIG. 4j.

FIG. 4l shows representative transfer curve of a transistor in the high-density all-MO transistor array.

FIG. 4m and FIG. 4n show optical surface profile of the plasmonically printed high-density ITO gates.

FIG. 4o shows height profile of the high-density ITO gates obtained from the optical surface profile in FIG. 4m. Thickness values are presented as mean±standard deviation.

FIG. 4p shows height profile of the high-density ITO gates obtained from the optical surface profile in FIG. 4m with an enlarged view. Rms values are presented as mean±standard deviation.

FIG. 5a shows plasmonically printed logic gates based on the all-MO transistors according to an embodiment of the invention, in particular, a circuit diagram and microscope photograph of a plasmonically printed inverter.

FIG. 5b shows curves of the output voltage versus input voltage of the inverter device at various VDD levels (6~12 V).

FIG. 5c shows gain curves of the inverter device at various VDD levels (6~12 V).

FIG. 5d shows circuit diagram and microscope image of a plasmonically printed NAND gate.

FIG. 5e shows output characteristics of the plasmonically printed NAND gate. Each input sequence lasts for 60 s. Logic ‘0’ and logic ‘1’ are represented by 0 V and 10 V, respectively, which is the same for the subsequent logic devices.

FIG. 5f shows circuit diagram and microscope photograph of a plasmonically printed NOR gate.

FIG. 5g shows output characteristics of the plasmonically printed NOR gate.

FIG. 5h shows microscope image of a plasmonically printed half-adder.

FIG. 5i shows output characteristics of the plasmonically printed half-adder.

FIG. 6a is a schematic illustration of the optical setup for the plasmonic printing.

FIG. 6b shows three plasmonic printing process flows. ‘M-OH’ represents the unconverted precursor film of MO, while ‘M-O’ represents the converted MO. The remaining Ag nanostructures in each flow are physically wiped off, and the remaining precursor film is removed by soaking in 3% w/v OA.

FIG. 7a shows electric field simulation for two intersecting Ag NWs, in particular, structure, coordinate, and incident light built in the simulation.

FIG. 7b and FIG. 7c show electric field distribution profiles in the x-z and x-y planes for structures with varied angle of intersection.

FIG. 8a shows electric field simulation for Ag NWs with side dumbbells, in particular, structure, coordinate, and incident light built in the simulation.

FIG. 8b shows electric field distributions in the x-y plane for structures with varied length and side-dumbbell radius.

FIG. 9a shows O(1s) XPS results of plasmonically printed MOs (InOₓ).

FIG. 9b shows O(1s) XPS results of plasmonically printed MOs (IGZO).

FIG. 9c shows O(1s) XPS results of plasmonically printed MOs (AlOx)

FIG. 9d shows O(1s) XPS results of plasmonically printed MOs (IZO).

FIG. 10a shows GIAXRD results for 150° C. annealed, 400° C. annealed and plasmonically printed MOs (ITO).

FIG. 10b shows GIAXRD results for 150° C. annealed, 400° C. annealed and plasmonically printed MOs (AlOx).

FIG. 10c shows GIAXRD results for 150° C. annealed, 400° C. annealed and plasmonically printed MOs (IGZO).

FIG. 10d shows GIAXRD results for 150° C. annealed, 400° C. annealed and plasmonically printed MOs (InOx).

FIG. 10e shows GIAXRD results for 150° C. annealed, 400° C. annealed and plasmonically printed MOs (IZO).

FIG. 11a shows scanning parameter optimization of the plasmonic printing process. Resistance (R) of an ITO film after laser irradiation (at 800 nm and 400+800 nm) under different light intensities for 1 min.

FIG. 11b shows scanning parameter optimization of the plasmonic printing process. Resistance (R) of an ITO film after laser irradiation (at 800 nm and 400+800 nm) under different light intensities for 5 min.

FIG. 11c shows R/Rₒ ratios extracted from FIG. 11a and FIG. 11b, with Rₒ denoting the resistance of the ITO film before laser irradiation. Individual data points (n=5 per group) are overlaid to show data distribution. Each point represents an independent ITO channel. Bar height, mean; error bars, standard deviation.

FIG. 11d shows absorption spectra of Ag NW thin films at different thicknesses (controlled by the volume of Ag NW solution).

FIG. 11e shows conductivity of a plasmonically printed ITO at varied fs laser wavelength.

FIG. 11f shows output power of the fs laser at different wavelengths.

FIG. 11g shows microscope photographs and measured conductivity of plasmonically printed ITO channels using different light intensities. The beam-scanning step length in this experiment is 10 μm.

FIG. 11h shows conductivity of the plasmonically printed ITO channels using different beam-scanning step lengths.

FIG. 11i shows conductivity of the plasmonically printed ITO channels of different thicknesses (controlled by the volume of Ag NW solution) using different light intensities. Data in FIGS. 11e, 11h and 11i, are measured from 5 independent ITO channels per group. Bar height, mean; point, mean; error bars, standard deviation. (n=5).

FIG. 11j shows conductivity of the plasmonically printed ITO channels measured at varied test distance.

FIGS. 12a-12g show comparison on heating process and printed ITO performance between fs and CW lasers.

FIG. 12a shows temporal temperature evolution during the plasmonic printing process by fs laser with varied power intensity.

FIG. 12b shows temporal temperature evolution during the plasmonic printing process by CW laser with varied power intensity.

FIG. 12c shows data collected right before and after laser illumination from FIG. 12a.

FIG. 12d shows data collected right before and after laser illumination from FIG. 12b.

FIG. 12e shows temperature distribution of the printed area after 0.1 s illumination by fs laser (left) and CW laser (right) with varied power intensity.

FIG. 12f shows schematics of the plasmonic printing optical setup using fs and CW lasers. The two laser beams are focused to the same size at the sample surface for direct comparison.

FIG. 12g shows resistance of printed solution-processed ITO films under fs and CW lasers with varied light intensity. Data are measured from 5 independent ITO channels per group. Point, mean; error bars, standard deviation.

FIG. 13a shows microscope photographs of a plasmonically printed high-density AlOₓ array.

FIG. 13b shows optical surface profile of the plasmonically printed high-density AlOₓ array.

FIG. 13c shows the optical surface profile of a single unit in the array.

FIG. 13d shows extracted height profile of the plasmonically printed high-density AlOₓ array.

FIG. 13e shows the height profile of a single unit in the array.

FIGS. 13f-13j show similar results as FIGS. 13a-13e for a plasmonically printed high-density IGZO array.

FIG. 14a shows thickness of Ag NW film of different volume per square centimeter sprayed (20 μL/cm²).

FIG. 14b shows thickness of Ag NW film of different volume per square centimeter sprayed (35 μL/cm²).

FIG. 14c shows thickness of Ag NW film of different volume per square centimeter sprayed (50 μL/cm²).

FIG. 14d shows thickness of Ag NW film of different volume per square centimeter sprayed (70 μL/cm²).

FIG. 15 shows diagrams of the complete erasure of Ag NW film and the precursor film.

FIG. 16a shows ToF-SIMS ion mappings of Ag+ of the plasmonically printed ITO sample.

FIG. 16b shows ToF-SIMS ion mappings of In+ of the plasmonically printed ITO sample.

FIG. 16c shows ToF-SIMS ion mappings of Sn+ of the plasmonically printed ITO sample.

FIG. 16d shows ToF-SIMS ion mappings of total of the plasmonically printed ITO sample.

FIG. 17 shows ToF-SIMS spectrum of the plasmonically printed ITO sample.

FIG. 18 shows morphology evolution of Ag NWs under fs laser illumination. The top region is the original state of sprayed Ag NWs network and the bottom region is under the center of the femto-second laser spot. Clearly, the Ag NWs melt and split to nano-to-micro-particles mostly in spherical shape in the center of the laser spot and melt as non-regularly shaped micro-particles near the edge of laser spot. The farther from the laser spot, the less Ag NWs melt.

FIG. 19 shows morphology of fs laser irradiated region with different light intensity, a, and amounts of Ag NWs, b. Excessive power intensity will damage the substrate. The amount of Ag NW directly influences the plasmonic structure after illumination and corresponding heating process. Thus, moderate power intensity and amount of Ag NWs are selected for plasmonic printing.

FIG. 20 shows extended temperature profile of Ag NWs under fs laser irradiation in FIG. 2a.

FIG. 21a shows wide-scan XPS spectrum for the 40° C. dried precursor film.

FIG. 21b shows corresponding spectrum for the In 3d peaks for the 40° C. dried precursor film.

FIG. 21c shows wide-scan XPS spectrum for the plasmonically printed ITO film.

FIG. 21d shows corresponding spectra for the In 3d peaks for the plasmonically printed ITO film.

FIG. 21e shows corresponding spectra for Ag element for the plasmonically printed ITO film.

FIG. 22a wide-scan XPS spectrum for the plasmonically printed IGZO film.

FIG. 22b shows corresponding spectra for the Zn 2p peaks for the plasmonically printed IGZO film.

FIG. 22c shows corresponding spectra for the Ga 2p peaks for the plasmonically printed IGZO film.

FIG. 22d shows corresponding spectra for Ag element for the plasmonically printed IGZO film.

FIG. 23a wide-scan XPS spectrum for the plasmonically printed InOₓ film.

FIG. 23b shows corresponding spectra for the In 3d peaks for the plasmonically printed InOₓ film.

FIG. 23c shows corresponding spectra for Ag element for the plasmonically printed InOₓ film.

FIG. 24a shows wide-scan XPS spectrum for the plasmonically printed IZO film.

FIG. 24b shows corresponding spectra for the Zn 2p peaks for the plasmonically printed IZO film.

FIG. 24c shows corresponding spectra for Ag element for the plasmonically printed IZO film.

FIG. 25a shows wide-scan XPS spectrum for the plasmonically printed AlOₓ film.

FIG. 25b shows corresponding spectra for the Al 2p peak for the plasmonically printed AlOₓ film.

FIG. 25c shows corresponding spectra for Ag element for the plasmonically printed AlOₓ film.

FIG. 26 shows absorption spectra (300-600 nm) of ITO thin films at different annealing temperatures.

FIG. 27 shows schematic of the probe test positions in the pure light effect verification experiment. In this experiment, the ITO film was annealed at high temperature, so the resistance could be measured at any position on the film by placing test probes. However, due to the high transparency of the ITO film after high-temperature annealing (350° C.), it becomes difficult to find a valid probe testing position after the laser scanning. This is unlike the situation after the MO precursor is converted into the MO, where the traces are more apparent. Therefore, before using the laser to irradiate the ITO film, we mark the starting and ending points of the laser scanning path, so that after irradiation, we can find the precise probe location to measure the resistance of the ITO that has been laser-scanned.

FIG. 28 shows equivalent rectangular rod resistance model for ITO conductivity calculation. L represents the length of the ITO channel, W represents the width of the ITO channel, and T represents the thickness of the ITO channel. R is the resistance value measured by probes at both ends.

FIG. 29 shows comparison of the conductivity of ITO printed using 800+400 nm and 800 nm laser sources. Individual data points (n=5 per group) are overlaid to show data distribution. Each point represents an independent ITO channel. Bar height, mean; error bars, standard deviation.

FIG. 30 shows (a to c) Morphology of Ag NWs under different fs laser illumination duration. (d to f) Morphology of Ag NWs under different CW laser illumination duration.

FIG. 31 shows (a to c) Morphology of Ag NWs annealed on 150-250° C. hot plates. (d) Enlarged SEM view of Ag NWs annealed on 250° C. hot plates.

FIG. 32 shows optical images of broken glass substrate due to excessive plasmonic heating. The broken part shows no resistance value at all.

FIG. 33 shows SEM image of Ag NWs illuminated by a stationary laser spot, with dwell time=5 s (a) and 20 s (b). The scale bar in both images is 20 μm.

FIG. 34 shows height profile of plasmonically printed ITO channel under different light spot dwell time, (a) 0 s, (b) 1 s, (c) 5 s, (d) 10 s.

FIG. 35 shows schematic diagram of the spot path during the printing of a, AlOₓ and b, IGZO films. Note: The electrodes were fabricated after the plasmonic printing process was completed.

FIG. 36 shows dielectric performance tests of AlOₓ films with different laser path spacings D (25-150 μm). a-f, C-V characteristics, g-1, C-F characteristics.

FIG. 37 shows measurement of AlOₓ thickness.

FIG. 38 shows dielectric property measurement of high-temperature annealed AlOₓ. a to c, Capacitance-frequency curves of different thickness of AlOₓ. Inset shows the device structure. d to f, Capacitance-voltage curves of AlOₓ annealed at different temperature.

FIG. 39 shows transfer characteristics of plasmonically printed IGZO channel-based transistors under different light intensities.

FIG. 40 shows transfer characteristics of plasmonically printed IGZO channel-based transistors under laser paths spacing.

FIG. 41 shows transfer characteristics of conventional high-temperature processed IGZO-based transistor.

FIG. 42 shows stability measurement of plasmonically printed MOs. Normalized conductivity, capacitance and mobility of ITO, AlOₓ, IGZO a-c, after exposed to ambient and d-f, thermal cycling.

FIG. 43a shows comparison of mobility of IZO⁽¹⁶⁻²⁴⁾ with other reported low-temperature process and vacuum-based process of MO as a function of processing temperature.

FIG. 43b shows comparison of mobility of InOₓ^{(11, 25-34)} with other reported low-temperature process and vacuum-based process of MO as a function of processing temperature. Note, the mobility values are all derived from IZO, InOₓ transistors with AlOₓ as the dielectric layer.

FIG. 44 shows a, Photograph of a large-area spray-coated Ag NW film. b, Plasmonically printed ITO channels (each 2 cm in length) on a 4-inch glass substrate.

FIG. 45 shows measured thicknesses of the large-area spray-coated Ag NW film at randomly selected 30 locations. The measured height profiles were smoothed to facilitate the determination of thickness values. Thickness value is presented as mean±standard deviation.

FIG. 46 shows distribution of conductivity measured along 15 plasmonically printed 2 cm-long ITO conductive channels, based on 150 resistance measurements taken at 200 μm intervals. Individual data points (n=15 per group) are overlaid to show data distribution. Each point represents an independent ITO channel. Box plots show the median (center line), the 25th and 75th percentiles (box bounds), and the minimum and maximum values (whiskers).

FIG. 47 shows schematic diagram of the fabrication flow of the plasmonically printed MO transistor array.

FIG. 48 shows (a, b) pre-patterned Ag NWs on ITO precursor film. (c, d) after plasmonic printing process and immersion of 3% w/v OA, patterned ITO array is formed. (e) the corresponding resistance distribution of the ITO array.

FIG. 49 shows the variation in ITO resistance printed by different light intensities before and after immersion in 3% w/v OA.

FIG. 50 shows (a, b) pre-patterned Ag NWs on ITO and AlOₓ precursor films. (c, d) after plasmonic printing process, patterned ITO and AlOₓ arrays are formed.

FIG. 51 shows impact of laser spot size and scanning parameters on the patterning resolution. a, Schematic illustration of the light intensity distribution of the laser spot along its diameter. b, Schematics of the optical setup for demonstrating the interplay among the laser spot size, smallest feature size, and edge precision. c, Microscope photographs of plasmonically printed ITO films scanned at different positions in b. The linewidth/edge precision of the printed ITO region increases (decreases) with the laser spot size.

FIG. 52 shows SEM image of a plasmonically printed MO pattern by Process Flow 2, exhibiting a uniform edge across a long distance.

FIG. 53 shows optical surface profiles of a, commercially customized patterned ITO film (fabricated by sputtering process and patterned by laser etching technology), b, plasmonic printing patterned ITO film, along with the corresponding ITO surface roughness measurements in c and d.

FIG. 54 shows (a to c) plasmonically printed ITO, AlOₓ, ITO/AlOₓ/IGZO arrays. Scale bars are 1.5 mm. (d) optical image of plasmonically printed MO array. Scale bars are 0.3 mm.

FIG. 55 shows optical image of plasmonically printed all-MO transistor with source and drain electrodes.

FIG. 56 shows Ion/Loff distribution of the 10×10 plasmonically printed MO transistor array.

FIG. 57 shows (a, b) time domain response of the plasmonically printed inverter device with an input pulse of 8V at 1 kHZ. (c) a magnified view of voltage rise in b.

FIG. 58 shows diagrams of four substrates: soda lime glass, quartz glass, PI/soda lime glass, and silicon wafer. a, Original state, b, After spray-coating with Ag NW films, c, After plasmonic printing process.

FIG. 59 shows optical images of soda lime glass and quartz glass after plasmonic printing under different light intensities.

FIG. 60 shows optical images of PI after plasmonic printing under different light intensities.

FIG. 61 shows conductivity of plasmonically printed ITO channels with different pre-dried temperature. Individual data points (n=5 per group) are overlaid to show data distribution. Each point represents an independent ITO channel. Bar height, mean; error bars, standard deviation.

FIG. 62 shows capacitance-frequency characteristics of 350° C. annealed AlOₓ films and plasmonically printed AlOx films under quasi-static conditions.

FIG. 63 shows transfer characteristics of plasmonically printed a, IGZO, b, IZO, c, InOx channel-based transistors in linear regime (V_{ds}=1V).

Before any embodiments of the invention are explained in detail, it is to be understood that the invention is not limited in its application to the details of embodiment and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting.

### DETAILED DESCRIPTION

Hereinafter, some embodiments of the invention will be described in detail with reference to the drawings.

### Plasmonic Printing of High-Performance Metal Oxide Electronics Under Room Temperature

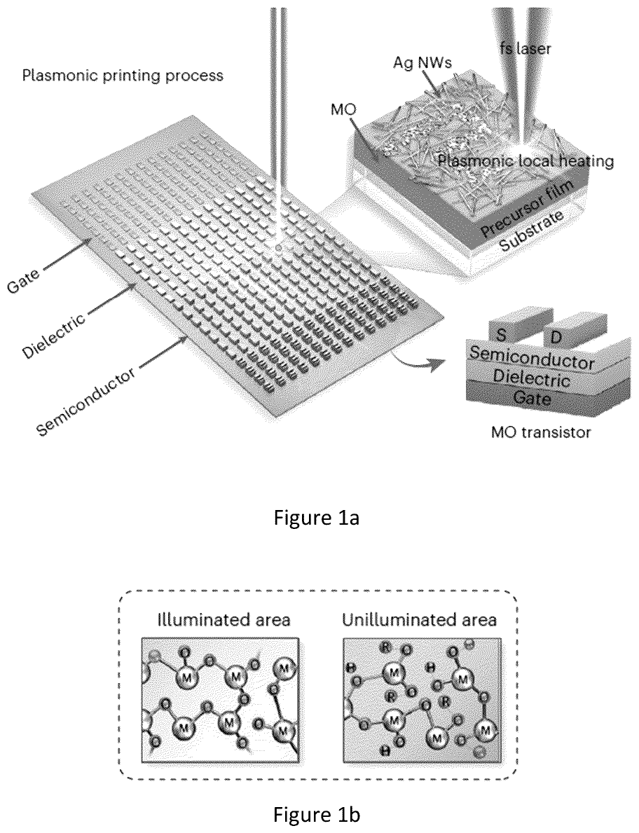

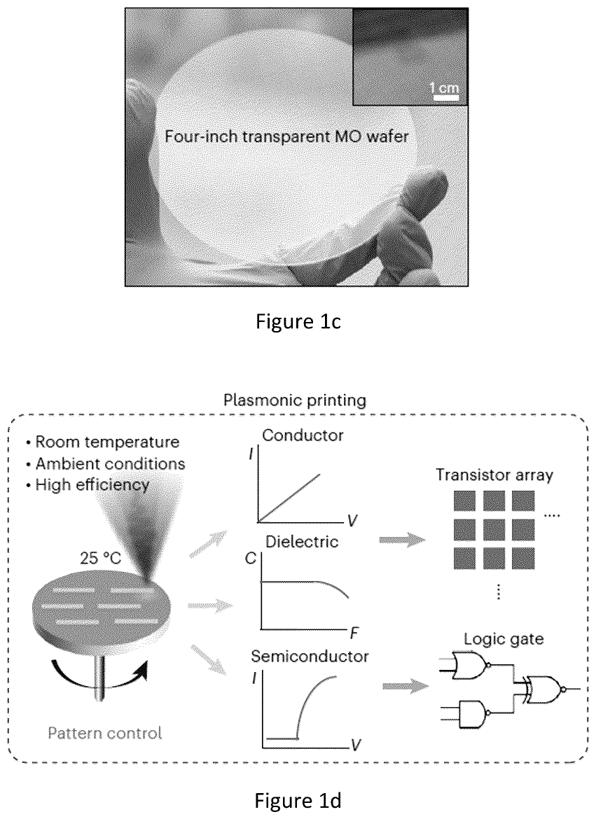

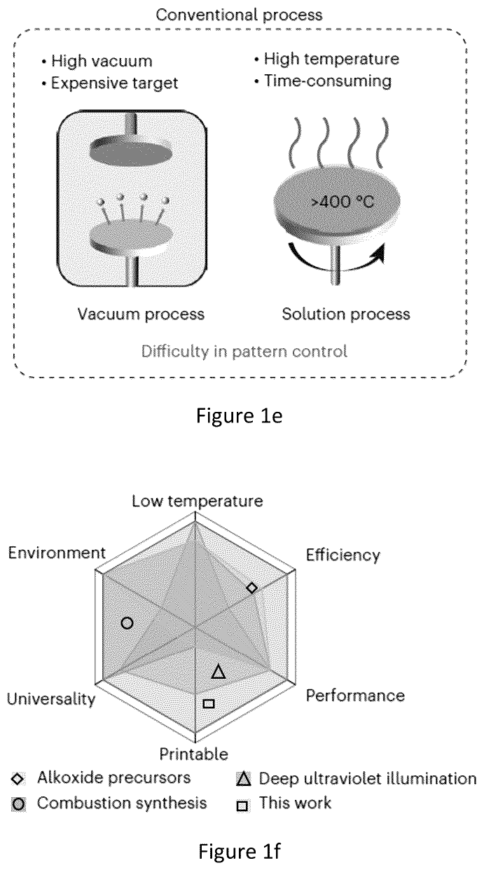

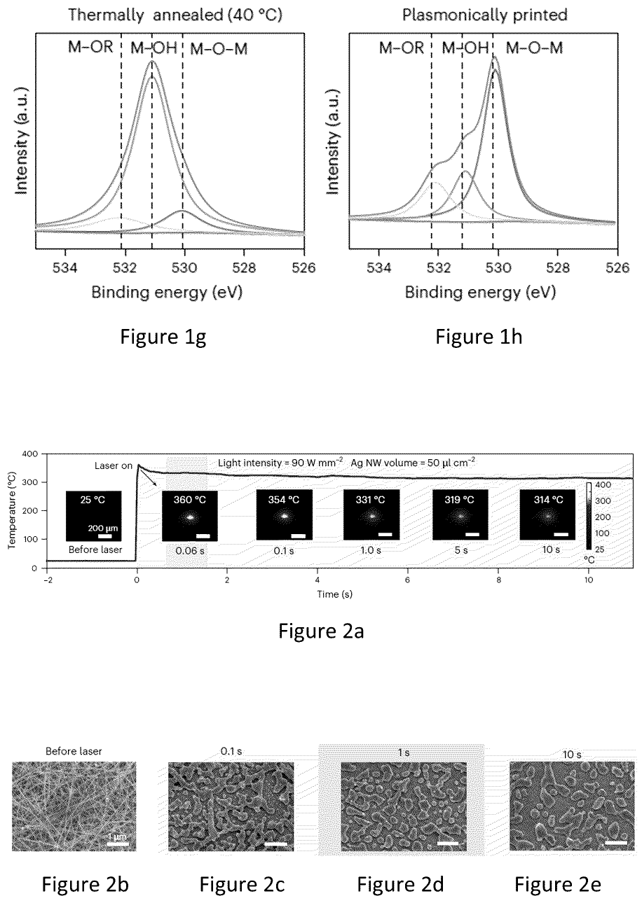

Some embodiments of the invention report a new and universal printing technology, termed ‘plasmonic printing’ (‘printing’ emphasizes the additive and constructive nature of this technique, associated with forming patterns by inks), to address all the long-standing challenges in printed MO thin-film electronics. It uses plasmon-induced local heating to serve as the MO-forming energy and enables the rapid patterning of high-quality MO thin films, including conductors, insulators and semiconductors, at room temperature and ambient conditions (FIG. 1a-c). A mixed (800 nm+400 nm) femtosecond (fs) laser beam serves as the writing source to illuminate silver nanowires (Ag NWs) for generating remarkable plasmonic local heating. Combining plasmonic local heating and ultraviolet-induced photochemical reactions selectively convert illuminated MO precursors into condensed thin films. Using a motorized stage ensures the uniform, precise printing of high-quality, solution-processed MO films. Compared with conventional and other low-temperature solution processes of MO, the plasmonic printing process offers three crucial advantages (FIG. 1d-f). First, it operates entirely at room temperature and ambient conditions, requiring no special gases or high-temperature treatments. Second, the MO precursor locally converts into high-quality films within ~0.3 s (FIG. 1g, h), substantially improving the fabrication efficiency compared with slow vacuum deposition or prolonged high-temperature annealing. Meanwhile, the resulting MO thin films exhibit electrical performance comparable with those produced by vacuum-based processes. Third, it supports three high-precision patterning flows. Taking advantage of this universal process, a uniform, high-density all-MO thin-film transistor (TFT) array (48,400 transistors per square centimetre) and various basic logic gates are demonstrated.

### Overview of the Plasmonic Printing Process

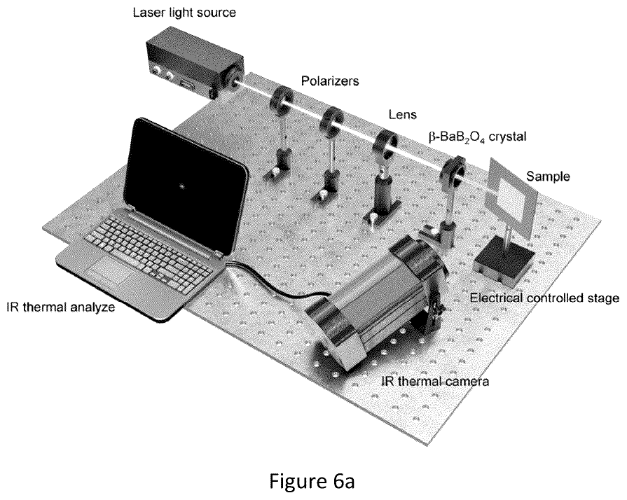

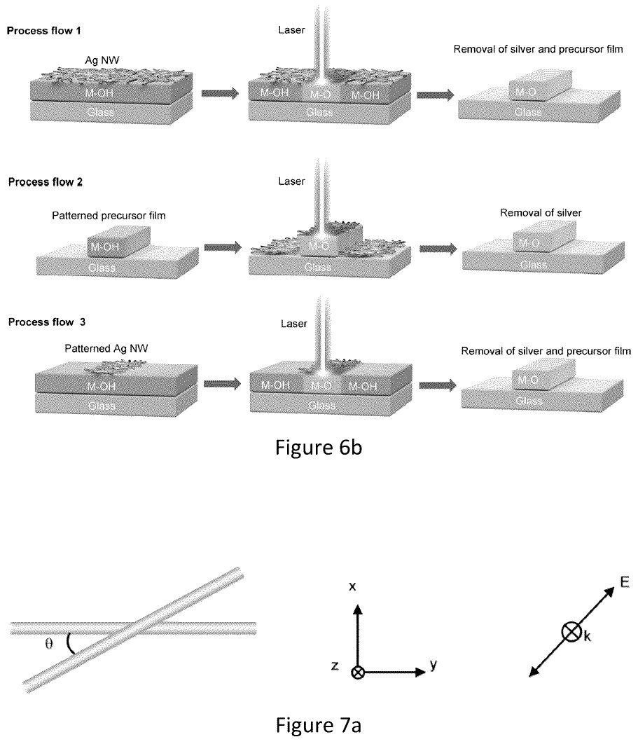

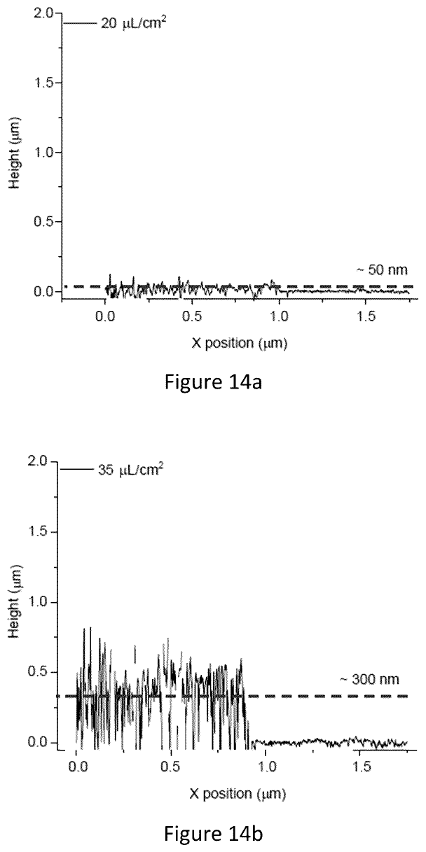

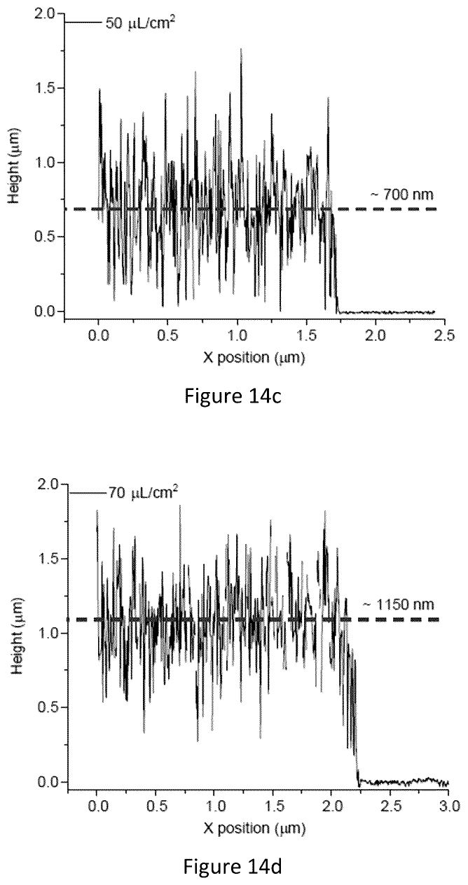

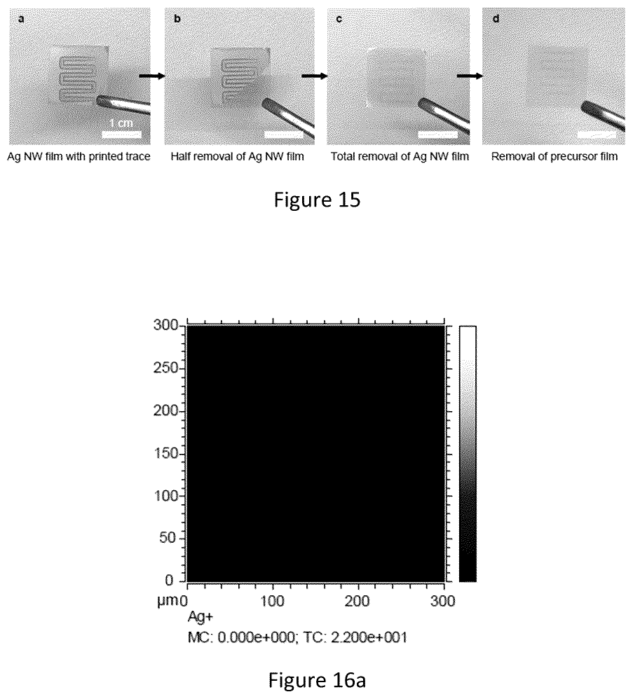

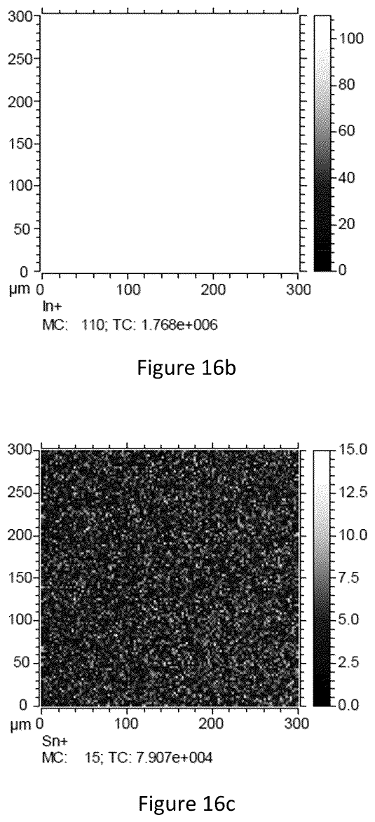

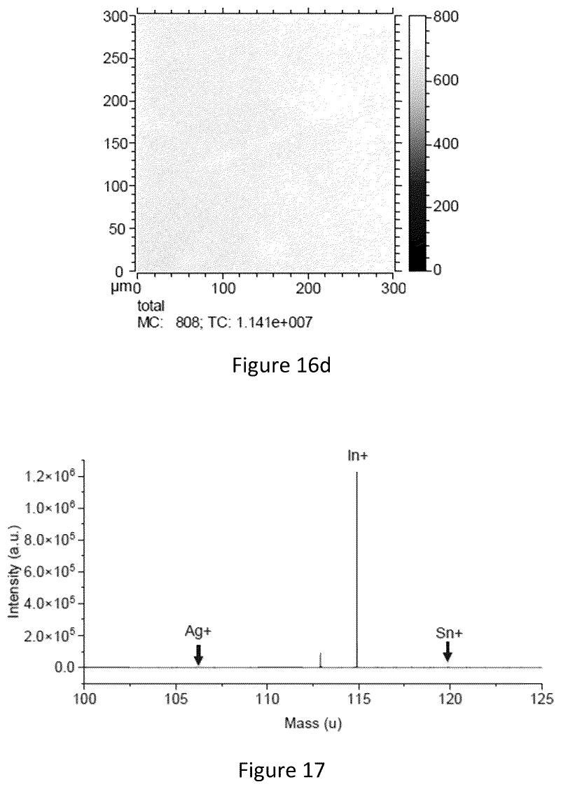

FIG. 6a shows the plasmonic printing setup. A polarized 800-nm fs laser beam is focused by a lens and converted into a mixed 800-nm+400-nm fs laser beam by a β-BaB₂O₄ crystal. This mixed beam is then directed onto a sample positioned by a motorized three-axis stage. Before printing, MO precursor films are prepared by conventional sol-gel processes without high-temperature annealing (Methods). Subsequently, an ~700-nm-thick film of Ag NWs (FIGS. 14a-14d) is spray-coated on the MO precursor film as the plasmonic local heat source. As shown in FIG. 6b, three different process flows enable MO conversion. Process flow 1 requires no patterning of either the precursor film or Ag NW film. Instead, the laser spot size and movement control the printed MO size and shape. Process flow 2 patterns the precursor film via photolithography in advance, yielding regular MO films with smooth edges. Conversely, process flow 3 controls Ag NW patterns to define the MO film shape. This process lays the groundwork for nanoscale MO printing using plasmonic nanostructures as heat sources. In all process flows, the unconverted precursor is removed by 3% w/v oxalic acid (OA), and Ag residues are wiped off (FIG. 15). Time-of-flight secondary ion mass spectrometry (TOF-SIMS) is used to confirm no Ag residues in an indium tin oxide (ITO) sample. Two-dimensional TOF-SIMS ion mappings (FIG. 16a-16d) show undetectable Ag⁺ and strong In⁺ and Sn⁺ signals. The TOF-SIMS mass spectrum (FIG. 17) further confirms that no Ag residues are detected in the plasmonically printed ITO film within the detection limit of TOF-SIMS. For multilayer devices, the process flows can be iterated on previously printed MO films.

### Morphology-Driven Plasmonic Local Heating

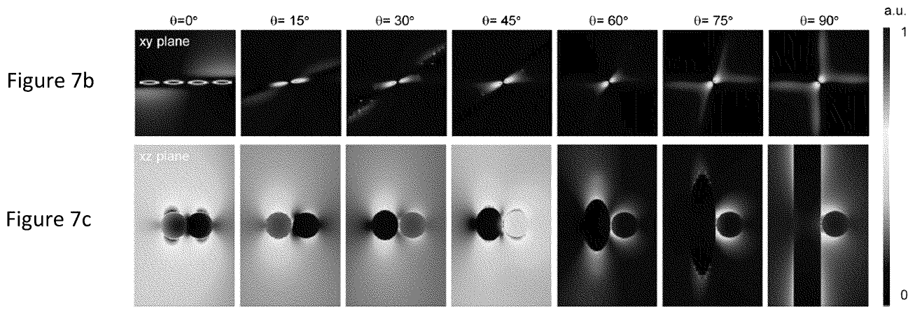

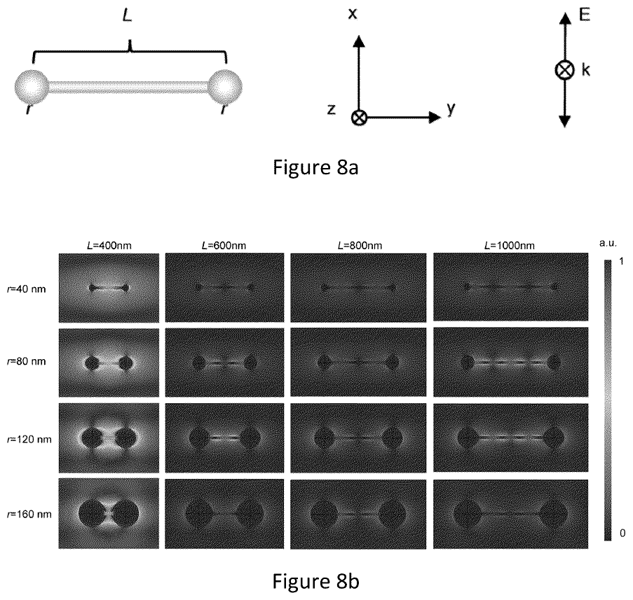

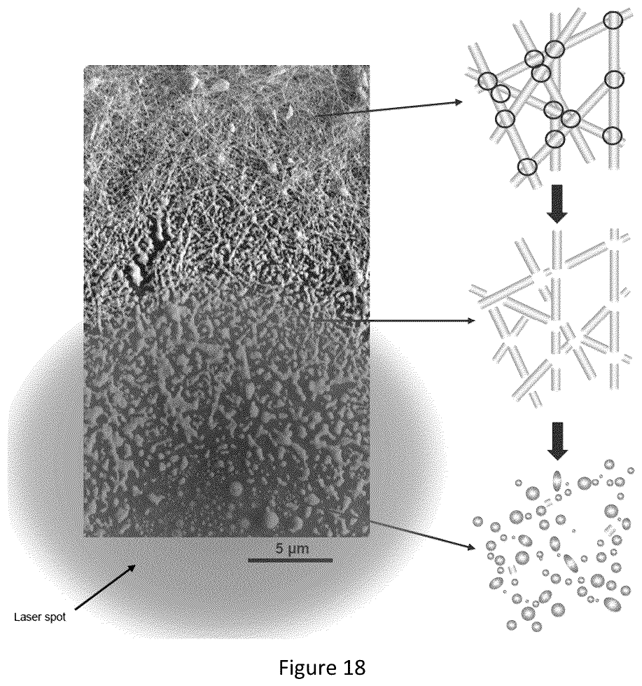

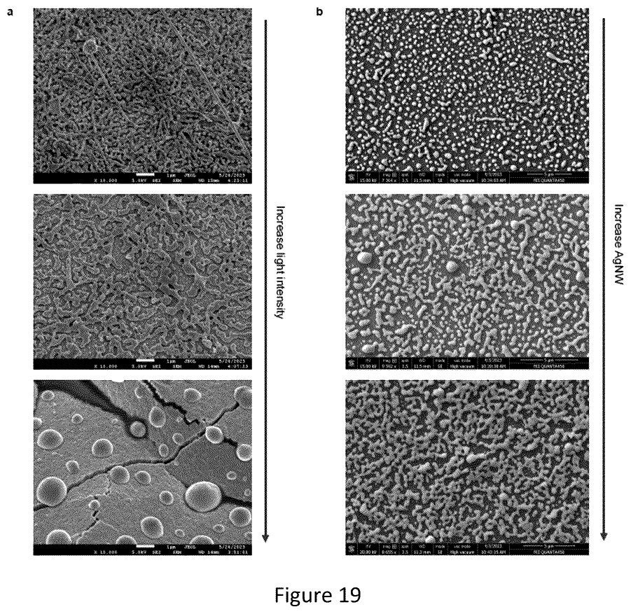

To achieve the on-demand thermal treatment of MO thin films, a progressive plasmonic printing scheme is proposed by exploiting the morphology evolution of Ag NWs driven by their local heating and collective temperature rise under fs laser illumination. Leveraging the plasmonic heating effect requires a pre-spray-coated network of Ag NWs as heating intermedia. Plasmon-induced tight near-field confinement forms hot spots at the intersections of Ag NWs (FIG. 7), triggering morphology evolution. FIG. 18 shows the morphology changes in the plasmonic-heating-induced Ag nanostructures. At lower light intensities around the edge of the fs laser spot, long Ag NWs break into short ones. With near-field hot spots along these short Ag NWs (FIG. 8), higher light intensities inside the laser spot melt them into small particles. The highest intensities at the centre cause small, dense Ag particles to merge into larger, sparser ones. In particular, excessive heat can damage the MO thin films or even the glass substrate (FIG. 19a). Therefore, an optimal light intensity is crucial^{21, 22}. The amount of Ag NWs also substantially influences its morphology evolution and the local heating effect (FIG. 19b).

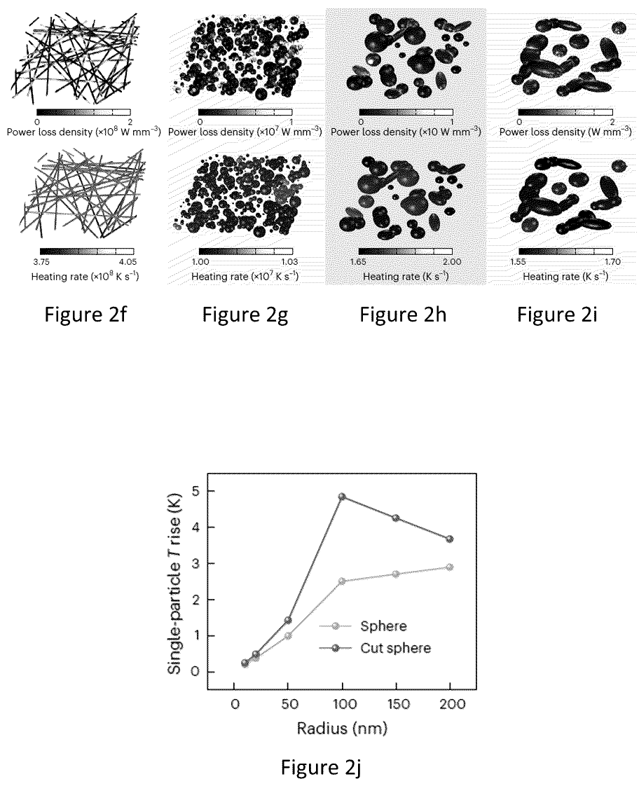

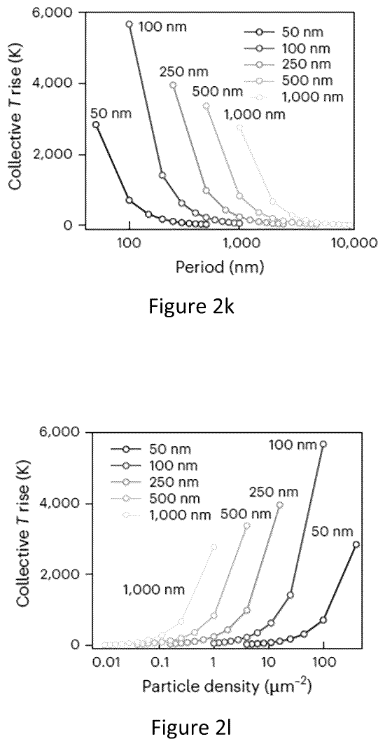

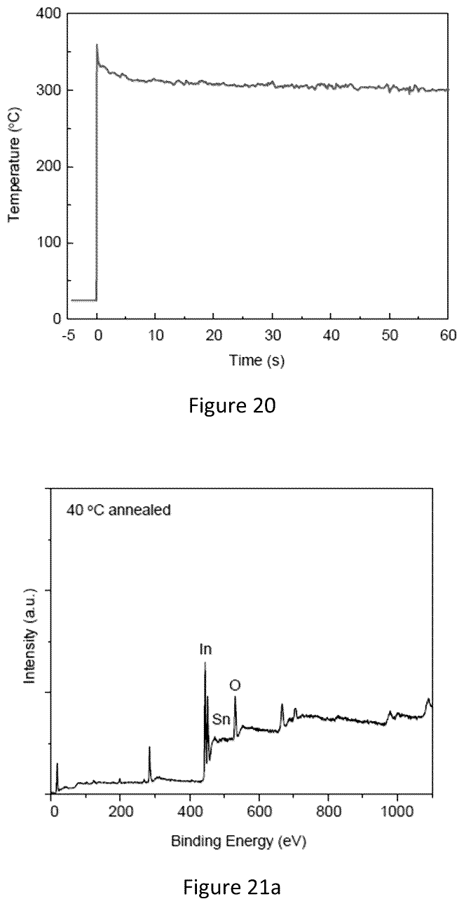

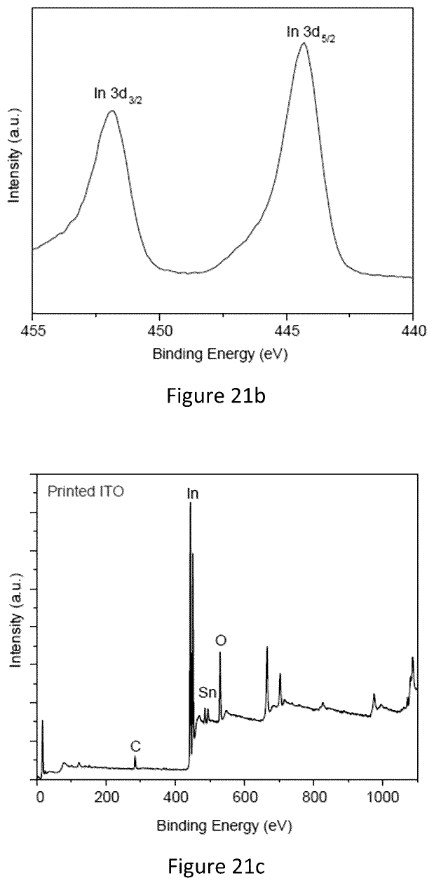

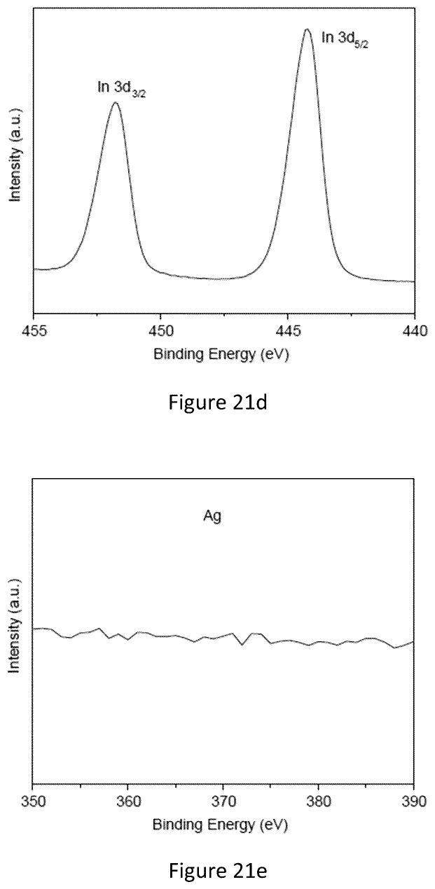

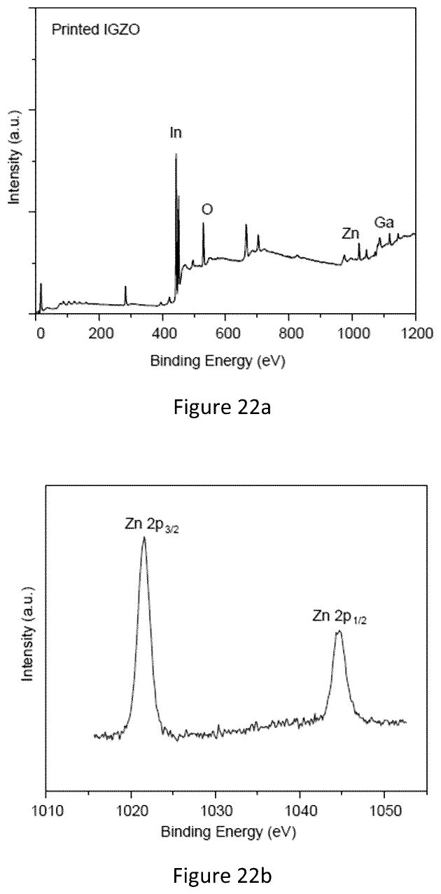

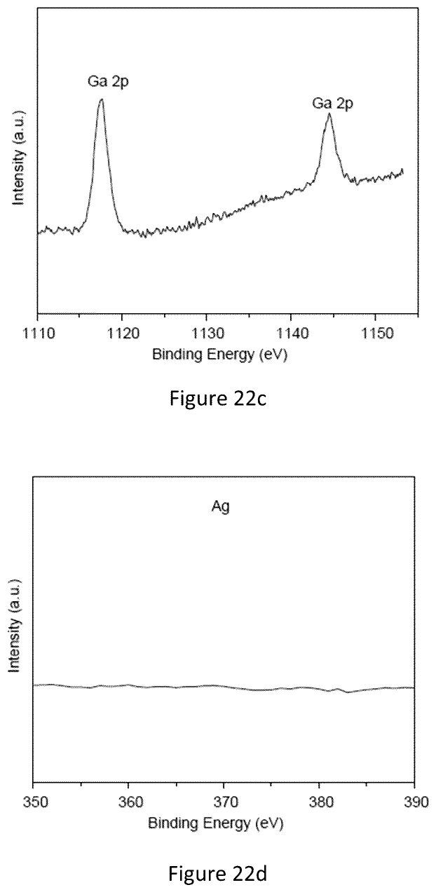

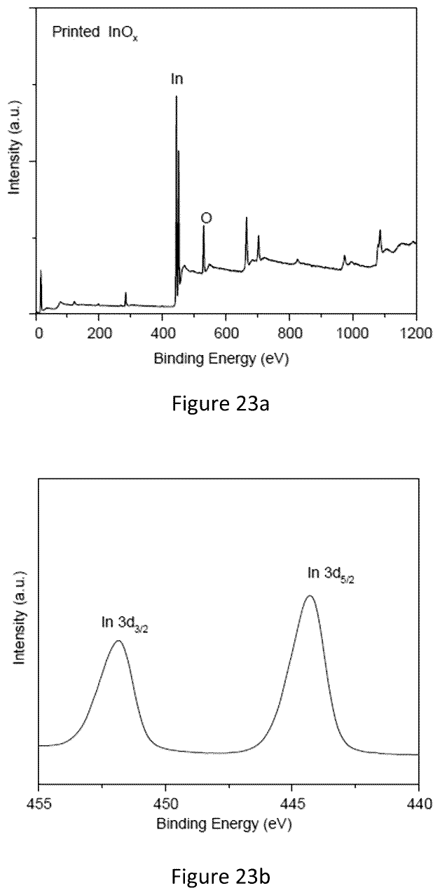

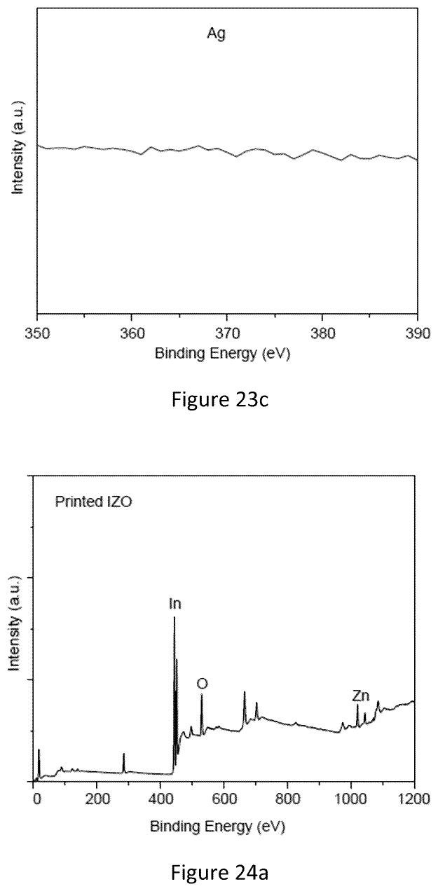

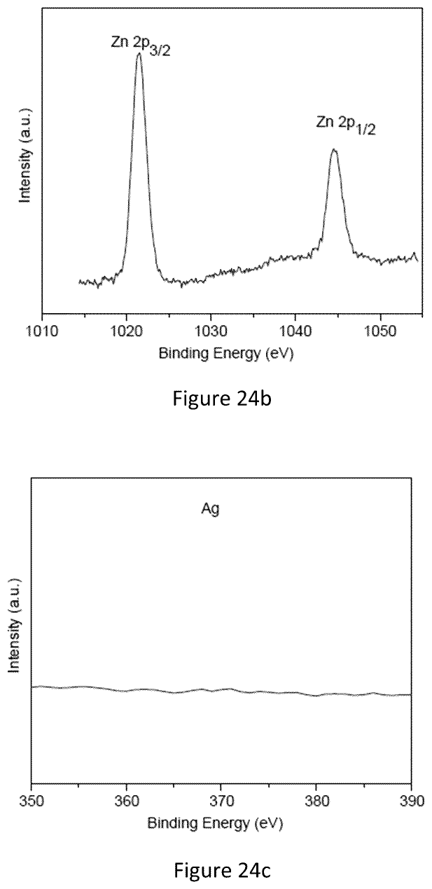

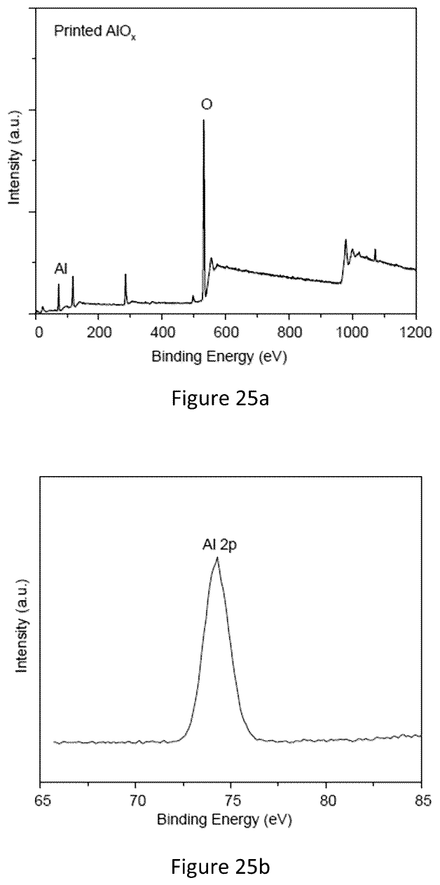

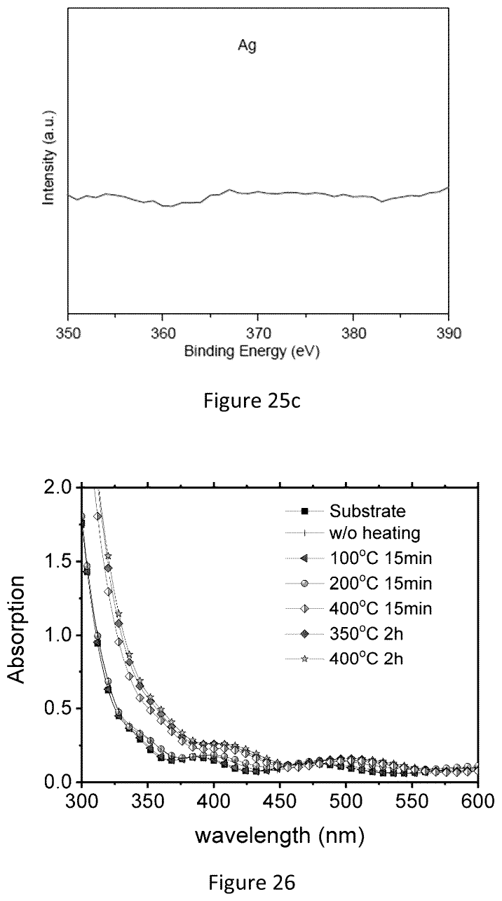

An infrared (IR) camera tracked the temporal temperature rise during plasmonic heating (FIG. 6a). As shown in FIG. 2a and FIG. 20, the local temperature of an illuminated region rises rapidly from 25° C. to ~360° C. in 66 ms and then drops to ~314° C. over 10 s due to the plasmonic heating-environment cooling balance. To understand such intriguing two-step heating process, scanning electron microscopy (SEM) is used to examine the Ag nanostructures before and after 0.1 s, 1 s and 10 s of laser irradiation (FIG. 2b-e). The Ag NW network melts into particles with varied sizes and densities during irradiation. Within 0.1 s, some Ag NWs form dense particles, whereas others melt into irregular assemblies. These then tend to merge into larger, sparser particles. Simulations based on the SEM images show that the pristine Ag NWs have the highest light absorption efficiency and, therefore, the largest rate of local temperature rise (FIG. 2f-i). However, since the plasmonic hot spots form at NW intersections, not at the NW-MO precursor interface (FIG. 2f), heat breaks the Ag NWs but does not treat the underlying MO precursors immediately. When the Ag NWs melt into small, dense particles within 0.1 s, the light absorption efficiency and local heating effect drop substantially but remain effective due to the collective contribution of the illuminated particles. This heating drives adjacent small particles/assemblies to merge into larger, sparser particles after 0.1 s (FIG. 2d,e), reducing the heat generation efficiency as morphology evolution completes (FIG. 2h,i). By contrast, isolated Ag particles exhibit a much lower temperature rise, regardless of their size and shape (FIG. 2j). However, dense Ag particle arrays with appropriate size and particle density can achieve in theory a temperature rise of over 2,000 K (FIG. 2k,l), providing instant yet sufficient thermal treatment for rapid MO precursor conversion.

### Characterizations of Plasmonically Printed MO Thin Films

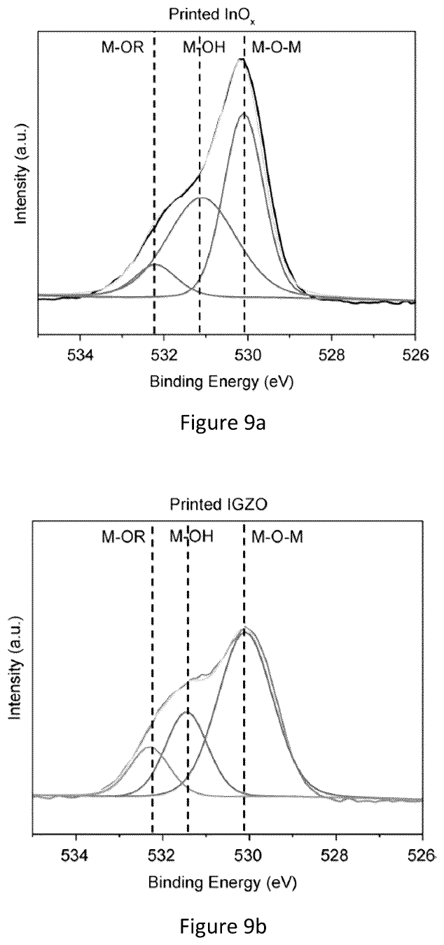

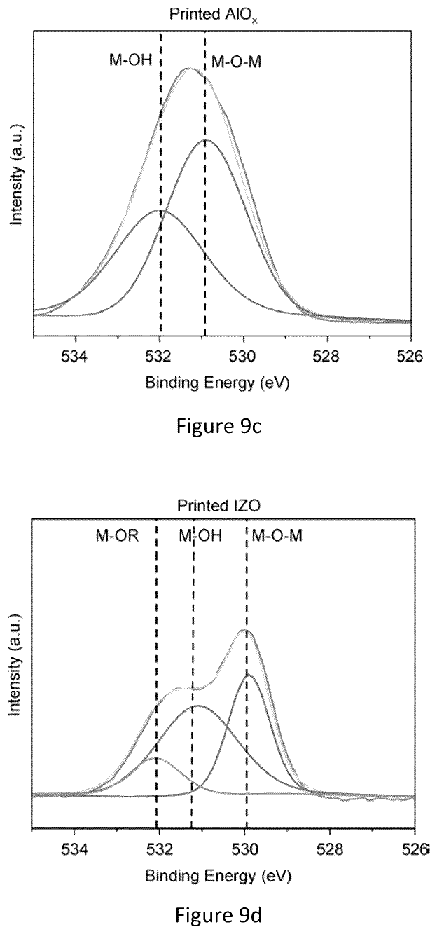

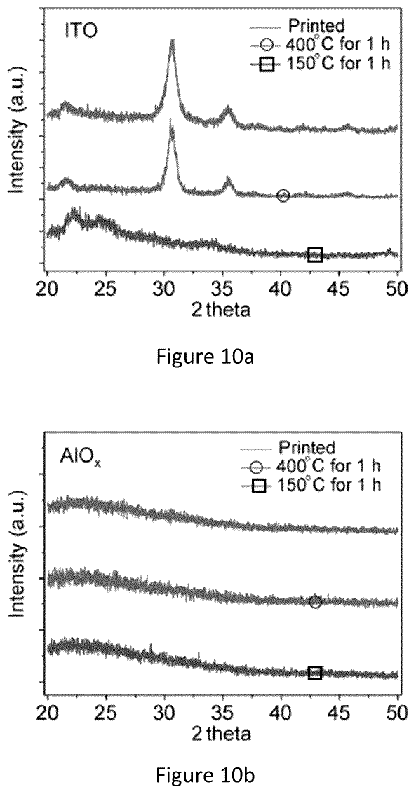

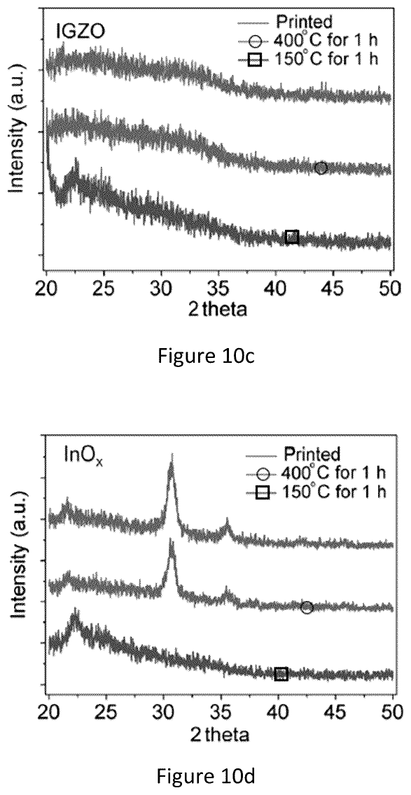

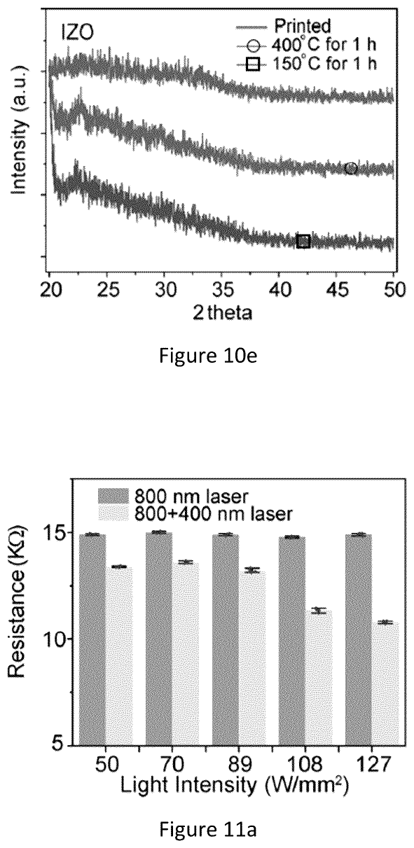

Generally, thin-film electronics rely on conductors, dielectrics and semiconductors. Here plasmonic printing enables high-performance MO thin films and provides a universal strategy. Several representative MOs, including ITO, AlOₓ, indium-gallium-zinc oxide (IGZO), indium-zincoxide (IZO) and InOx are prepared. X-ray photoelectron spectroscopy (XPS) is used to analyse metal-oxygen bonding in MOs before and after plasmonic printing (FIG. 1g,h, FIG. 9 and FIGS. 34-38). The Ols peaks at 530.1 eV, 531.2 eV and 532.3 eV correspond to M-O-M lattices, M-OH species and M-OR species, respectively^{8, 10, 11}. The 40° C.-dried ITO precursor film contains dominant densities of M-OH species, indicating incomplete oxidation. After the plasmonic printing process, the M-O-M peak at 530.1 eV intensifies, indicating successful conversion to dense ITO. Similar trends are observed for AlOₓ, IGZO, IZO and InOₓ (FIG. 9), demonstrating the method's universality. No Ag peaks are observed in the XPS results of all the plasmonically printed MO films, further supporting the claim that Ag NWs can be completely removed at least to the detection limit of XPS. Grazing-incidence angle X-ray diffraction (GIAXRD) further evaluates the film crystallinity. Here ITO and InOx thin films processed by low-temperature annealing (150° C.), high-temperature annealing (400° C.) and plasmonic printing are compared (FIG. 10). Both 400° C. annealing and plasmonic printing yield the desired polycrystalline films, but the latter shows sharper Bragg peaks, indicating higher crystallinity. By contrast, AlOₓ, IGZO and IZO films remain amorphous after printing, as expected¹. Overall, the XPS and GIAXRD results confirm that the quality of MO films printed within 0.3 s is comparable with that of MO films under 400° C. annealing for 1 h.

### Plasmonically Printed MO Thin-Film Electronics

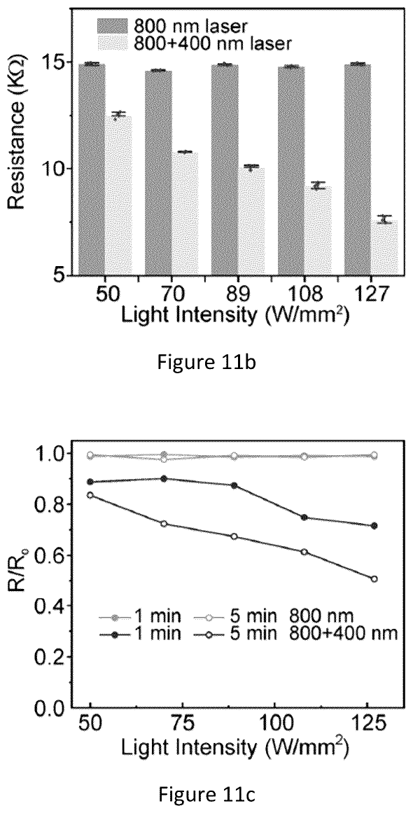

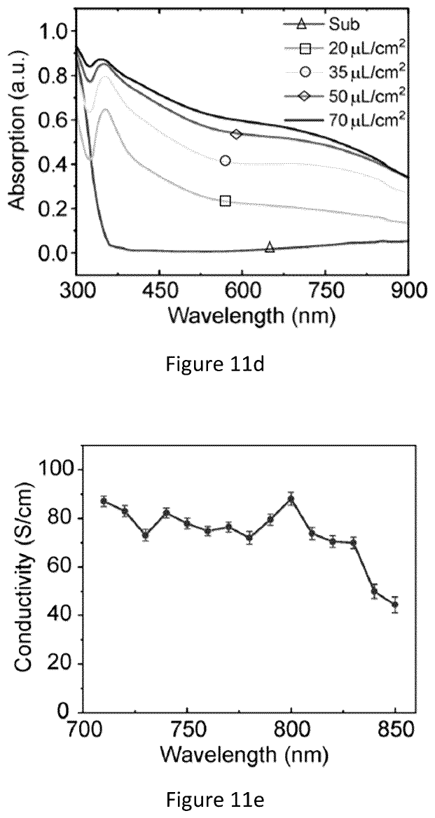

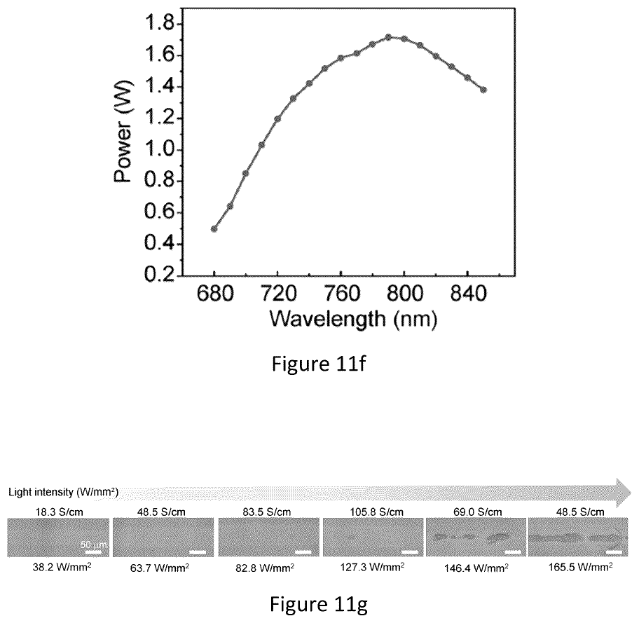

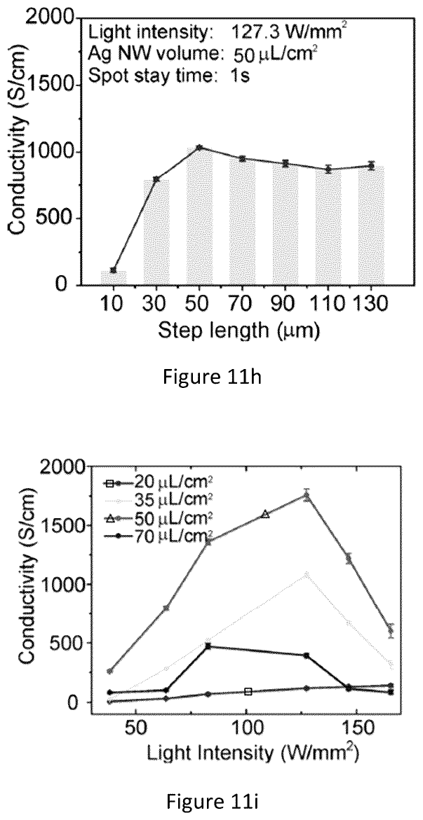

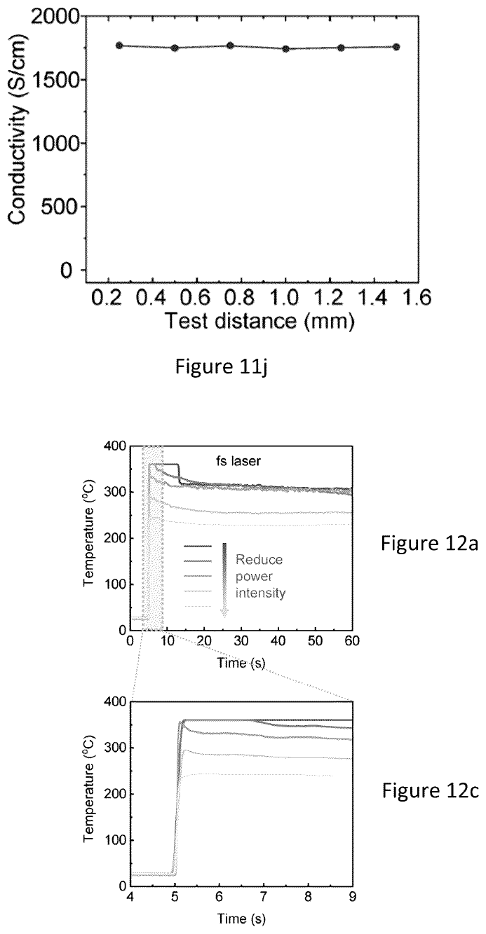

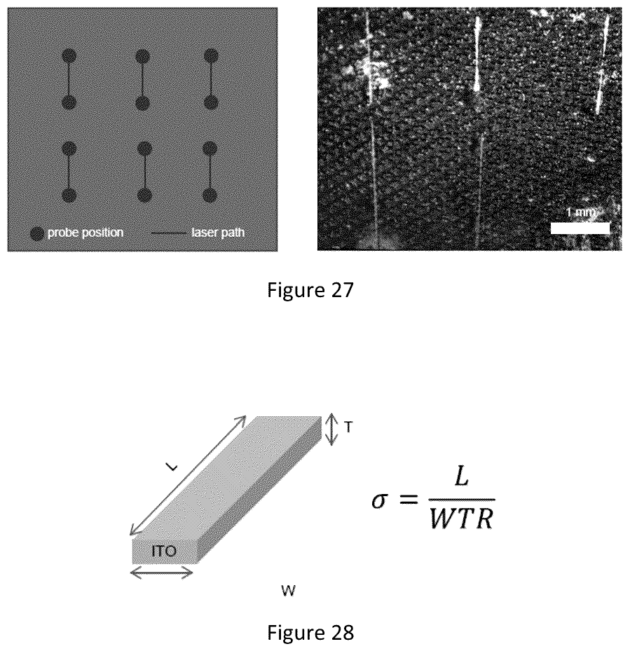

XPS and GIAXRD measurements show great quality of the plasmonically printed MO thin films. Next, the electrical performance of these MO thin films across conductors, dielectrics and semiconductors is investigated. ITO, as the most common MO conductor, is first printed by optimizing the plasmonic printing parameters. The effect of ultraviolet-induced photochemical reactions (no Ag NWs)^{11, 23, 24} on the ITO films is examined first (Supplementary Notes 1 and 2, FIG. 11, FIGS. 26 and 27 and Supplementary Table 1). It is found that the mixed 800+400-nm fs pulses halved the resistance of the 350° C.-annealed ITO, whereas pure 800 nm alone had no effect. This shows the effectiveness of 400-nm laser-induced photochemical reactions, which can enhance the quality and performance of MO thin films.

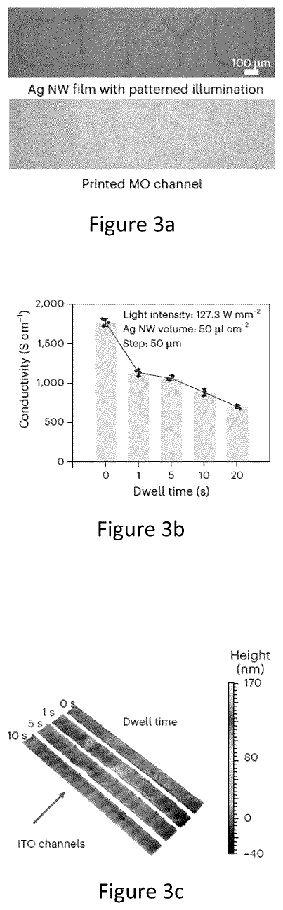

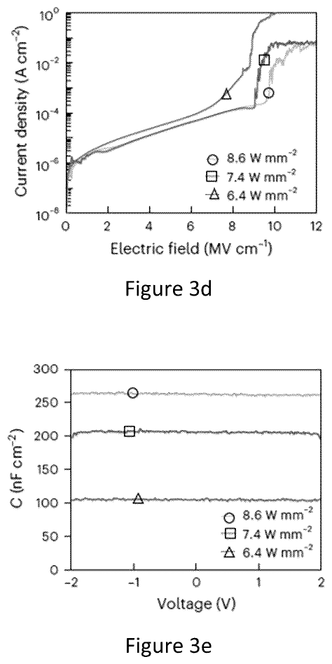

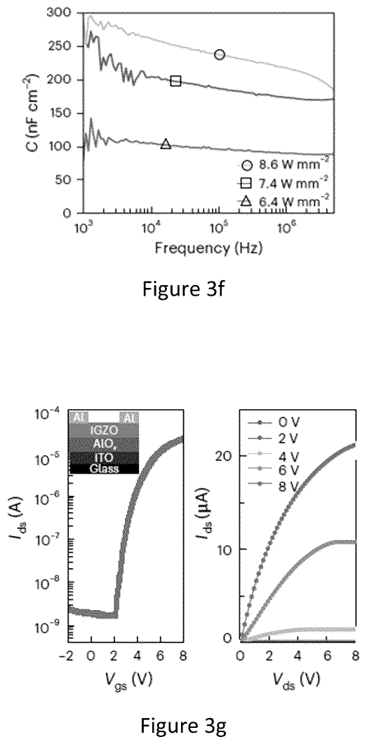

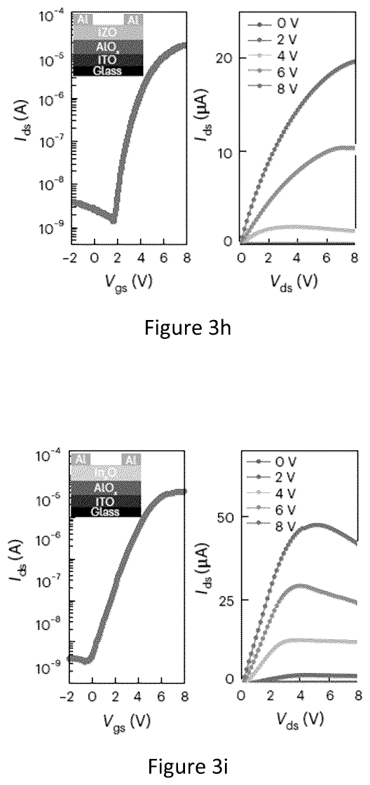

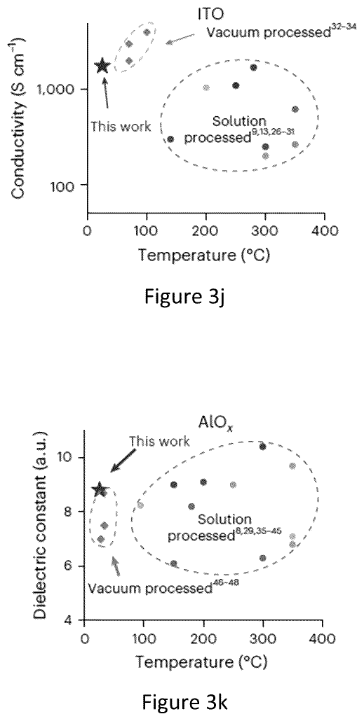

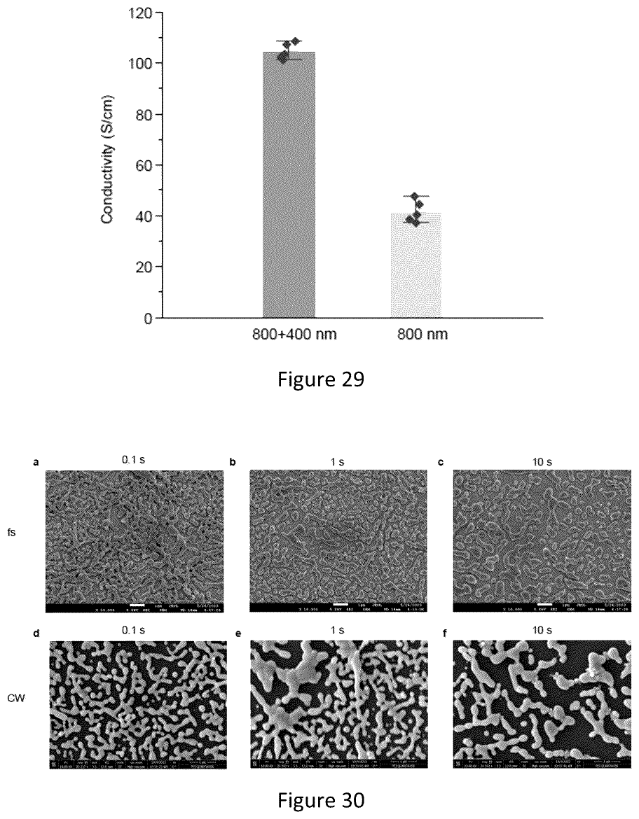

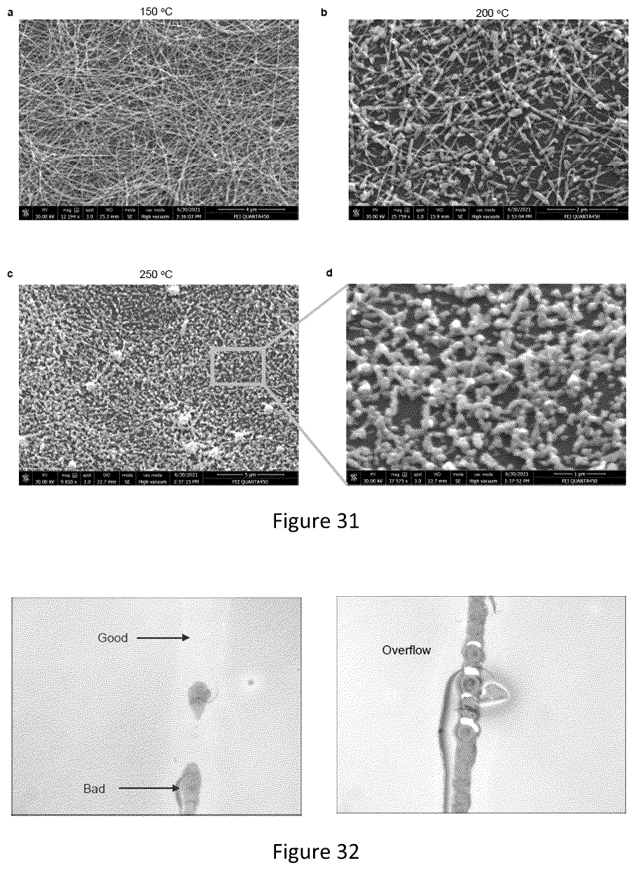

Next, plasmonic local heating is introduced by the laser excitation of the Ag NWs film. Process flow 1 is used to print individual MO functional layers, enabling direct pattern control and large-area fabrication via periodic laser scanning. FIG. 3a shows visible traces on the Ag NW film due to their morphology changes. Removing residual Ag nanostructures revealed a ‘CITYU’ ITO pattern, demonstrating excellent patterning control. Then, the scan parameters are optimized for high-quality ITO films, using conductivity as the primary indicator of film quality. Narrow and long ITO channels (1.5 mm×40 μm×12 nm) are printed and their resistances are measured. Using rectangular prism modelling, the ITO conductivity is calculated (FIG. 28). As noted, the photochemical reactions triggered by 400-nm light also enhance the quality of ITO after 350° C. annealing. With the same Ag NW-induced plasmonic local heating, it is found that the conductivity of ITO printed with the 400+800-nm laser is approximately two times that of ITO printed with a pure 800-nm laser (FIG. 29). This demonstrates that 400-nm-light-induced photochemical reactions can further enhance the electrical properties of ITO. Further optimization revealed that a 127 W mm⁻² fs laser with a primary wavelength of 800 nm was optimal for the plasmonic printing of MO (Supplementary Notes 3 and 4, FIGS. 11 and 12 and FIGS. 30-32).

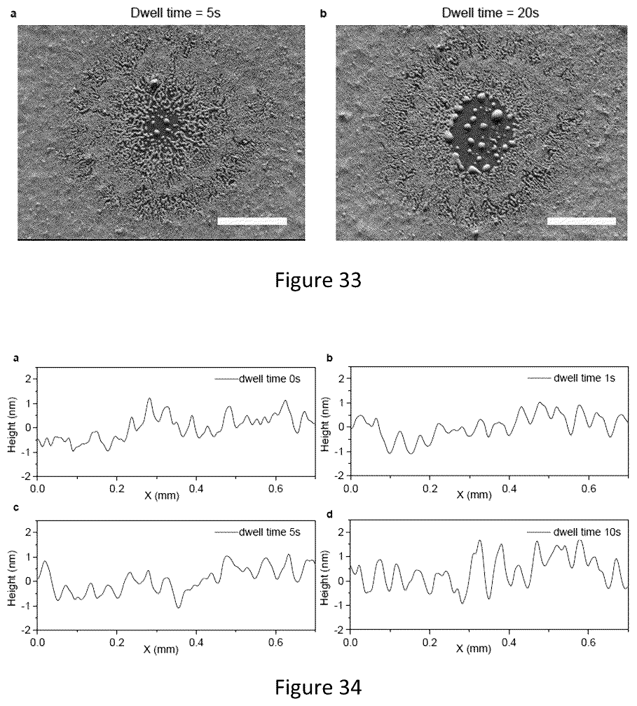

Some embodiments of the invention further optimize the scan parameters, namely, step length, dwell time and Ag NW thickness (FIG. 3b, FIGS. 11h and i). Conductivity drops sharply if the step size is <30 μm or the dwell time is >1 s. This results from morphological changes in the Ag NW during scanning (FIG. 2d,e and FIG. 33). SEM images (FIG. 2d,e) show that Ag NWs transform into larger, irregular and continuous ellipsoidal structures after 1 s of irradiation, reducing the plasmonic heat generation capability. FIG. 33 shows the morphologies of Ag NWs after dwell times of 5 s and 20 s. Prolonged irradiation causes the Ag NWs around the edges of the light spot to transform into irregular ellipsoidal shapes due to thermal conduction. When the light spot passes over these structures, the efficiency of plasmonic heat generation drops, lowering the ITO quality. To verify this, we profiled the surface of ITO printed under varied dwell times. FIG. 3c and FIG. 34 show that longer dwell times severely affect the surface morphology: dwell times of >1 s create a periodic topography with peaks and valleys; for dwell times from 1 s to 10 s, surface variation increases, indicating non-uniformity in the conversion of ITO. Weaker plasmonic heat generation results in lower conversion efficiency and thicker films, whereas stronger heat generation leads to more efficient conversion and thinner films²⁵. Such an uneven conversion lowers the ITO conductivity. Likewise, shorter scanning steps reduce the plasmonic heat generation efficiency, also lowering the ITO conductivity. Consequently, we identified the optimal scanning parameters for ITO, achieving a maximum average conductivity of 1,763 S cm⁻¹ (comparable with commercial ITO glass (5,000 S cm⁻¹)), and used the parameters for other MOs. Periodic bidirectional scanning suffices for preparing MO areas without parameter adjustment. For example, printing a 1-mm² ITO film takes ~1.6 min. Moreover, conductivity values measured at different probe distances (FIG. 11 j) are nearly identical, showing high uniformity.

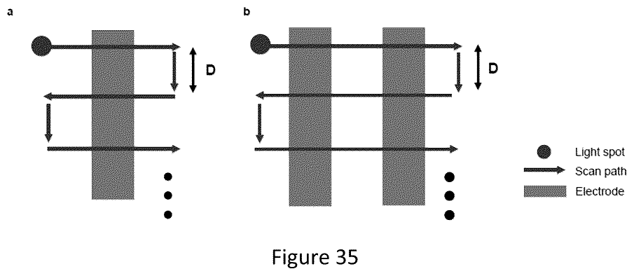

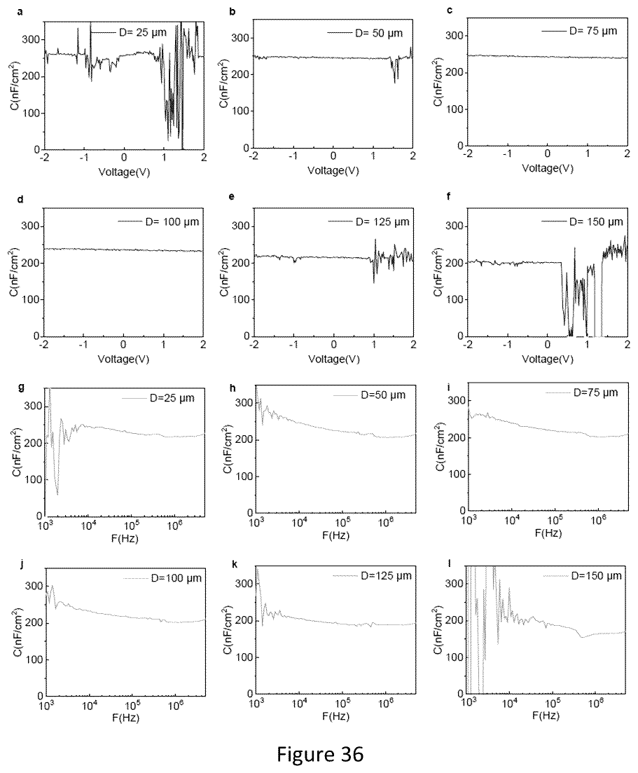

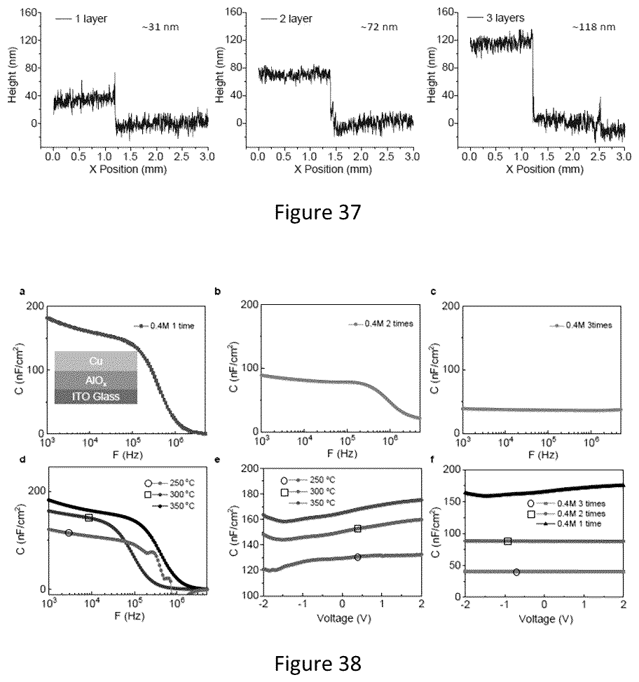

Next, AlOₓ as the MO dielectric is processed by plasmonic printing. FIG. 3d (insert) shows the dielectric testing of the AlOₓ:ITO/AlOₓ/Cu sandwich with an electrode area of 0.1×1 mm². FIG. 3d-f shows the key dielectric properties: leakage current density (J-E), capacitance-voltage (C-V) and capacitance-frequency (C-F) curves of AlOₓ films. Laser path spacing is optimized for uniform coverage (Supplementary Note 4 and FIGS. 35 and 36). Dielectric properties can be improved by optimized strong light intensity with an ~9-V breakdown voltage, high capacitance (260 nF cm⁻² at 10 kHz) and stable frequency stability (10³-10⁶ Hz). However, a further intensity increase shows no marked improvement in performance. Due to the low conversion temperature of AlOₓ, a light intensity of 8.6 W mm⁻² suffices. A higher intensity risks energy wastage and substrate damage. Therefore, the light intensity is set at 8.6 W mm⁻². The measured thickness (FIG. 37) and capacitance give a dielectric constant of 8.8 for plasmonically printed AlOx films. This value is comparable with vacuum-prepared AlOx films, which surpasses 350° C.-annealed films (dielectric constant of 7.2; FIG. 38).

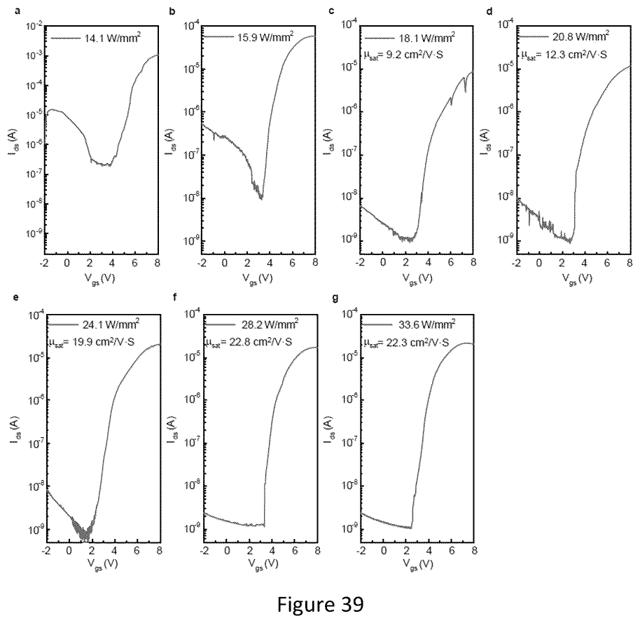

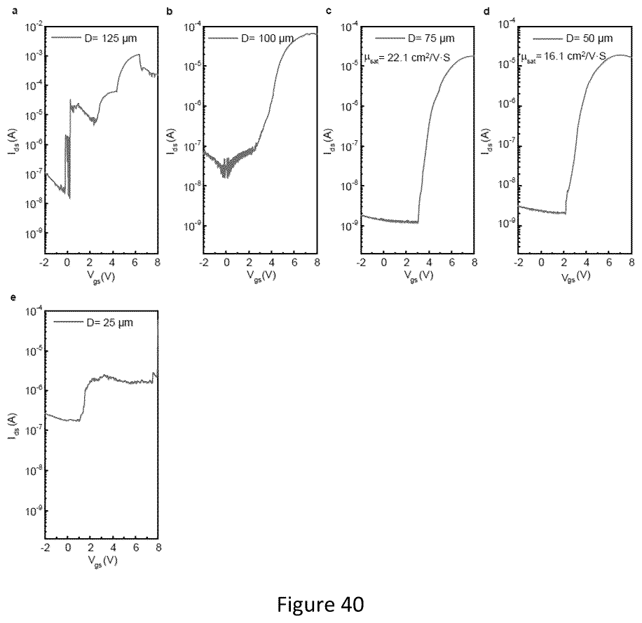

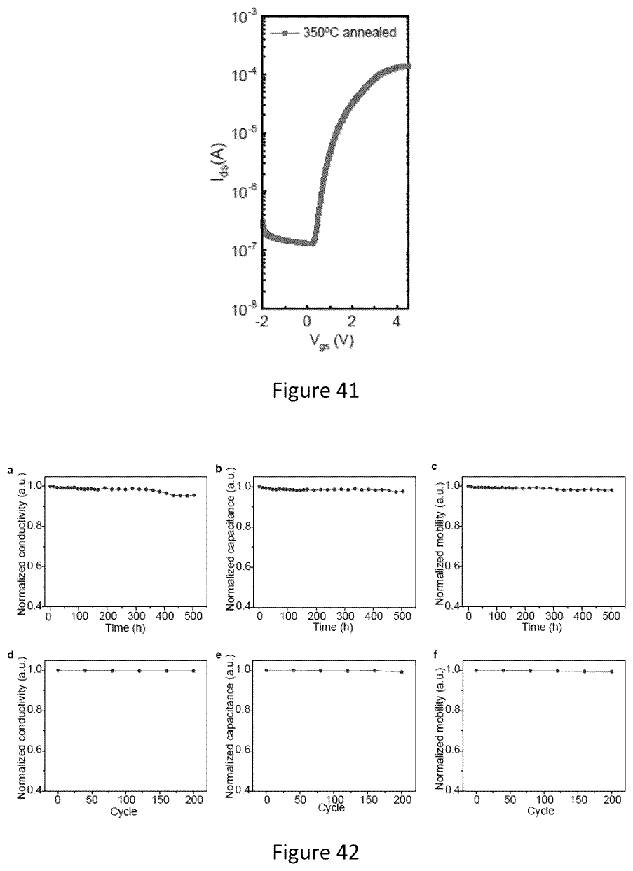

Finally, based on the optimized printing parameter (Supplementary Note 4 and FIGS. 39 and 40), MO semiconductors, including IGZO, IZO and InOx for transistors, are printed. The insets in FIG. 3g-i show the transistor structures with ITO gate-glass substrate, associated with the AlOₓ dielectric (annealed at 350° C., ~120 nm) and Al source-drain electrodes (40 nm). FIG. 3g-i shows the transfer and output curves of the TFTs based on plasmonically printed MO semiconductors. Supplementary Table 2 summarizes the comprehensive device parameters for these devices. All the printed semiconducting MO films exhibit good TFT performance, especially IGZO, with a saturation mobility (μₛₐₜ) of 21.0±3.2 cm² V⁻¹ s⁻¹ and Iₒₙ/I_{off}~10⁴, surpassing 350° C.-annealed devices (Supplementary Table 2 and FIG. 41). In particular, in the plasmonically printed IZO- and InOₓ-based transistors, apparent negative-differential-resistance phenomena are observed under high gate voltage and bias. The underlying mechanisms are discussed in Supplementary Note 5.

Plasmonic printing offers a rapid and universal approach for the high-throughput fabrication of solution-processed MO conductors, dielectrics and semiconductors, with superior performance over thermal annealing due to localized plasmonic heating (Supplementary Note 6). It is worth mentioning that different MO precursor solutions necessitate different conversion temperatures, determining the laser intensity. Other processing parameters remain constant across MO materials (Supplementary Note 7). Meanwhile, the plasmonically printed high-quality MO films exhibit excellent environmental and thermal stability (Supplementary Note 8 and FIG. 42).

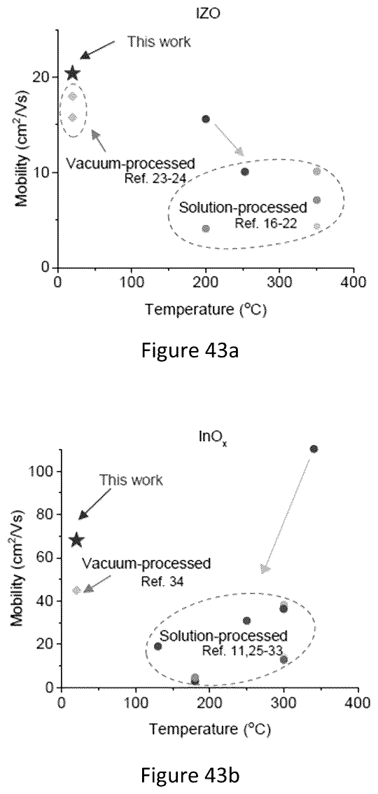

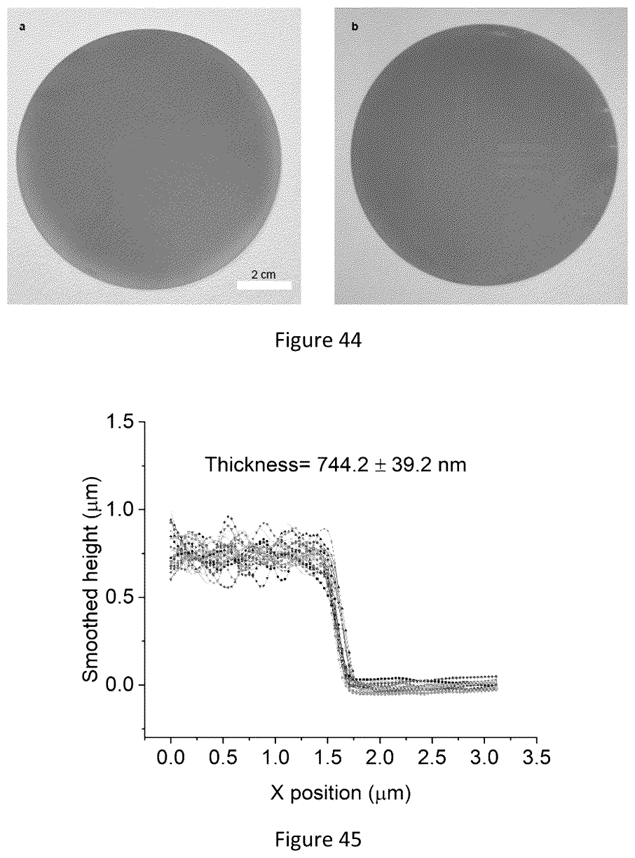

FIG. 3j-1 and FIG. 43a and FIG. 43b compare the performance of plasmonically printed MO devices with those from other low-temperature-solution- and vacuum-processed ones. Plasmonically printed MOs show obvious electrical performance advantages. Plasmonically printed ITO achieves the highest conductivity (1,763 S cm⁻¹) among the reported low-temperature-solution-processed works reported so far^{10, 13, 26-34}; the dielectric constant of plasmonically printed AlOₓ approaches ~9, which is also among the best^{8, 29, 35-48}; and the μₛₐₜ value of transistors based on plasmonically printed IGZO, IZO and InOₓ are also among the highest values, comparable with vacuum-processed devices^{8, 11, 29, 49-59}. In particular, all-MO devices are printed under ambient conditions with much faster conversion (<0.3 s) than that of other methods. The process also enables precise, uniform and large-area fabrication (Supplementary Note 9 and FIGS. 44-46). These features are crucial for scalable, low-cost MO electronics.

### Plasmonically Printed Transistor Arrays and Logic Circuits

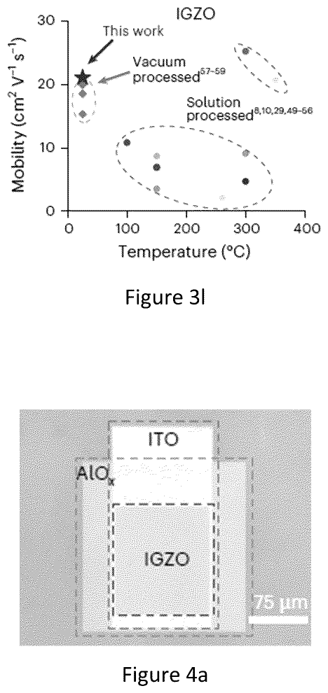

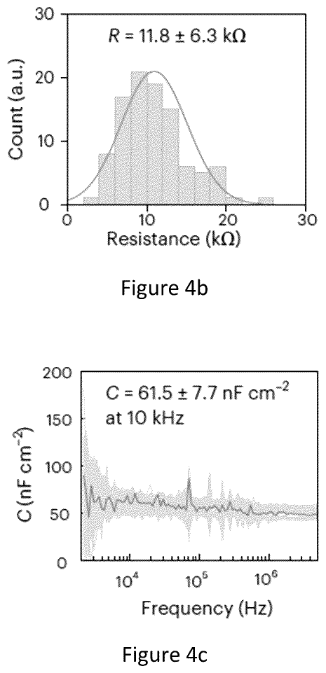

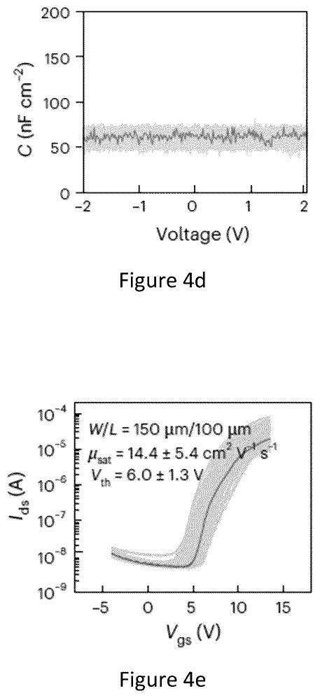

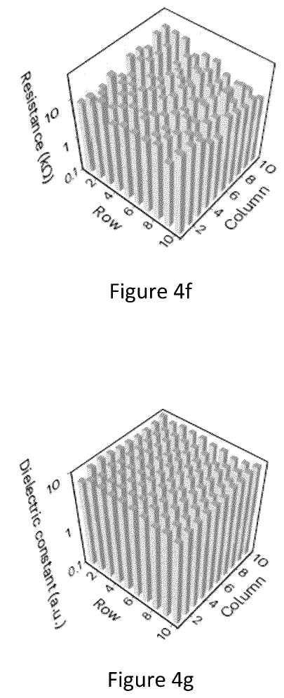

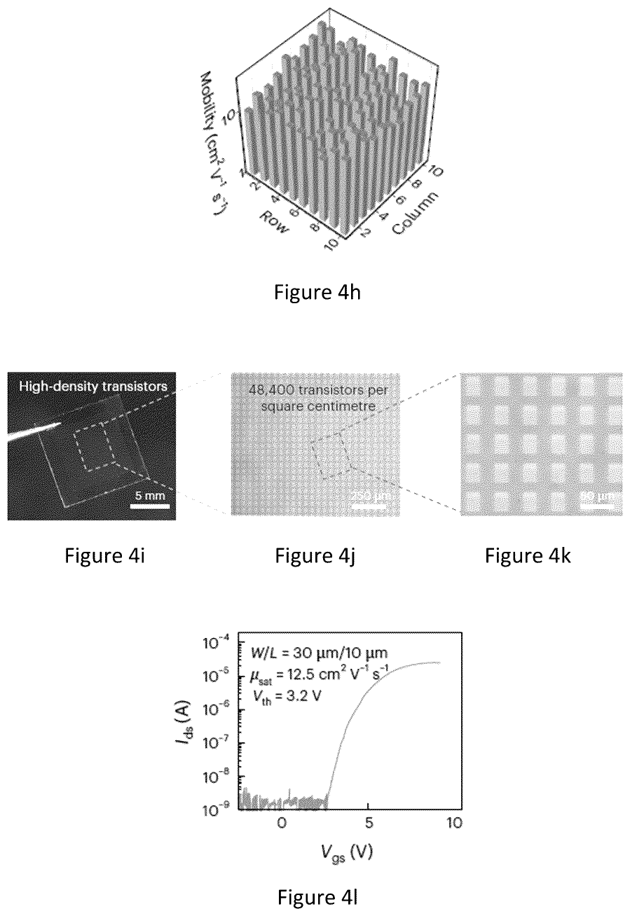

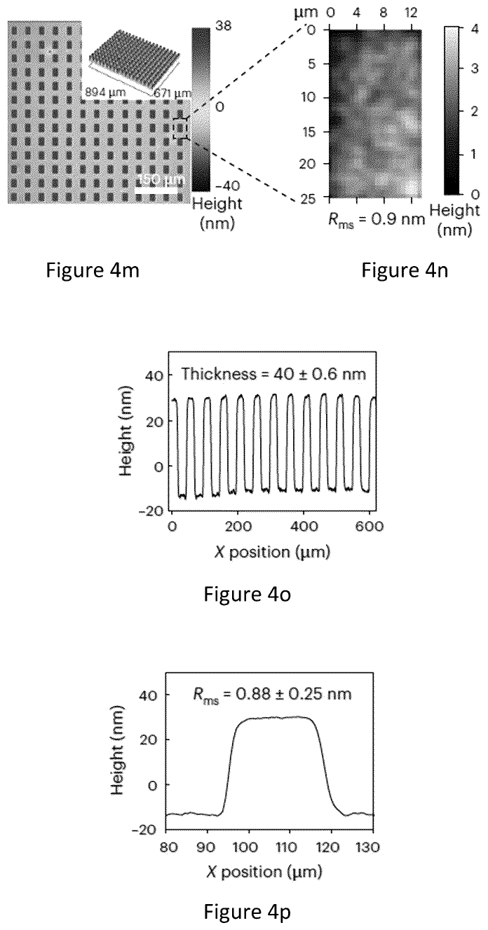

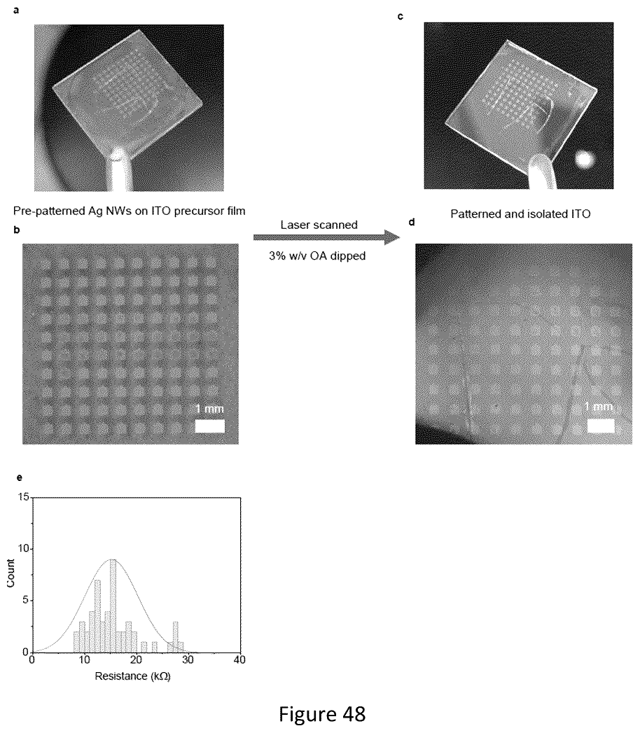

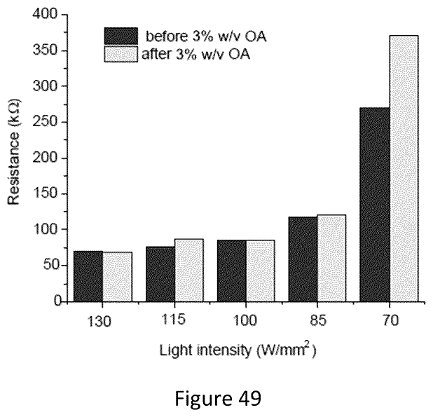

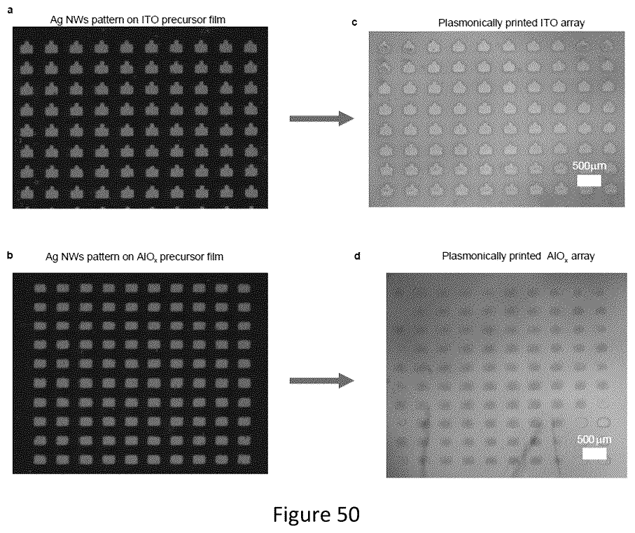

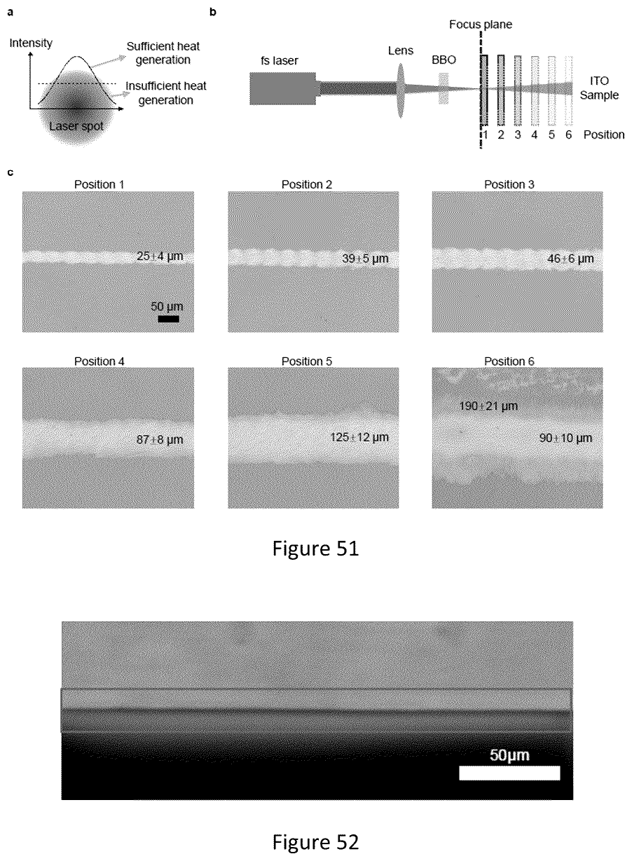

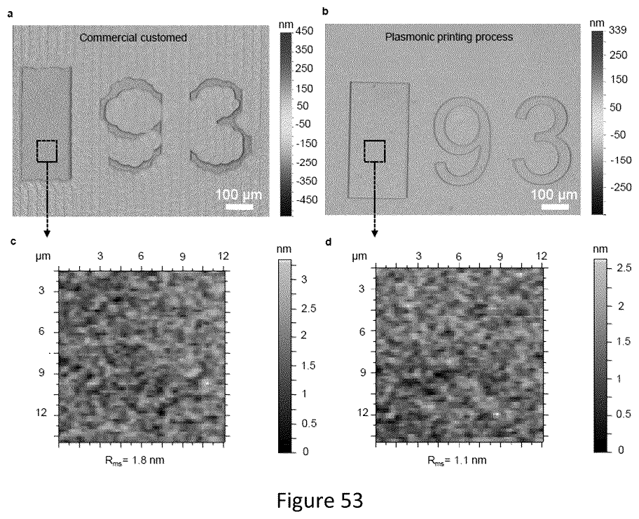

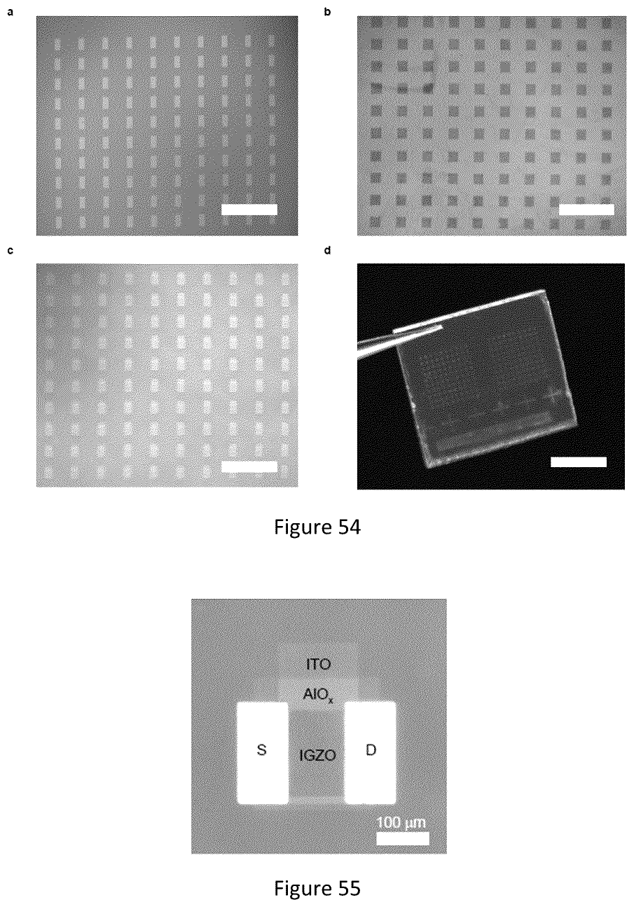

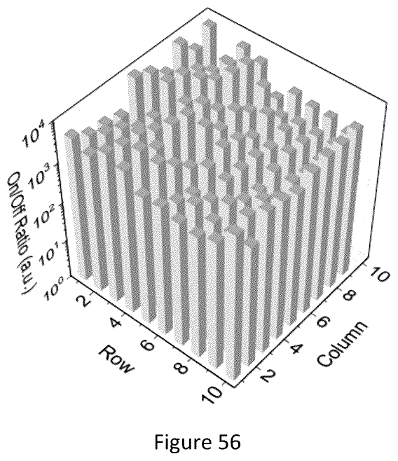

IGZO, with a low power consumption and fast response, is a promising alternative to Si and, thus, commercially used in high-density TFT arrays for displays³. However, vacuum processing limits the scalability with high cost. The plasmonic printing process is employed to fabricate fully solution-processed high-density MO TFT arrays under room temperature and ambient conditions (FIG. 47). Process flow 3 is first used to fabricate a 10×10 ITO gate array (0.5×0.5 mm² each; FIG. 48). Ag NWs are patterned to confine the plasmonic heating regions⁶⁰. The uncondensed MO precursor film is easily removed through ~10 s of immersion in a 3% w/v OA solution. This immersion does not affect the electrical properties of the printed condensed ITO (FIG. 49). Moreover, process flow 3 also enables smaller-scale arrays of ITO and AlOₓ (0.25×0.2 mm²). At reduced scales, the thermal conduction effects at the edges of the Ag NW patterns cause the non-uniformity of MO patterns (FIG. 50). These irregularities could degrade performance in high-density arrays. Still, process flow 3 offers greater possibilities for printing nanoscale TFTs by patterning nanostructures on the MO precursor film. These nanostructures can induce local plasmonic heating to convert MOs at the nanoscale. Process flow 2 uses photolithography to pattern MO precursors with smooth edges. This flow ensures high resolution and edge quality (Supplementary Notes 10 and 11 and FIGS. 51 and 52). Additionally, the proposed method yields better uniformity and lower roughness than commercially used vacuum techniques (Supplementary Note 12 and FIG. 53). As illustrated in FIG. 4a and FIGS. 54 and 55, an array of 10×10 MO TFTs (ITO/AlOₓ/IGZO with width W=150 μm and length L=100 μm) is demonstrated with uniformly patterned features. To assess the reliability of the process, we evaluated the electrical performance of the 10×10 plasmonically printed ITO gate electrodes, AlOₓ dielectric layers and final IGZO-based TFTs (FIG. 4b-h and FIG. 56). The results show that all these MOs exhibited great uniformity: ITO resistance, 11.8±6.3 kΩ; AlOₓ dielectric constant, 8.03+0.8; IGZO μₛₐₜ, 14.5±5.4 cm² V⁻¹ s⁻¹ These results confirm ~100% yield and uniform performance. This underscores the considerable potential of this technique for applications in the active-matrix technology.

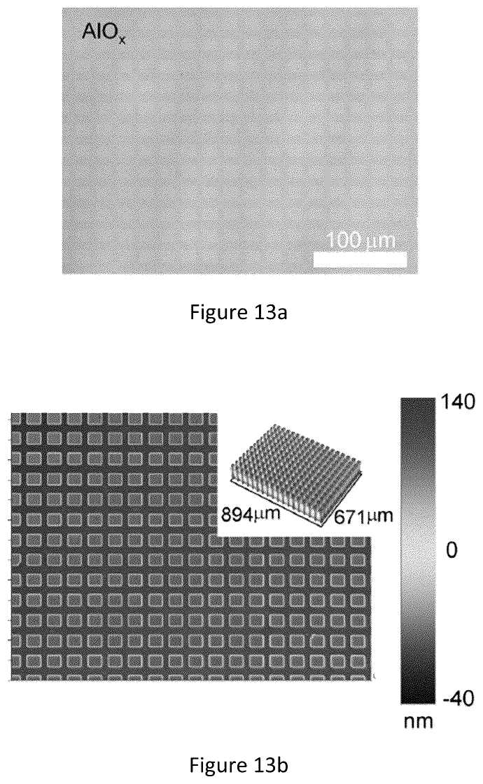

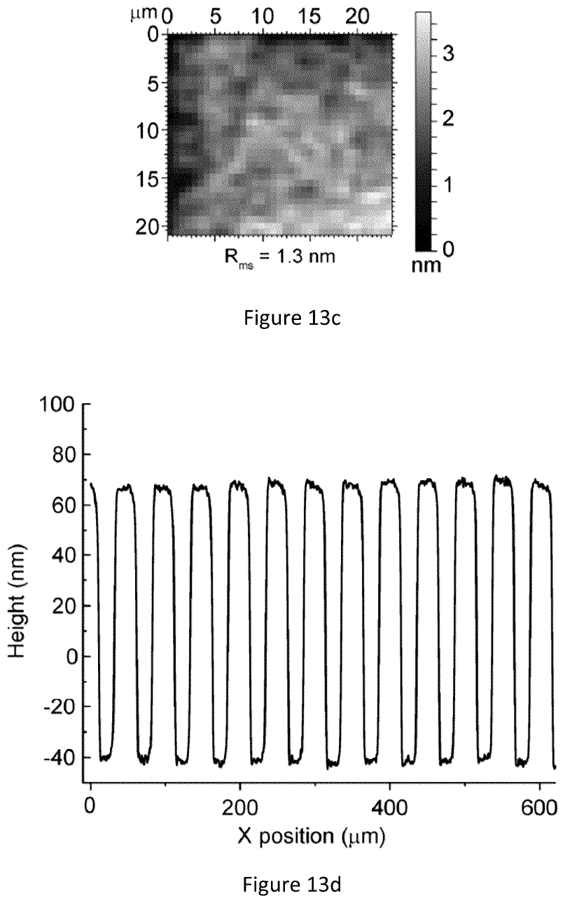

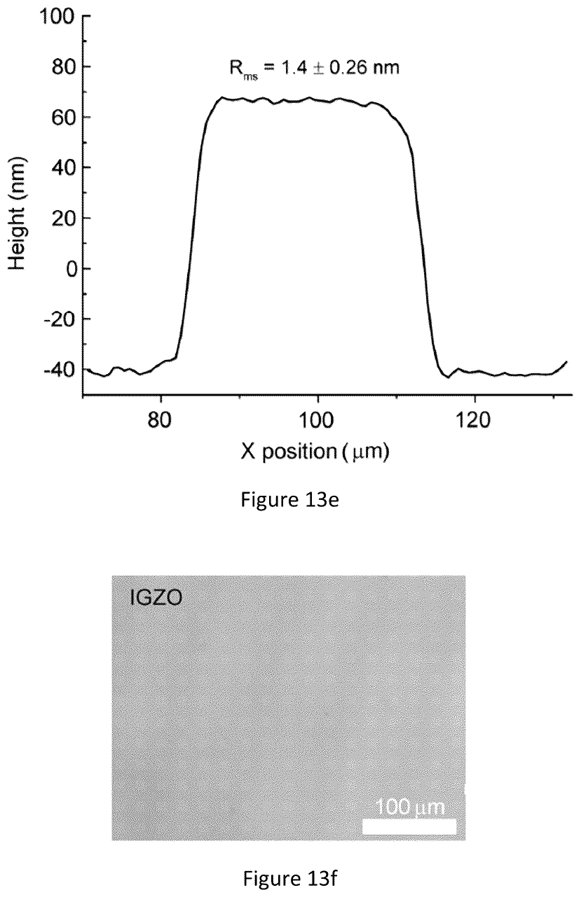

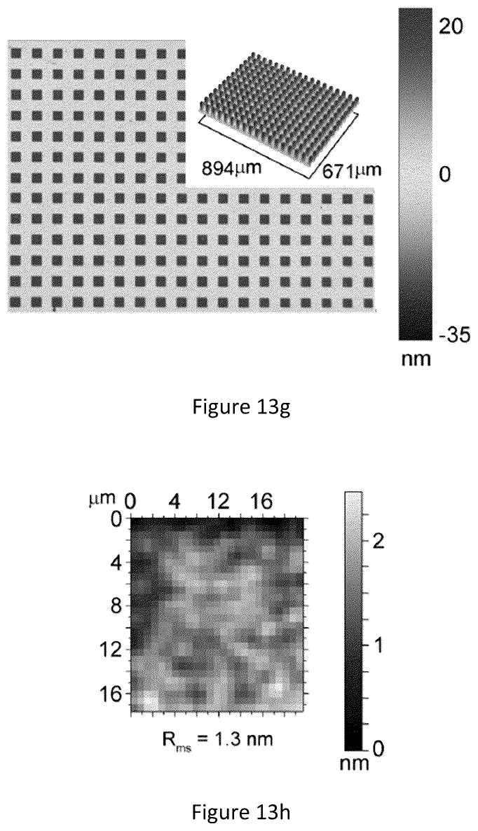

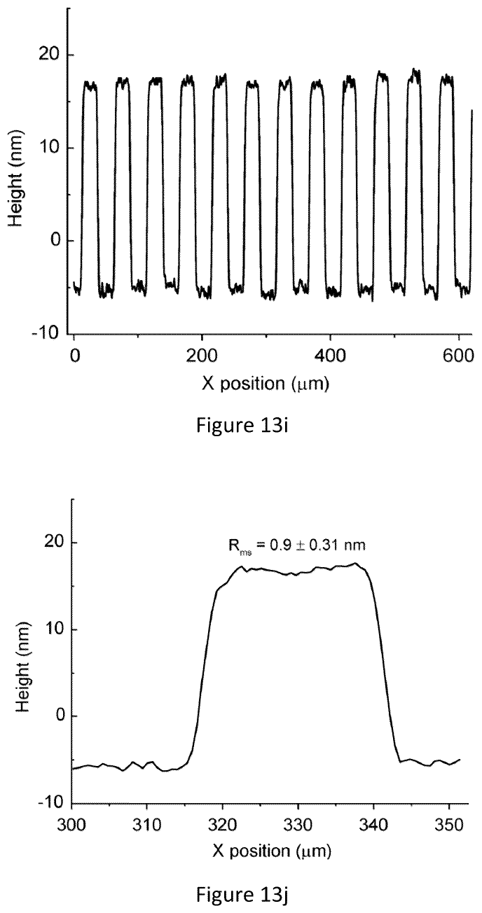

Next, it is demonstrated the high-density, fully solution-processed MO transistor array (FIG. 4l-4k) with a super-high resolution of 48,400 transistors per square centimetre at room temperature under ambient conditions. To the best of our knowledge, this density represents the highest level so far for a solution-processed MO transistor array. Each transistor has an ITO/AlOₓ/IGZO structure with a 30 μm×10 μm channel. FIG. 4l presents a representative transfer curve with μₛₐₜ of 12.6 cm² V⁻¹ s⁻¹, Vₜₕ of 3.2 V and Iₒₙ/I_{off} of ~104. An optical profilometer is used to examine the surface morphology and uniformity. As shown in FIG. 4m-p and FIG. 13, the plasmonically printed units show uniform shape and thickness. The ITO surface is smooth, with root mean square (Rₘₛ) roughness of 0.88±0.25 nm. These results confirm that Ag—NW-induced plasmonic heating enables uniform MO unit fabrication, crucial for high-density active-matrix applications.

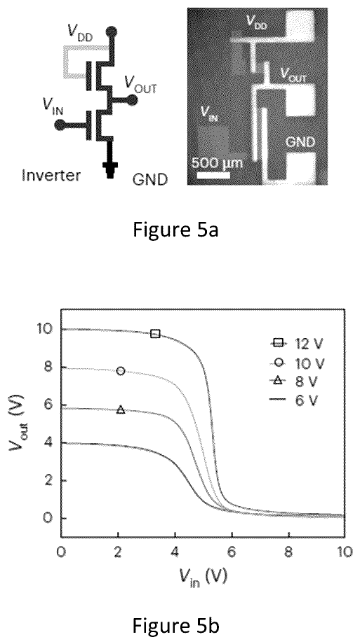

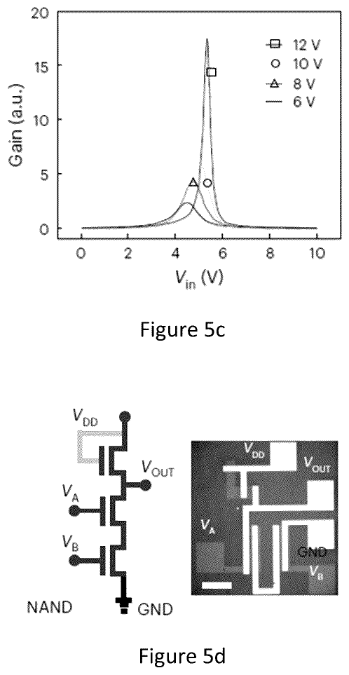

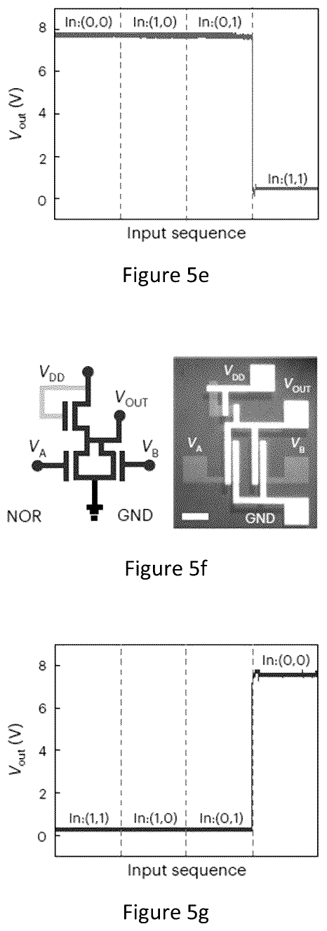

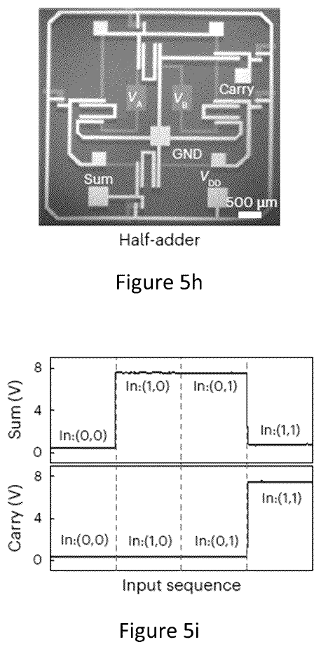

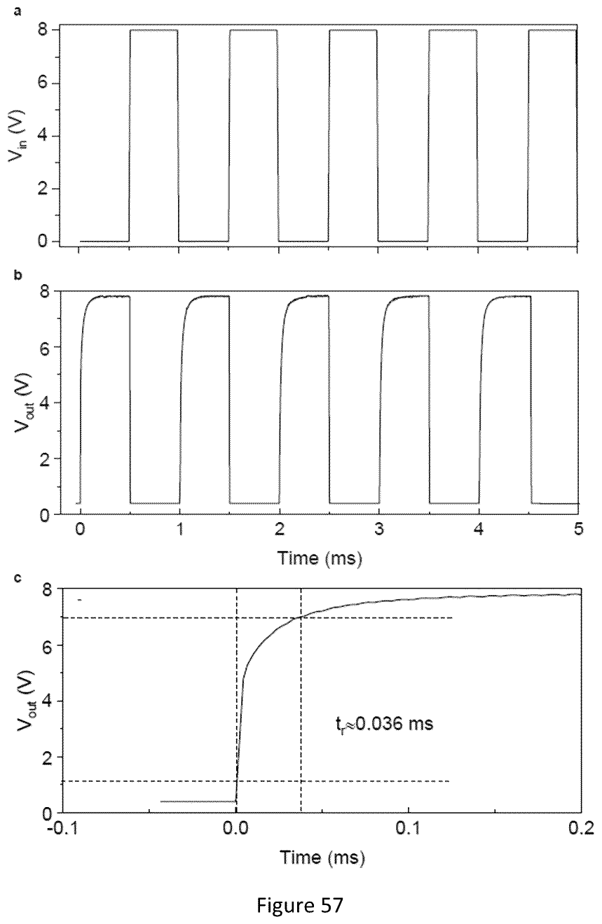

Finally, plasmonic printing is used to fabricate all-MO-based logic circuits. Using process flow 2, some embodiments of the invention fabricate transistors as described and pattern them into typical n-type metal-oxide-semiconductor logic gates. FIG. 5a shows the schematic and optical photograph of the inverter based on plasmonically printed MO transistors (load transistor W/L=1.5, drive transistor W/L=15). FIG. 5b,c presents the representative voltage transfer curves (Vout-Vin) and voltage gain curves under supply voltages VDD ranging from 6 V to 12 V, indicating good swing behaviour of inverter and gain of 15 at a VDD of 12 V. FIG. 57 shows the inverter transient performance in the time domain. The input voltage is a square wave (1 kHz and 8 V) and VDD is 10 V. The inverters show good stability, fast switching, symmetric rise/fall edges and clear inversion. Some embodiments of the invention also design and print logic NAND and NOR gates with the ideal logic function (FIG. 5d-g). The reliability of the plasmonic printing technique enables the design and printing of more complex circuits, such as a half-adder (FIG. 5h). Desired logic functions of the half-adder indicate that all the printed transistors function properly (FIG. 5i).

### CONCLUSION

In this disclosure, proposed is a new printing method for the high-throughput processing of high-performance MO thin films with super-high resolution, called plasmonic printing. It uses Ag NW-induced plasmonic local heating, which affords comparable condensation/reaction energy of those based on thermal annealing at 300-400° C., enabling great performance for electronics. Moreover, plasmonic printing universally applies to conductors, dielectrics and semiconductors at room temperature in ambient air. Its high yield and uniformity enable the fabrication of high-density MO TFT arrays and complex logic circuits. This breakthrough paves the way for commercializing low-cost solution-processed MO electronics, thereby fostering its extensive application in active-matrix pixilation, logic chip fields and many others.

### Methods

### Precursor Preparation

All the MO precursor materials and 2-methoxyethanol can be purchased from Sigma-Aldrich. Metal salts are dissolved in 2-methoxyethanol to generate desired concentration. Also, 60.2 mg ml⁻¹ of In(NO₃)₃·xH₂O solution is used for the InOₓ precursor. Furthermore, 150 mg ml⁻¹ of Al(NO₃)₃·xH₂O solution is used for AlOₓ precursor. For the ITO precursor, 120.4 mg ml⁻¹ of In(NO₃)₃·xH₂O solution and 75.6 mg ml⁻¹ of SnCl₂ solution are mixed in a ratio of 9:1; For the IGZO precursor, 60.2 mg ml⁻¹ of In(NO₃)₃·xH₂O, 51.2 mg ml⁻¹ of Ga(NO₃)₃·xH₂O and 37.8 mg ml⁻¹ of Zn(NO₃)₃·xH₂O are mixed in a ratio of 3:1:1. For the IZO precursor, 60.2 mg ml⁻¹ of In(NO₃)₃·xH₂O and 37.8 mg ml⁻¹ of Zn(NO₃)₃·xH₂O are mixed in a ratio of 7:3. All the precursor are stirred at 25° C. overnight and filtered through 0.20-μm syringe filters before film fabrication.

### Optical Setup for Plasmonic Printing Process

As shown in FIG. 6a, the optical setup includes a fs laser source (Chameleon Ultra II, Coherent) with a pulse duration of 140 fs and a repetition rate of 80 MHz, a pair of linear polarizers (LPVIS, Thorlabs) for intensity control, a convex lens (f=25 mm) to focus the laser spot, and a β-BaB₂O₄ crystal (thickness of 1 mm) in front of the focus for second harmonic generation. The Ag NW-sprayed samples are mounted on a three-axis motorized stage for direct laser printing. The temperature data are recorded using an IR thermal camera (A325sc with Close-up 1×, FLIR). When extracting the temporal morphology, a mechanical shutter with a minimum open duration of ~100 ms is placed right after the β-BaB₂O₄ crystal for required illumination time.

### Plasmonic Printing of MO Thin Films

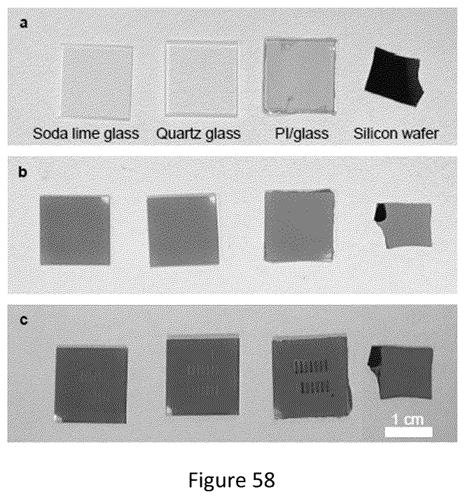

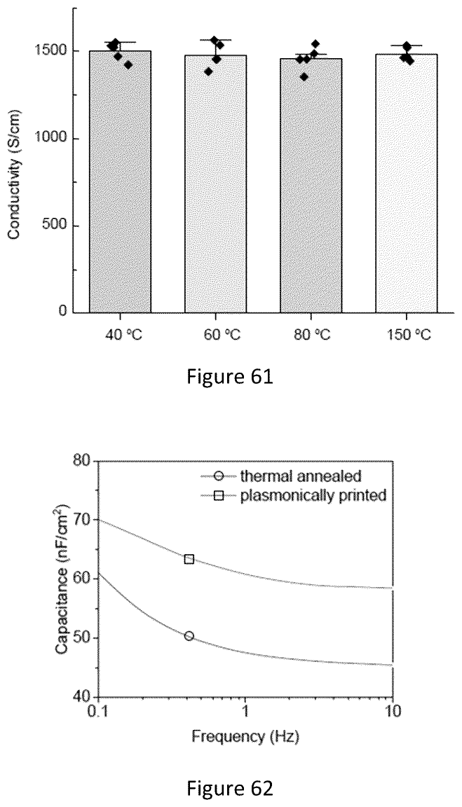

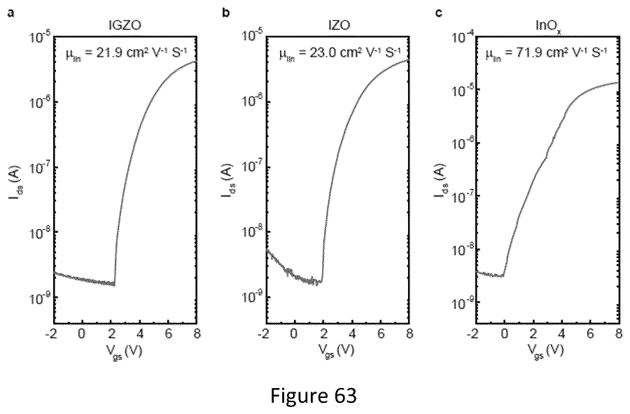

Due to plasmonic heating generating extremely high localized temperatures in a very short time, the thermal stability of the substrate becomes the most critical factor when selecting a substrate. In Supplementary Note 13 and FIGS. 58-60, various substrates are compared for compatibility with the plasmonic printing process, and it is concluded that soda lime glass, with its excellent thermal stability and relatively poor thermal conductivity, is the best choice for this plasmonic printing process. Any subsequent references to glass specifically refer to soda lime glass. The glass substrates (1.5×1.5 cm², 0.7 mm thick) are first solvent cleaned and treated with energetic oxygen plasma for 5 min. For spin-coating fabrication, all the prepared precursors are spin-coated at 2000 rpm for 40 s in a chamber with relative humidity controlled at 20% and dried at 40° C. for 6 h. Note that the drying process here is aimed at removing solvents of the wet precursor film, allowing it to air dry and become more solid for subsequent processing. To achieve a completely dried precursor film, lower dry temperatures require longer durations (40° C. for 6 h), whereas higher dry temperatures require shorter durations (150° C. for 5 min). However, the final device performance remains similar (FIG. 61). If necessary, these processes are repeated to achieve the desired film thickness. Process flow 1 (FIG. 6b) is used for the printing of single, functional MO layers. Ag NW solution (5 mg ml⁻¹ in ethanol) is purchased from XFNANO and used as received. Different thicknesses of Ag NW films, which are measured as per the volume of Ag NW solution sprayed per unit area (20-70 μl cm⁻²), are sprayed onto the precursor film with a discharge speed of 40 ml per 30 s by an IWATA HP-CP spray gun (0.3 mm) at an air pressure of 15 psi. Next, the sample is secured onto a high-precision three-dimensional electrically controlled stage, allowing control over the parameters of the laser spot scanning, including spot size, step size and spot dwell time. After laser scanning, the residual Ag nanostructures are wiped away with a dust-free cloth. For the printing and performance measurements of ITO, the laser spot is scanned along a long and narrow path on the Ag NW film, thereby printing an ITO conductive channel (1.5 mm long, 40 μm wide). Subsequently, with the assistance of a metal mask, 60-nm-thick Cu electrodes are sputtered at both ends of the ITO channel, and the resistance of ITO is measured using a probe station and DAQ6510. As described in the main text, the optimized scanning parameters for ITO are as follows: step size of 50 μm, dwell time of 0 s, Ag NW volume of 50 μl cm⁻² and light intensity of 127.3 W mm-2. These parameters are applied to the preparation of other MOs, with only the light power density being adjusted based on the temperature required for the conversion of different precursors. For the printing and performance measurement of AlOₓ, commercial ITO glass is used instead of pure glass as the substrate, and the AlOₓ precursor film and the Ag NW film are prepared as previously described. Subsequently, laser scanning is performed periodically back and forth on the Ag NW film to scan out a square area of approximately 0.5 mm². Following this, Cu electrodes (0.1×1 mm²) are deposited within the region using a metal mask. Then, J-E, C-V and C-F curves are measured using a Keysight B1500A semiconductor analyzer. For the printing and performance measurements of InOₓ, IZO and IGZO, commercial ITO glass is used as the substrate followed by the fabrication of an ~120-nm 350° C.-annealed AlOₓ film as the dielectric layer. Then InOₓ, IZO and IGZO precursor films and the Ag NW film are prepared as previously described. Laser scanning is performed periodically back and forth on the Ag NW film to scan out a square area of approximately 1 mm². Following this, Al electrodes (W=150 μm, L=100 μm) are deposited within the region using a metal mask by an electron beam. Then, the transfer and output characteristic curves are measured using Keysight B1500A semiconductor analyzer. The μₛₐₜ values in the saturation regime are calculated using the standard equation:

$${I}_{D} = \frac{W}{2 L} {μ}_{sat} {C ( {V}_{G} - {V}_{T} )}^{2} ,$$

where I_{D} is the source-drain current; C is the capacitance per unit area of the dielectric layer; V_{T} is the threshold voltage; V_{G} is the gate voltage; and W and L are the channel width and length, respectively. The average quasi-static capacitance of the high-temperature-annealed AlOₓ films (49 nF cm⁻² over 0.1-10 Hz; FIG. 62 and Supplementary Note 14) was measured by Novocontrol Concept 80 under 0.5 V, which was used to calculate the saturation mobility for all the transistors based on individually plasmonically printed semiconductors. To better evaluate the intrinsic mobility of the semiconductor channel, the linear mobility of the transistor is also calculated and thoroughly discussed (FIG. 63 and Supplementary Note 14).

### Plasmonic Printing of MO TFT Array and Logic Gates

The fabrication of precursor film is the same as described above. As shown in FIG. 6b, process flows 2 and 3 are used to fabricate the MO arrays. In process flow 2, photolithography is applied to pattern the precursor film. AZ 4620 (AZ Electronic Materials) is spin coated at 3000 rpm for 40 s on the precursor film, annealed at 100° C. for 5 min and exposed to ultraviolet light through a designed photomask. After development in the AZ 400K developer (volume ratio of 1:4 with water), the substrate is immersed in 3% w/v OA for 10 s to remove the exposed precursor film. Subsequent removal of residual photoresist is carried out using acetone, resulting in the desired precursor array geometry. Next, a certain thickness of Ag NW film (50 μL cm⁻²) is sprayed onto the substrate. The laser spot is then programmed to scan only the areas with precursor arrays, followed by wiping off the residual Ag nanostructures. This process is repeated to fabricate multilayered MO functional layers. Finally, Ag electrodes are fabricated by electron beam and patterned by photolithography. The transfer curves of the 10×10 MO transistor array and high-density MO transistor are measured by Keysight B1500A semiconductor analyzer. The average quasi-static capacitance of the plasmonically AlOₓ films (64 nF cm⁻² over 0.1-10 Hz; Supplementary Note 14) is used for saturation mobility calculation of the transistor array. The resistance values of 100 ITO gates are measured at their diagonal positions using a two-probe method. The C-V and C-F characteristics of 100 AlOₓ films are measured by the Keysight B1500A semiconductor analyser after plasmonically printing AlOₓ arrays on ITO glass and then depositing the metal electrodes. Process flow 2 is also applied to fabricate the logic gates as described above. The logic function of the devices is tested by an oscilloscope. In process flow 3, after preparation of the precursor film, 50 μl cm⁻² of the Ag NW film is sprayed onto the precursor film with the designed metal mask to form a patterned Ag NW film array (FIG. 50). Subsequently, the laser spot is programmed to scan only the areas with Ag NWs. After wiping the residual Ag nanostructures, the substrate is immersed in 3% w/v OA for 10 s to remove the unconverted precursor film, leaving behind the converted MO. In the experiment of comparing the structural properties between plasmonically printed MO and commercial customized MO by using vacuum-based methods, the commercial ITO film is fabricated using a robust vacuum sputtering process, and the patterning of ITO is achieved via laser etching technology.

### Film Characterization

The TOF-SIMS results are measured using ION TOF-SIMS 5. The XPS results are measured using Thermo Fisher ESCALAB 250Xi. The vacuum level in the analysis chamber is maintained at 8×10⁻¹⁰ Pa, and the excitation source utilizes Al Kα radiation (hv=1,486.6 eV). GIAXRD measurements are conducted by a Rigaku SmartLab device (9 KW). All the MO samples used for the XPS and GIAXRD measurements are printed using optimal printing parameters. The surface morphologies are measured using top-view SEM (FEI Quanta 450 FESEM) and optical surface profiler.

### Electric Field Simulation

The electric-field distribution in two intersecting Ag NWs is simulated using finite-difference time-domain to build infinitely long nanowires. The incident light is a plane wave. To mimic the randomly oriented Ag NWs within the network, the incident polarization is set at 45° with respect to the axis of one NW, and the angle of intersection between the two NWs varies from 0° to 90°. No substrate is built in the simulation model since the Ag NWs are mostly floating unless intersecting with other wires. For the short Ag NWs with side dumbbells, the size of side dumbbells increases when reducing the length of the middle part, to maintain the total amount of Ag. In this case, a glass substrate is built in the model since these structures would not float. An air gap of 2 nm is set between the glass substrate and the structures to avoid singularities in the simulation.

### Light Absorption and Heat Generation Simulation

To depict the morphology-driven heating processes, multiphysics simulations (COMSOL) are performed for four states of the Ag nanostructures (before and after light illumination for 0.1 s, 1 s and 10 s). The simulated structures are built within a 2 μm×2 μm area based on the SEM images. Two ‘electromagnetic waves, frequency domain’ modules are applied to obtain the volumetric light absorption intensity of the structures. The first step only consists of air and glass for calculating the reflection of an incident transverse-electric wave by the substrate, which is then utilized, in the second step, as a background field for simulating the scattering field and power loss density of the Ag nanostructures on the substrate. The incident light intensity is set as 636 W m⁻². The refractive index of Ag is obtained from ref. 61, and the refractive index of glass is set as 1.45. Afterwards, the ‘heat transfer in solids and fluids’ module is applied to obtain the temperature distribution by inputting the volumetric heat source obtained above. The environmental air speed and ambient temperature are set as 0.1 m s⁻¹ and 293.15 K, respectively.

### Supplementary Information

### Supplementary Note 1 Impact of UV Light on ITO Films

Previous reports have demonstrated that UV irradiation can induce photochemical reactions to facilitate M-O-M lattice formation and film densification⁽¹⁻³⁾. It is found that the absorption of ITO film around 400 nm wavelength increases greatly after over 350° C. annealing treatment (FIG. 26). Here, a BBO crystal is utilized for second harmonic generation. When illuminated by 800 nm laser at highest power, the second harmonic generation is ~0.5% at wavelength of 400 nm. Such light intensity of 400 nm is insufficient for heat generation and hardly influences the optothermal effect at 800 nm. We prepared 40° C. dried ITO precursor film and 350° C. annealed ITO films (15 k (2 between 2 mm distance) respectively, followed by irradiation with pure 800 nm fs laser and a combination of 800+400 nm wavelength fs laser (FIG. 27). For dried ITO precursor film, neither wavelength of light has shown any positive effect on it, as no conductivity or resistance values could be measured. This could be attributed to the low absorption of light of dried ITO film. For 350° C. annealed ITO film, as shown in FIG. 11a-c, after irradiation with pure 800 nm laser light, the resistance of ITO remained virtually unchanged. In contrast, irradiation with mixed laser leads to a significant decrease in the resistance of ITO, with the extent of decrease increasing with higher light intensity and longer irradiation duration. Under irradiation of 800+400 nm laser with 127 W/mm² light intensity for 5 minutes, the resistance of ITO decreased to 50.9% of its initial value.

### Supplementary Note 2 Superiority of the Plasmonic Printing Process Over Laser Annealing Process

Pulsed lasers have been utilized in laser annealing process⁽⁴⁻⁷⁾ for low-temperature fabrication of MO thin films. Laser induced photothermal effect can directly heat the precursor film to facilitate MO formation. However, the single-pulse energy density is required at tens to hundreds of mJ/cm² in laser annealing process to achieve desired performance of MO, due to the low photothermal efficiency of the MO precursors. In contrast, owing to the high photothermal efficiency of the plasmonic structures, the maximum single-pulse energy density for the proposed plasmonic printing process is only 150 μJ/cm², which is far lower (>two orders of magnitude) than the laser annealing process. This also explains why, in the experiments, pure 800 nm or 800+400 nm light has no effect on the 40° C. dried and Ag NWs-free MO precursor films (FIG. 11a-c)—the far lower single-pulse energy density fs laser we used cannot achieve the laser annealing effect. On the other hand, the mixed light (800+400 nm) has a positive effect on the 350° C. annealed and Ag NWs-free MO thin films. This is due to the increased absorption at 400 nm of the MO films annealed at 350° C., leading to photochemical reactions induced by the 400 nm light. Though the photon energy of 400 nm light is not that high, the photon fluence (60 W/cm²) or irradiation dose (0.3-3.8 MJ/cm²) is far higher than previously reported values for UV induced photochemical reactions^{(1, 2, 6)}. Therefore, from the perspective of laser power, the 400 nm light induced photochemical reactions play the main role in enhancing the quality and the performance of MO thin film.

Furthermore, this also highlights the significant advantage of the proposed plasmonic printing process compared to the reported laser annealing processes, which is the high energy conversion efficiency. By introducing plasmonic local heating, we achieve an energy amplification effect, efficiently converting light energy into heat. Combined with the photochemical effects of 400 nm light, this ultimately leads to high performance of MO thin films (FIG. 29). In contrast, laser annealing process is limited by low light absorption of the precursor films and the process itself, resulting in a significant waste of light energy, similar to the substantial thermal energy waste observed during traditional high-temperature annealing.

### Supplementary Note 3 Comparison Between fs and CW Lasers.

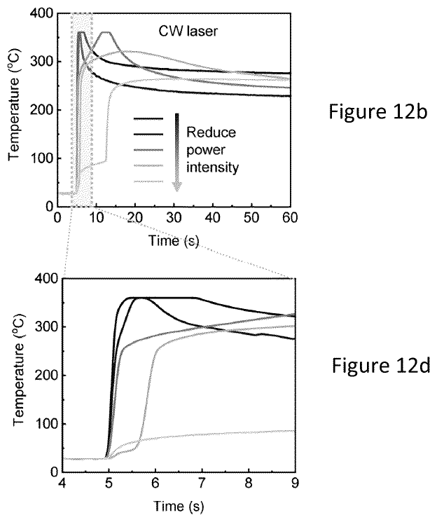

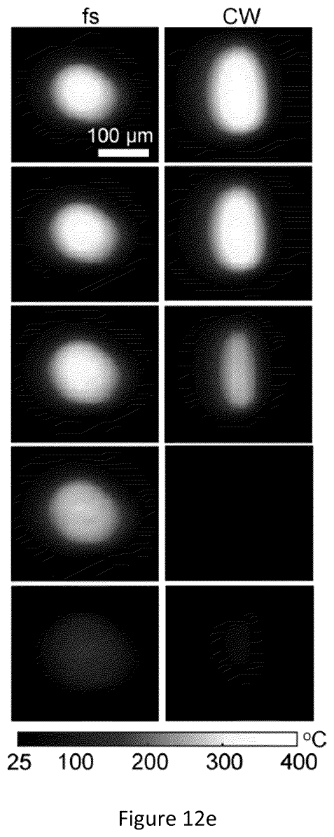

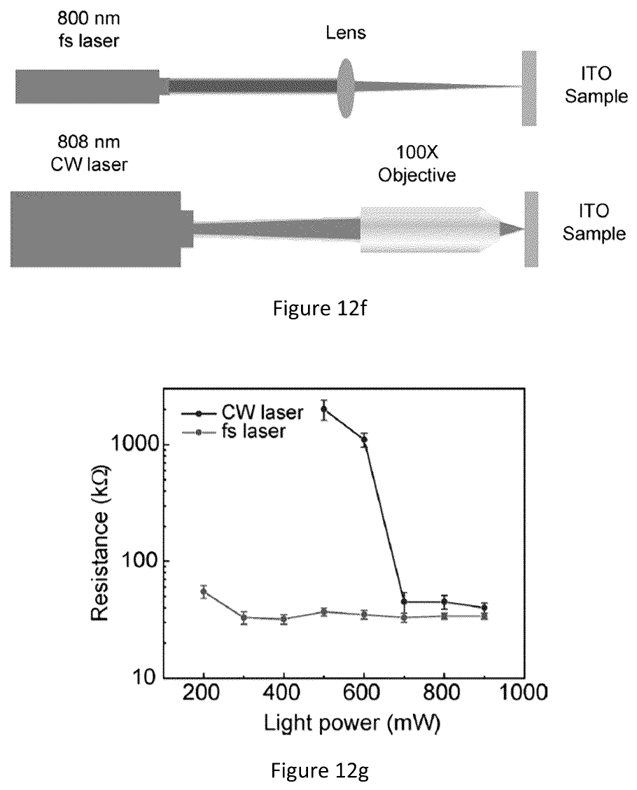

Since the single-particle temperature rise is negligible, heat diffusion and collective thermo-plasmonic response within the illuminated region are considered to be responsible for either morphology evolution of Ag NWs or thermal treatment of metal oxide films. Assuming a periodic array of small and dense plasmonic particles, the collective contribution on steady state temperature rise can be expressed as⁽⁸⁾:

$$Δ {T}_{0}^{c o l} \approx \frac{{σ}_{a b s} P}{{k}_{eff}} \frac{1}{π DA} ( 1 - \frac{2 \sqrt{A}}{\sqrt{π} D} )$$

where σ_{abs} is the absorption cross section of each particle. P is the averaged power intensity of illumination. k_{eff} is the effective thermal conductivity of the surrounding environment of the plasmonic array. D and A are the diameter of laser spot and period area of the unit cell, respectively. It's worth noting that in such cases, both fs and CW lasers lead to the same collective temperature rise since heat accumulation over nanosecond is required. Fs laser always provides better heat localization spatially and temporally, which is supposed to be more favored for plasmonic printing^{(9, 10)}. To determine the better light source in some embodiments of the invention, the fs laser at 800 nm is compared with a CW laser at 808 nm from both heating processes, including temperature rise and morphology evolution, as well as the printing results. The optical setups for two lasers are illustrated in FIG. 12f, the laser spot area at ITO sample is adjusted to be the same for two lasers for direct comparison. As shown in FIG. 12a-d, the slope of temperature rise for fs laser irradiation is rapid and consistent for all power intensity. Notably, due to the time resolution and range limitations of the infrared camera, it may not be able to capture the highest temperature exhibited by the sample under fs laser irradiation. While it reduces before achieving the maximum temperature for CW laser. This slope variation is ascribed to the slow and unconfined heat generation that drives morphology evolving into sparse particles and even particle clusters (see FIG. 30), which in turn reduces the plasmonic heating effect. Evidence can also be found in FIG. 3l and FIG. 12e. No stacked clusters are formed for spatially and temporally localized heating under fs laser while numerous particle clusters are formed for fully non-localized heating through a hot plate in FIG. 3l. The CW laser provides partially localized heating and generates a few amounts of particle clusters. Moreover, in FIG. 12e, the hot-spot size under fs laser illumination is invariant for all power intensities, indicating superior heat localization which is preferred for on demand plasmonic printing of metal oxide electronics. While for CW laser, the hot-spot size shrinks with reducing power intensity since heat diffuses faster with higher power under deficient heat localization. Finally, the electric properties of printed ITO films under two lasers are also compared. The results in FIG. 12g reveal lower resistances as well as incident power threshold for fs laser. Therefore, fs laser is selected as the light source for plasmonic printing.

### Supplementary Note 4 Optimization of the Laser Scanning.

The wavelength selection of the fs laser is the first consideration. As shown in FIG. 11d, the optical absorption spectra of Ag NWs films are measured at different thicknesses. It can be observed that the absorption of the Ag NWs film within the wavelength range of 300-900 nm increases with thickness. However, there is no significant shift in the position of the absorption peak. Therefore, at this point, the plasmonic local heating generation of the Ag NWs with certain thickness is mainly influenced by the power of the light source. FIG. 11e illustrates the conductivity of ITO printed using lasers with different primary wavelengths (710-850 nm) with a power of 1 W. It can be observed that before 830 nm, the ITO conductivity remains around 82 S/cm with a highest ITO conductivity of 88 S/cm at 800 nm wavelength. When the wavelength is larger than 830 nm, the ITO conductivity decreases with wavelength. FIG. 11f shows the power of the light source of different wavelength. As the power of the light source is highest at 800 nm, capable of generating more possible plasmonic local heating, we chose 800 nm as the primary wavelength for the laser source. Next, the light intensity of laser source directly affects the heat generation intensity of Ag NWs. As shown in FIG. 11g, with the increase in light intensity, the conductivity of the printed ITO channels also rises. At a light intensity of 127.3 W/mm², the conductivity reaches its maximum value of 105.8 S/cm. However, further increasing the light intensity will generate excessive plasmonic local heating, which even damages the ITO and the underlying glass substrate (FIG. 11g and FIG. 32), leading to a sharp decrease in the conductivity of ITO.

As shown in FIG. 35, unlike ITO, testing the performance of the plasmonically printed AlOₓ and IGZO films requires the deposition of surface electrodes. Therefore, AlOₓ or IGZO films of appropriate square sizes are prepared through repeated laser scanning. During this periodic scanning process, the spacing (D) between laser scan paths is a critical factor in forming a complete film. For AlOₓ and IGZO films, the laser spot diameters were 170 μm and 110 μm, respectively.

In FIG. 36, we tested the dielectric properties of the AlOₓ films printed with various laser path spacings, ranging from 25 μm to 150 μm. When the path spacing was 150 μm, although the laser paths fully covered the printed area, the quality of alumina printed at the edges of the laser spot was compromised, likely due to insufficient temperature. As a result, significant fluctuations in capacitance were observed in the low-frequency region (<10,000 Hz) or under high voltages (>1 V), with leakage phenomena (negative capacitance values) also occurring. As the laser path spacing decreased, the quality of the plasmonically printed AlOₓ film improved progressively. The best performance was achieved with spacings of 100 μm and 75 μm, which both exhibited stable C-V and C-F dielectric properties. However, as the spacing continues to decrease, the dielectric properties of the plasmonically printed AlOₓ films become unstable again. When the spacing was further reduced to 25 μm, the quality of the plasmonically printed AlOₓ films declined sharply, leading to significant fluctuations in both C-V and C-F tests. This phenomenon is similar to the sharp decrease in conductivity observed in ITO under smaller laser spot step sizes (FIG. 11h). It is caused by excessively small laser spot spacings, which lead to the transformation of plasmonic heat-generating nanostructures from being composed of Ag NWs to predominantly irregular ellipsoidal shapes, thereby reducing the heat generation capacity during laser scanning. Additionally, excessively small scanning spacings dramatically increase the time required to fabricate films of the same area. Taking all factors into consideration, a spacing of 75-100 μm is the optimal choice.

When printing IGZO, we first optimized the light intensity used (FIG. 39). At a light intensity of 14.1 W/mm², the plasmonic heat generated was insufficient to fully convert the IGZO precursor, resulting in low film quality with significant leakage currents. This led to a high off-state current for the transistor under negative voltage. As the light intensity gradually increases, the quality of the plasmonically printed IGZO films improved. At a light intensity of 20.8 W/mm², transistors based on the plasmonically printed IGZO began to exhibit well-defined characteristic transfer curves of n-type transistors, with a mobility of 12 cm²/V·S. When the light intensity was further increased to 28.2 W/mm², the corresponding transistors showed a more stable off-state current, with mobility increasing to 22.8 cm²/V·S. However, further increasing the intensity to 33.5 W/mm² did not lead to a noticeable improvement in IGZO transistor performance. To avoid energy waste, 28.2 W/mm2 was determined to be the optimal choice.

The laser path spacing parameters for printing IGZO films are also optimized (FIG. 40). Unlike alumina, IGZO requires a higher conversion temperature, and incomplete conversion or the presence of defects significantly increases the transistor's leakage current. When the laser path spacing is 125 μm (greater than the laser spot diameter of 110 μm), the presence of unconverted IGZO precursors results in very high leakage currents across the entire bias voltage range. At a spacing of 100 μm, the leakage current is noticeably reduced but remains significant under off-state voltage. When the spacing is reduced to 75 μm or 50 μm, the transistors exhibit well-defined characteristic transfer curves of n-type semiconductors, with mobility values of 22.1 cm2/V·S and 16.1 cm2/V·S. However, further reducing the spacing to 25 μm causes a sharp decline in the quality of the IGZO films, similar to the behavior observed in alumina and ITO. This is due to reduced heat generation capacity, leading to a dramatic increase in leakage current and the complete loss of transistor characteristics. Overall, a spacing of 75 μm is the optimal parameter for printing IGZO.

### Supplementary Note 5 Negative Differential Resistance of IZO and InOₓ Transistors.

The observed negative differential resistance behavior originates from temporal instabilities caused by trap states inherent to IZO and InOₓ materials.^{11, 12} These materials inherently contain certain defects, such as oxygen vacancies or interface traps, which would have minimal impact on carrier transport at low source-drain and gate voltages, leading to negligible NDR effects. However, under high source-drain voltage, the strong electric field in the channel significantly enhances hot-electron effects, allowing carriers to gain sufficient energy to activate/occupy these trap states or generate new traps at the semiconductor/electrode interface, thereby reducing the number of conductive carriers and suppressing current growth. Additionally, the increased carrier concentration at high gate voltage further exacerbates this dynamic process, leading to a more pronounced NDR phenomenon.

### Supplementary Note 6 Comparison Between the Plasmonic Printing Process and Thermal Annealing.

The plasmonically printed materials demonstrate superior figures of merit compared to solely thermally annealed materials due to the unique advantages of plasmonic local heating combined with UV-induced photochemical activation. While both approaches involve thermal treatment, the proposed method offers significant benefits over conventional thermal annealing.

First, the plasmonic printing process integrates plasmonic local heating with UV-induced photochemical activation. While the localized plasmonic heating raises the precursor temperature, the simultaneous UV exposure facilitates additional photochemical reactions that further improve film quality. This dual mechanism improves key properties of MO films such as conductivity, dielectric constant, and mobility, making plasmonically printed MOs outperform those produced by purely thermal annealing under equivalent temperature conditions.

Second, traditional thermal annealing mainly relies on bulk heating of an entire sample with a hotplate. Reaching the temperatures required for producing high-quality amorphous MO films (typically above 350° C.) can take a considerable amount of time; for example, it takes about 10 minutes for the hotplate we used to reach the target temperature and at least another 30 minutes to anneal the sample to produce high quality MO films. Additionally, conventional hotplates are typically incapable of achieving higher temperatures needed for forming partially crystalline structures, such as ITO films (above 550° C.). Notably, cooling after annealing also takes substantial time. In contrast, the proposed plasmonic printing process can generate local temperature rises exceeding 350° C. within just 0.3 seconds, and increasing the light intensity can further raise the local temperature. Furthermore, the highly localized nature of plasmonic heating allows for rapid cooling immediately after the treatment, significantly reducing the overall processing time. While further increasing the temperature in traditional methods (e.g., using a tube furnace) could improve ITO properties, this would come at a significantly higher cost and complexity.

Third, conventional thermal annealing cannot achieve patterned MO thin films directly because the entire sample is uniformly heated. Therefore, patterning must be achieved through additional post-processing steps. The proposed approach, however, leverages the spatial localization of plasmonic heating, enabling rapid and straightforward patterning of MO films by scanning the focused laser spot.

Fourth, conventional thermal annealing is inherently energy-inefficient, as a significant amount of heat energy is lost to the surroundings. In contrast, the proposed plasmonic printing method utilizes the energy amplification effect of plasmon resonance to maximize the conversion of light energy into localized heat, which is then efficiently used for MO formation. This approach minimizes energy waste and hence optimizes energy utilization.

These advantages collectively highlight why plasmonically printed materials exhibit better figures of merit compared to those fabricated using conventional thermal annealing methods. Furthermore, future optimizations, such as increasing the localized heating temperature, may further improve the performance of metal oxide films fabricated with the proposed approach.

### Supplementary Note 7 Influence of Precursor Chemistry on Light Intensity for Plasmonic Printing of Different MOs.

Different MO compositions do have distinct precursor properties. Regarding the solubility issue, we employed a conventional sol-gel method, which has been extensively studied and optimized for various MO compositions. In the proposed work, the precursors of different MOs exhibit excellent solubility in the selected solvent systems and concentrations (as described in Methods), forming stable and homogeneous precursor solutions. This process ensures the fabrication of uniform precursor thin films across different MO compositions, which is critical for the subsequent plasmonic printing process.

Regarding the thermal reactivity issue, different MO compositions require distinct annealing temperatures to achieve optimal material properties, primarily due to the decomposition behavior of their precursors and the specific energy needed to form a dense metal-oxygen-metal (M-O-M) framework. For example, ITO precursors, often comprising organic ligands and metal complexes, require high annealing temperatures (~550° C. or above). At these temperatures, complete decomposition of organic ligands and crystallization of InOₓ occur, alongside the incorporation of Sn atoms into the lattice to achieve the desired high conductivity and optical transparency. In contrast, IGZO precursors typically require annealing temperatures in the range of ~350-400° C. This is because IGZO functions effectively in its amorphous state, which forms at lower energy levels compared to the crystalline structure of ITO. Furthermore, AlOₓ can be processed at even lower temperatures (~250-300° C.) because of its simple precursor composition, and it primarily forms a dense and stable amorphous structure that does not rely on extensive crystallization or secondary phase formation. Despite these differences, the plasmonic printing process effectively adapts to the specific requirements of different MOs by precisely tuning the light intensity to provide the required thermal energy for each material's transformation. For example, the optimized light intensity used for ITO is 127.3 W/mm², for IGZO 28.2 W/mm² and for AlOₓ 8.6 W/mm². Aside from adjusting the laser energy input to match the specific thermal requirement of each MO precursor, no other significant changes to other processing parameters are needed.

Although the plasmonically printed ITO films exhibit electrical properties comparable to those produced via vacuum methods, further enhancement is limited by the glass substrate used in our study. Glass is susceptible to damage under localized high-temperature conditions when the light intensity is above 146.4 W/mm², limiting the achievable performance of plasmonically printed ITO. To overcome this limitation, future research could explore substrates with higher tolerance to localized heat, with a hope of unleashing the full potential of plasmonic printing.

### Supplementary Note 8 the Environmental and Thermal Cycling Stability of Plasmonically Printed MOs.

The plasmonically printed high-quality MO thin films exhibit excellent long-term electrical stability. In the long-term stability test, we exposed the plasmonically printed ITO, AlOₓ, and IGZO samples to an environment with a temperature of 24° C. and a humidity of 50%, and tested their long-term electrical stability. As shown in FIG. 42, all samples maintained good electrical performance over a period of 21 days, with almost no degradation compared to their initial values. This can be attributed to the intrinsic long-term stability of MO under ambient environment and the high quality of the plasmonically printed MO thin films.

Thermal cycling tests were also conducted on the plasmonically printed MOs by placing the samples on a hot plate at 200° C., holding for 2 minutes, then rapidly cooling them to room temperature, and repeating this process multiple times while recording the electrical performance of the MOs after several cycles. As shown in FIG. 42, all plasmonically printed MOs exhibit excellent thermal stability, with their electrical performance remaining unchanged as the number of cycles increases. Since the proposed plasmonic printing process was performed on rigid glass substrates, no related mechanical performance tests were conducted.

### Supplementary Note 9 Uniformity and Precision of Plasmonic Printing Process Over Large Areas.

The proposed plasmonic printing process ensures uniformity and precision for multiple scale MO fabrication from the following aspects. On the one hand, the uniformity of MO precursor films is achieved through a conventional spin-coating method, which is well suited for preparing thin films on large-area substrates. On the other hand, during the printing process, precise scanning of the focused laser beam is controlled by a high precision motorized 3D stage, ensuring consistent and uniform laser scanning over long distances and large areas.

Another key factor for large-area MO fabrication is the uniformity of Ag NW thin films produced by spray coating. As shown in FIG. 44, a large-area Ag NW thin film was successfully fabricated on a 4-inch glass substrate. To evaluate its uniformity, we randomly selected 30 locations across the substrate, removed the Ag NWs to expose the substrate, and measured the thickness of the Ag NW film. The results in FIG. 45 demonstrate that the Ag NW film maintains excellent uniformity over the whole substrate, ensuring consistent and uniform plasmonic heating for MO fabrication. Thus, the proposed plasmonic printing process can guarantee uniformity and precision of large-area MO fabrication, which is supported by robust control over each fabrication step.

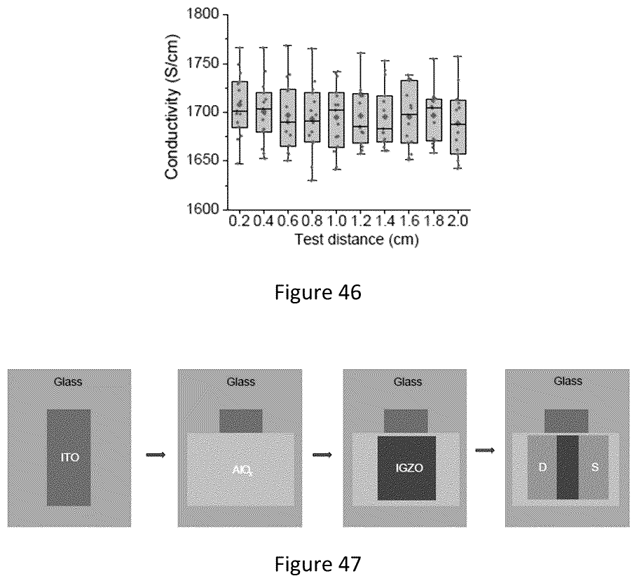

Additionally, 15 conductive ITO channels (each 2 cm long) were printed on the 4-inch glass substrate. We measured their conductivity at different probe distances with a 200 μm interval. As shown in FIG. 46, the plasmonically printed ITO channels exhibit high conductivity and good uniformity over the entire length of each channel. These results collectively demonstrate the scalability and practicality of the proposed plasmonic printing process for large-area MO fabrication.

### Supplementary Note 10 the Minimum Feature Size and Edge Precision of Plasmonic Printing Process.

As shown in FIG. 6b, three different plasmonic printing process flows are developed. In Process Flow 1, neither the Ag NWs nor the MO precursor film was pre-patterned, and patterning of the MO film is achieved by the “plasmonic hot spot” generated through laser scanning with appropriate light intensity and scanning parameters. Therefore, the smallest feature size and edge precision, which are 25 μm and ±4 μm respectively (FIG. 51), are determined by the heat generation process under laser scanning. This process is closely related to both the Ag nanostructures and scanning parameters, which is discussed in detail in Supplementary Note 10.

In Process Flow 2, patterning of the MO film is pre-determined by patterning the MO precursor film using conventional photolithography. As a result, the minimum feature size achievable in this process is limited by the resolution of the photolithography technique used, with the smallest achievable pattern size and edge precision being 20 μm and <1 μm (FIG. 52).

In Process Flow 3, patterning of the MO film is determined by the pre-patterned Ag NW film, which is created through spray coating with the assistance of a custom designed metal mask. Consequently, the minimum achievable pattern size is determined by the resolution of the metal mask, with the smallest pattern size being 100 μm. However, the resulting pattern exhibits relatively rough edges (FIG. 50), which may be caused by incomplete adhesion of the metal mask, leading to solution diffusion at the edges of the mask pattern or uneven spraying. This results in uneven edges in the Ag NW pattern, causing non-uniform heat generation at the edges.

The Ag NW morphology does not significantly affect the resolution. The pristine Ag NWs were randomly oriented and stacked after being spray-coated onto the sample. Since the diameter of the Ag NWs (~30 nm) is much smaller than the laser spot (>50 μm in diameter), their randomly distributed morphology is effectively uniform for heat generation and has negligible influence on the pattern resolution of the underlying MO films.

### Supplementary Note 11 the Role of Laser Spot Size, Scanning Speed, and Dwell Time in Defining Patterning Resolution.

The laser spot has a round shape with a Gaussian-like intensity profile. The light intensity at the center of the spot is higher than that at the edges (see FIG. 51a). As a result, the heat generation efficiency is greater at the center and gradually decreases towards the edges, leading to non-uniform morphological evolution of the Ag nanostructures in the laser-irradiated regions (see FIG. 18 and FIG. 33). A smaller laser spot size with higher light intensity can improve the minimum feature size and edge precision. Thus, the optimized scanning parameters include a step size of 50 μm, which is determined by the minimum laser spot size (~50 μm), and the scanning speed is primarily governed by the step size.

To further investigate the relationship between laser spot size, minimum feature size, and edge precision, we prepared plasmonically printed ITO films with varied laser spot size. As shown in FIG. 51, six ITO precursor films, spray-coated with the same amount of Ag NWs, were scanned at different positions relative to the focal plane of the laser beam. After wiping away the Ag nanostructures and removing the unmodified MO precursor film by immersing it in 3% w/v OA, the plasmonically printed ITO regions were observed under an optical microscope. As shown in FIG. 51, the plasmonically printed ITO region which was scanned at the focus plane (i.e. position 1) exhibits the minimum linewidth of 25 μm and an edge precision of approximately 4 μm. This linewidth is substantially smaller than the laser spot size, since the Ag nanostructure evolution near the edge of the laser spot does not provide sufficient thermal treatment. The stepping process of the laser spot can be clearly observed. Notably, the optical setup can be further improved to focus or shape the laser spot, thereby reducing the minimum feature size and improving edge precision.

When the samples were scanned at de-focused positions (i.e., positions 2-3), the linewidth of the ITO region increases, and the edge precision also decreases with the laser spot size. Beyond the central region of the laser spot, which generates sufficient heat, and the edge region, which cannot provide thermal treatment, there is an intermediate region that offers insufficient heat generation and thermal treatment, causing partial crystallization of the ITO precursor. When the sample is farther from the focus plane (i.e., positions 4-6), this intermediate region becomes more prominent as the light distribution becomes more gradual.

Although the light intensity at the laser spot edge may not be sufficient for heat generation, a longer dwell time can compensate for this (see FIG. 33). However, to achieve high scanning speed and ensure desired performance of plasmonically printed MO, the scanning dwell time in the main text is optimized to 0 s.

### Supplementary Note 12 Comparison of Structural Properties Between Plasmonically Printed MO and Commercial Customized MO by Vacuum-Based Methods.

The plasmonically printed MO thin films exhibit advantages in terms of structural properties (film uniformity, surface roughness) when compared to those prepared using vacuum-based methods. As a control, we custom-ordered a batch of patterned ITO glass with dimensions of 1.5×1.5 cm² from the market. The customized ITO film was patterned by laser etching technology on commercially sputtered ITO. The customized pattern consisted of a 200×400 μm² square block and a combination of the digits “9” and “3” with a line width of approximately 50 μm. Similarly, we used plasmonic printing process to fabricate patterned ITO films with the same design for comparison.

As shown in FIG. 53, surface morphology analysis of the ITO patterns produced by both processes was performed using an optical profiler. The commercially customized ITO glass successfully produced large-scale square patterns; however, the pattern edges were significantly rough. Moreover, when fabricating smaller and more intricate patterns such as the digits “9” and “3,” severe distortion occurred. Notably, the high laser power in their process, required to completely etch the stable ITO layer, caused substantial etching of the glass substrate, leading to a highly rough substrate surface. This roughness can impose significant limitations on subsequent thin-film processing. Despite these drawbacks, such commercially customized ITO glass remains highly expensive.

In contrast, the patterned ITO film fabricated using plasmonic printing process exhibited highly uniform edges and enabled the creation of complete, smooth “9” and “3” patterns. Additionally, the proposed process is more cost-effective and efficient.

Furthermore, the surface roughness of the ITO film fabricated via the vacuum sputtering is slightly higher than that of the ITO film produced using plasmonic printing process, with an Rₘₛ of 1.8 nm compared to 1.1 nm.

### Supplementary Note 13 the Thermal Stability of Various Substrate Types During Plasmonic Printing Process.

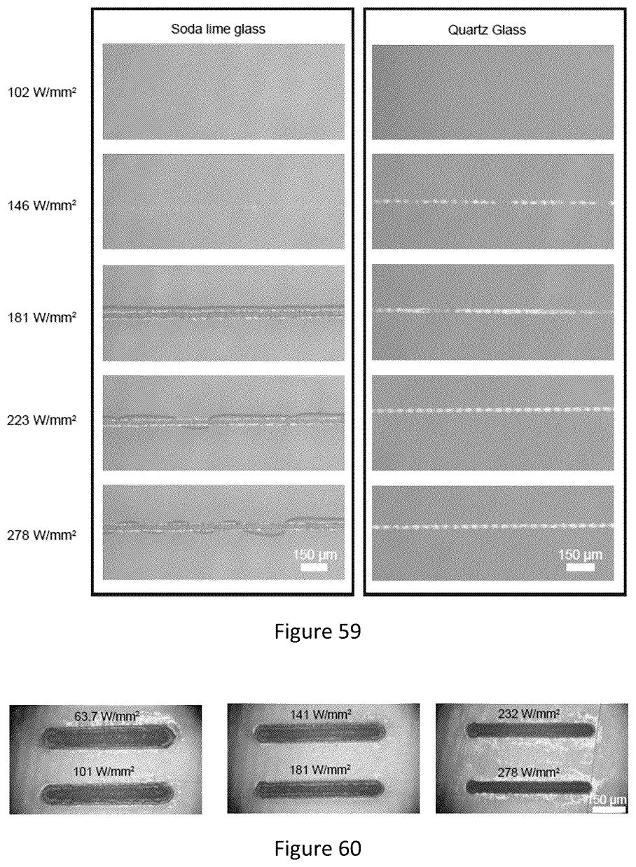

During the plasmonic printing process, we used regular soda-lime glass, which exhibits a certain tolerance to localized high temperatures. In addition to regular soda lime glass, three commonly used substrates are introduced: quartz glass, polyimide (PI, attached to a glass substrate to facilitate the spraying of Ag NW thin films), and silicon wafers for thermal stability comparison. As shown in FIG. 58, approximately 700 nm thick Ag NWs were sprayed onto different substrates (only the substrates were involved, without any MO) and exposed to fs laser with varying light intensities. Subsequently, the Ag NW thin films were wiped off, and the irradiated regions of the substrates were examined under a microscope to observe morphological changes. As illustrated in FIG. 59, soda-lime glass and quartz glass exhibited similar thermal stability. When the light intensity was less than 102 W/mm², the substrates maintained an intact surface. However, at a power density of 146 W/mm², signs of slight localized damage due to high temperatures began to appear on the substrate surface. Further increasing the light intensity resulted in complete destruction or even indentation of both glass substrates due to excessive localized heat. Nevertheless, the thermal stability of glass is sufficient to withstand the plasmonic printing of conductivity comparable to that of ITO prepared by vacuum methods and significantly exceeds the temperatures required for AlOx and IGZO. As shown in FIG. 60, the thermal stability of PI was significantly inferior to that of the glass substrates. A power density of 63 W/mm² was sufficient to fully carbonize PI. Adjusting the light intensity or reducing heat concentration may potentially improve the thermal tolerance of PI. However, at all light intensities, the localized heating induced by laser-excited plasmonic effects did not leave any trace on the silicon wafer. To investigate the cause of this phenomenon, we recorded thermal imaging video of the silicon wafer during the illumination process. Infrared data analysis revealed that, due to the excellent thermal conductivity of the silicon wafer, its temperature mildly increased and expanded to surrounding areas. The result indicates that the heat generated by laser excitation of Ag NWs dissipated and conducted rapidly across the silicon wafer. Moreover, the final stable temperature of the silicon wafer was only around 60° C., making it unsuitable for use in the plasmonic printing process.

### Supplementary Note 14 Mobility Calculations of Transistors.

The migration of ions can lead to instability in the dielectric performance of AlOₓ films in the frequency domain¹³, a phenomenon also observed in both plasmonically printed and high-temperature annealed AlOₓ film (FIG. 3f and FIG. 38a-b). To avoid overestimating the mobility, we conducted quasi-static capacitance measurements (0.1-10 Hz) on both high-temperature annealed AlOₓ films and plasmonically printed AlOₓ films in FIG. 62. The extracted average capacitance values within this frequency range are 49.4 nF/cm² for the high temperature annealed AlOₓ film and 64.1 nF/cm² for the plasmonically printed AlOₓ film, which were then used for mobility calculations.

FIG. 63 shows the transfer characteristics of plasmonically printed IGZO, IZO, InOx channel-based transistors in the linear regime (V_{ds}=1V). The linear mobility (μₗᵢₙ) was calculated by the following equation:

$${I}_{D} = \frac{W}{L} {μ}_{lin} C ( {V}_{G} - {V}_{T} ) {V}_{ds}$$

where I_{D} is the source-drain current, C is the capacitance per unit area of the dielectric layer, V_{T} is the threshold voltage, V_{G} is gate voltage, V_{ds} is the drain-source voltage, W and L are the channel width and length, respectively. The calculated μₗᵢₙ of the plasmonically printed IGZO, IZO, InOₓ channel-based transistors under V_{G}=8V (consistent with the calculation of saturation mobility) are 21.9 cm² V⁻¹ s⁻¹, cm² V⁻¹ s⁻¹, 23.0 cm² V⁻¹ S⁻¹ and 71.9 cm² V⁻¹ S⁻¹, respectively. The calculated μₗᵢₙ values generally agree with the calculated saturation mobility (μₛₐₜ), with the IZO and InOₓ based transistors showing slightly larger Min than μₛₐₜ (μₛₐₜ=19.2 cm² V⁻¹ S⁻¹ for IZO, μₛₐₜ=62.5 cm² V⁻¹ S⁻¹ for InOₓ). The slight difference is attributed to the exacerbation of trap states under high source-drain voltages, which suppresses carrier concentration in the saturation regime and saturation mobility.^{12, 14, 15} This is also consistent with the origin of the apparent NDR phenomenon observed in the output characteristics of the IZO and InOₓ transistors.

SUPPLEMENTARY TABLE 1
Electrical resistance of ITO films prepared under different light
irradiation conditions. Thermal annealing was performed at 350° C.

| Resistance | | | | Resistance |
|---|---|---|---|---|
| after thermal | Light | Light | | after light |
| annealing | wavelength | intensity | Irradiation | irradiation |
| (kΩ) | (nm) | (W/mm²) | time (min) | (kΩ) |
| 15.0 | 800 | 50 | 1 | 14.9 |
| 15.0 | 800 | 70 | 1 | 15.0 |
| 15.0 | 800 | 89 | 1 | 14.8 |
| 15.0 | 800 | 108 | 1 | 14.9 |
| 15.0 | 800 | 127 | 1 | 14.92 |
| 15.0 | 800 + 400 | 50 | 1 | 13.4 |
| 15.0 | 800 + 400 | 70 | 1 | 13.6 |
| 15.0 | 800 + 400 | 89 | 1 | 13.2 |
| 15.0 | 800 + 400 | 108 | 1 | 11.3 |
| 15.0 | 800 + 400 | 127 | 1 | 10.8 |
| 15.0 | 800 | 50 | 5 | 14.9 |
| 15.0 | 800 | 70 | 5 | 14.6 |
| 15.0 | 800 | 89 | 5 | 14.8 |
| 15.0 | 800 | 108 | 5 | 14.7 |
| 15.0 | 800 | 127 | 5 | 14.9 |
| 15.0 | 800 + 400 | 50 | 5 | 12.5 |
| 15.0 | 800 + 400 | 70 | 5 | 10.8 |
| 15.0 | 800 + 400 | 89 | 5 | 10.1 |
| 15.0 | 800 + 400 | 108 | 5 | 9.2 |
| 15.0 | 800 + 400 | 127 | 5 | 7.6 |

SUPPLEMENTARY TABLE 2
Performance metrics for transistors based
on plasmonically printed IGZO, IZO, InOₓ.

| MO | T(° C.) | μₛₐₜ(cm²/Vs) | Vₜₕ(V) | Vₒₙ(V) | Iₒₙ/I_{off} | Time | |
|---|---|---|---|---|---|---|---|
| IGZO | 350 | 17.7 ± 1.2 | 0.07 ± 0.1 | 0.2 ± 0.02 | ~10³ | 1 | h |
| IGZO | RT | 21.0 ± 3.2 | 2.2 ± 0.4 | 2.2 ± 0.5 | ~10⁴ | <0.3 | s |
| IZO | RT | 19.2 ± 2.6 | 2.3 ± 0.3 | 1.8 ± 0.4 | ~10⁴ | <0.3 | s |
| InOₓ | RT | 62.5 ± 8.1 | 3.4 ± 0.9 | −0.1 ± 0.05 | ~10³ | <0.3 | s |

Average of at least 10 devices.

### EXAMPLE ADVANTAGES OF SOME EMBODIMENTS

Unlike silicon electronics using capital-intensive vacuum-based processing technologies, solution processability of MO thin films offers great possibilities in high-throughput, low-cost and large-scale printing. However, the challenge of printing high-quality MO lies in the fact of long-term and high-temperature annealing (>400° C.), which is not suitable for efficient, continuous additive manufacture. The high-temperature processing route also results in the difficulty of patterning MO into high-channel-count transistor arrays. Compared with conventional processes and other low-temperature solution processes of MO, the proposed plasmonic printing process offers three significant advantages. First, the entire process is conducted under room temperature and ambient conditions, eliminating the need for special gases or high-temperature treatments. Second, the MO precursor film can be locally transformed into high-quality MO thin film within an extremely short duration of intensive thermal and optical exposure (typically within 0.3 seconds), significantly improving the fabrication efficiency compared to slow vacuum deposition or prolonged high-temperature annealing. Meanwhile, all the printed MO thin films exhibit superior electrical performance comparable to those produced using a vacuum-based process. Third, this process demonstrates strong capabilities for pattern control to achieve three different high-precision printing methods for MO thin films.

The current fabrication technology for commercial metal oxide electronics primarily relies on large-scale vacuum-based processes such as magnetron sputtering. These techniques are costly due to the expensive high-quality target materials and large equipment required. Additionally, the high-precision patterning steps for metal oxides are complex and challenging, further increasing the production cost of metal oxide electronics. Some embodiments of the invention present a novel pathway for achieving cost-effective and high-throughput printing of high-density, complex, multilayered solution-processed all-MO thin-film electronics, delivering performance on par with vacuum-based counterparts. It can reduce the production cost of metal oxide electronics.

### REFERENCES

All referenced literatures throughout this disclosure are incorporated herein by reference in their entirety, which include the following references:

### 1. References for the Main Description

1. Yu, X., Marks, T. J. & Facchetti, A. Metal oxides for optoelectronic applications. Nat. Mater. 15, 383-396 (2016).
2. Kim, T. et al. Progress, challenges, and opportunities in oxide semiconductor devices: a key building block for applications ranging from display backplanes to 3D integrated semiconductor chips. Adv. Mater. 35, e2204663 (2023).
3. Hosono, H. & Kumomi, H. Amorphous Oxide Semiconductors: IGZO and Related Materials for Display and Memory (John Wiley & Sons, 2022).
4. Wang, B. et al. Flexible and stretchable metal oxide nanofiber networks for multimodal and monolithically integrated wearable electronics. Nat. Commun. 11, 2405 (2020).
5. Zheng, D. et al. Combustion synthesized zinc oxide electrontransport layers for efficient and stable perovskite solar cells. Adv. Funct. Mater. 29, 1900265 (2019).
6. Biggs, J. et al. A natively flexible 32-bit Arm microprocessor. Nature 595, 532-536 (2021).
7. Park, J. W., Kang, B. H. & Kim, H. J. A review of low-temperature solution-processed metal oxide thin-film transistors for flexible electronics. Adv. Funct. Mater. 30, 1904632 (2019).
8. Wang, B. et al. Expeditious, scalable solution growth of metal oxide films by combustion blade coating for flexible electronics. Proc. Natl Acad. Sci. USA 116, 9230-9238 (2019).
9. Banger, K. K. et al. Low-temperature, high-performance solution-processed metal oxide thin-film transistors formed by a ‘sol-gel on chip’ process. Nat. Mater. 10, 45-50 (2011).
10. Kim, M. G., Kanatzidis, M. G., Facchetti, A. & Marks, T. J. Low-temperature fabrication of high-performance metal oxide thin-film electronics via combustion processing. Nat. Mater. 10, 382-388 (2011).
11. Kim, Y. H. et al. Flexible metal-oxide devices made by room-temperature photochemical activation of sol-gel films. Nature 489, 128-132 (2012).
12. Yu, X. et al. Spray-combustion synthesis: efficient solution route to high-performance oxide transistors. Proc. Natl Acad. Sci. USA 112, 3217-3222 (2015).
13. Datta, R. S. et al. Flexible two-dimensional indium tin oxide fabricated using a liquid metal printing technique. Nat. Electron. 3, 51-58 (2020).
14. Teng, L.-F., Liu, P.-T., Lo, Y.-J. & Lee, Y.-J. Effects of microwave annealing on electrical enhancement of amorphous oxide semiconductor thin film transistor. Appl. Phys. Lett. 101, 132901 (2012).
15. Ji, K. H. et al. Effect of high-pressure oxygen annealing on negative bias illumination stress-induced instability of InGaZnO thin film transistors. Appl. Phys. Lett. 98, 103509 (2011).
16. Nakata, M. et al. Improvement of InGaZnO4 thin film transistors characteristics utilizing excimer laser annealing. Appl. Phys. Express 2, 021102 (2009).
17. Chen, H., Rim, Y. S., Jiang, C. & Yang, Y. Low-impurity high-performance solution-processed metal oxide semiconductors via a facile redox reaction. Chem. Mater. 27, 4713-4718 (2015).
18. Scheideler, W. J., Kumar, R., Zeumault, A. R. & Subramanian, V. Low-temperature-processed printed metal oxide transistors based on pure aqueous inks. Adv. Funct. Mater. 27, 1606062 (2017).
19. Park, J. & Moon, J. Control of colloidal particle deposit patterns within picoliter droplets ejected by ink-jet printing. Langmuir 22, 3506-3513 (2006).
20. Kong, M. et al. Ambient printing of native oxides for ultrathin transparent flexible circuit boards. Science 385, 731-737 (2024).
21. Lin, L. et al. In situ nanojoining of Y- and T-shaped silver nanowires structures using femtosecond laser radiation. Nanotechnology 27, 125201 (2016).
22. Huang, H., Sivayoganathan, M., Duley, W. & Zhou, Y. High integrity interconnection of silver submicron/nanoparticles on silicon wafer by femtosecond laser irradiation. Nanotechnology 26, 025303 (2014).
23. Rim, Y. S., Lim, H. S. & Kim, H. J. Low-temperature metal-oxide thin-film transistors formed by directly photopatternable and combustible solution synthesis. ACS Appl. Mater. Interfaces 5, 3565-3571 (2013).
24. Huang, W. et al. Ultraviolet light-densified oxide-organic self-assembled dielectrics: processing thin-film transistors at room temperature. ACS Appl. Mater. Interfaces 13, 3445-3453 (2021).
25. Park, S. et al. In-depth studies on rapid photochemical activation of various sol-gel metal oxide films for flexible transparent electronics. Adv. Funct. Mater. 25, 2807-2815 (2015).
26. Tue, P. T., Inoue, S., Takamura, Y. & Shimoda, T. Combustion synthesized indium-tin-oxide (ITO) thin film for source/drain electrodes in all solution-processed oxide thin-film transistors. Appl. Phys. A 122, 623 (2016).
27. Sunde, T. O. L. et al. Transparent and conducting ITO thin films by spin coating of an aqueous precursor solution. J. Mater. Chem. 22, 15740-15749 (2012).
28. Lee, J. et al. A facile solution-phase approach to transparent and conducting ITO nanocrystal assemblies. J. Am. Chem. Soc. 134, 13410-13414 (2012).
29. Wang, B. et al. Solution-processed all-oxide transparent high-performance transistors fabricated by spray-combustion synthesis. Adv. Electron. Mater. 2, 1500427 (2016).
30. Song, L., Schenk, T., Defay, E. & Glinsek, S. Highly conductive low-temperature combustion-derived transparent indium tin oxide thin film. Mater. Adv. 2, 700-705 (2021).
31. Ruan, C. et al. Lightwave irradiation-assisted low-temperature solution synthesis of indium-tin-oxide transparent conductive films. Ceram. Int. 48, 12317-12323 (2022).
32. Wong, F., Fung, M., Tong, S., Lee, C. & Lee, S. Flexible organic light-emitting device based on magnetron sputtered indium-tin-oxide on plastic substrate. Thin Solid Films 466, 225-230 (2004).
33. Lin, Y.-C., Li, J. & Yen, W. Low temperature ITO thin film deposition on PES substrate using pulse magnetron sputtering. Appl. Surf. Sci. 254, 3262-3268 (2008).
34. David, C., Tinkham, B., Prunici, P. & Panckow, A. Highly conductive and transparent ITO films deposited at low temperatures by pulsed d.c. magnetron sputtering from ceramic and metallic rotary targets. Surf. Coat. Technol. 314, 113-117 (2017).
35. Nayak, P. K., Hedhili, M. N., Cha, D. & Alshareef, H. N. High performance In2O3 thin film transistors using chemically derived aluminum oxide dielectric. Appl. Phys. Lett. 103, 033518 (2013).
36. Branquinho, R. et al. Aqueous combustion synthesis of aluminum oxide thin films and application as gate dielectric in GZTO solution-based TFTs. ACS Appl. Mater. Interfaces 6, 19592-19599 (2014).
37. Jo, J.-W. et al. Highly stable and imperceptible electronics utilizing photoactivated heterogeneous sol-gel metal-oxide dielectrics and semiconductors. Adv. Mater. 27, 1182-1188 (2015).
38. Avis, C. & Jang, J. High-performance solution processed oxide TFT with aluminum oxide gate dielectric fabricated by a sol-gel method. J. Mater. Chem. 21, 10649-10652 (2011).
39. Xu, W., Wang, H., Ye, L. & Xu, J. The role of solution-processed high-K gate dielectrics in electrical performance of oxide thin-film transistors. J. Mater. Chem. C 2, 5389-5396 (2014).
40. Xu, W. et al. Fully solution-processed metal oxide thin-film transistors via a low-temperature aqueous route. Ceram. Int. 43, 6130-6137 (2017).
41. Carlos, E. et al. Printed, highly stable metal oxide thin-film transistors with ultra-thin high-K oxide dielectric. Adv. Electron. Mater. 6, 1901071 (2020).
42. Huh, J.-E. et al. Effects of process variables on aqueous-based AlOx insulators for high-performance solution-processed oxide thin-film transistors. J. Ind. Eng. Chem. 68, 117-123 (2018).
43. Carlos, E. et al. Laser induced ultrafast combustion synthesis of solution-based AlOx for thin film transistors. J. Mater. Chem. C 8, 6176-6184 (2020).
44. Mu, Q. et al. A low-temperature solution-process high-k dielectric for high-performance flexible organic field-effect transistors. Front. Mater. 7, 570002 (2020).
45. Kumar, A. et al. Low-temperature solution-processed high-capacitance AlOx dielectrics for low-voltage carbon-based transistors. Org. Electron. 110, 106636 (2022).
46. Groner, M., Fabreguette, F., Elam, J. & George, S. Low-temperature Al2O3 atomic layer deposition. Chem. Mater. 16, 639-645 (2004).
47. Voigt, M. & Sokolowski, M. Electrical properties of thin rf sputtered aluminum oxide films. Mater. Sci. Eng. B 109, 99-103 (2004).
48. Liang, L. Y. et al. Substrate biasing effect on the physical properties of reactive RF-magnetron-sputtered aluminum oxide dielectric films on ITO glasses. ACS Appl. Mater. Interfaces 6, 2255-2261 (2014).
49. Heo, J. S. et al. Water-mediated photochemical treatments for low-temperature passivation of metal-oxide thin-film transistors. ACS Appl. Mater. Interfaces 8, 10403-10412 (2016).
50. Wang, H. et al. Low-temperature facile solution-processed gate dielectric for combustion derived oxide thin film transistors. RSC Adv. 4, 54729-54739 (2014).
51. Bhalerao, S. R., Lupo, D. & Berger, P. R. Flexible thin film transistor (TFT) and circuits for Internet of Things (IoT) based on solution processed indium gallium zinc oxide (IGZO). In 2021 IEEE International Flexible Electronics Technology Conference (IFETC) 0023-0025 (IEEE, 2021).
52. Kim, K. T. et al. An ultra-flexible solution-processed metal-oxide/carbon nanotube complementary circuit amplifier with highly reliable electrical and mechanical stability. Adv. Electron. Mater. 6, 1900845 (2020).
53. Xu, W. et al. Low temperature solution-processed IGZO thin-film transistors. Appl. Surf. Sci. 455, 554-560 (2018).
54. Jo, J.-W. et al. High-speed and low-temperature atmospheric photo-annealing of large-area solution-processed IGZO thin-film transistors by using programmable pulsed operation of xenon flash lamp. J. Korean Phys. Soc. 74, 1052-1058 (2019).
55. Jo, J.-W., Kim, K.-T., Facchetti, A., Kim, M.-G. & Park, S. K. High-quality solution-processed metal-oxide gate dielectrics realized with a photo-activated metal-oxide nanocluster precursor. IEEE Electron Dev. Lett. 39, 1668-1671 (2018).
56. Carlos, E. et al. Boosting electrical performance of high-κ nanomultilayer dielectrics and electronic devices by combining solution combustion synthesis and UV irradiation. ACS Appl. Mater. interfaces 9, 40428-40437 (2017).
57. Zheng, Z. et al. All-sputtered, flexible, bottom-gate IGZO/Al2O3bi-layer thin film transistors on PEN fabricated by a fully room temperature process. J. Mater. Chem. C 5, 7043-7050 (2017).
58. Ning, H. et al. Room-temperature fabrication of high-performance amorphous In—Ga—Zn—O/Al2O3 thin-film transistors on ultrasmooth and clear nanopaper. ACS Appl. Mater. Interfaces 9, 27792-27800 (2017).
59. Ning, H. et al. Facile room temperature routes to improve performance of IGZO thin-film transistors by an ultrathin Al2O3 passivation layer. IEEE Trans. Electron Dev. 65, 537-541 (2018).
60. Gao, Z. et al. Room-temperature-processed transparent hemispherical optoelectronic array for electronic eyes. Mater. Today 69, 31-40 (2023).

### 2. References for the Supplementary Information

1. Y. H. Kim et al., Flexible metal-oxide devices made by room-temperature photochemical activation of sol-gel films. Nature 489, 128-132 (2012).
2. W. Huang et al., Ultraviolet Light-Densified Oxide-Organic Self-Assembled Dielectrics: Processing Thin-Film Transistors at Room Temperature. ACS Appl. Mater. Interfaces 13, 3445-3453 (2021).
3. Y. S. Rim, H. S. Lim, H. J. Kim, Low-temperature metal-oxide thin-film transistors formed by directly photopatternable and combustible solution synthesis. Appl. Mater. Interfaces 5, 3565-3571 (2013).
4. C. Chen et al., Solution-processed metal oxide arrays using femtosecond laser ablation and annealing for thin-film transistors. J. Mater. Chem. C 5, 9273-9280 (2017).
5. S. Dellis et al., Rapid laser-induced photochemical conversion of sol-gel precursors to In 2 O 3 layers and their application in thin-film transistors. J. Mater. Chem. C 5, 3673-3677 (2017).
6. A. Queralto et al., Ultrafast epitaxial growth kinetics in functional oxide thin films grown by pulsed laser annealing of chemical solutions. Chem. Mater. 28, 6136-6145 (2016).
7. Y.-H. Yang, S. S. Yang, K.-S. Chou, Characteristic enhancement of solution processed In—Ga—Zn oxide thin-film transistors by laser annealing. IEEE Electron Dev. Lett. 31, 969-971 (2010).
8. É. Boulais, R. Lachaine, M. Meunier, Plasma mediated off-resonance plasmonic enhanced ultrafast laser-induced nanocavitation. Nano Lett. 12, 4763-4769 (2012).
9. G. Baffou, H. Rigneault, Femtosecond-pulsed optical heating of gold nanoparticles. Phys. Rev. B 84, 035415 (2011).
10. S. Song et al., Photothermal Lithography for Realizing a Stretchable Multilayer Electronic Circuit Using a Laser. ACS nano 17, 21443-21454 (2023).
11. Zhuang, X. et al. High-performance and low-power source-gated transistors enabled by a solution-processed metal oxide homojunction. Proc Natl Acad Sci USA 120, e2216672120 (2023).
12. Seo, J.-S. et al. Solution-processed flexible fluorine-doped indium zinc oxide thin-film transistors fabricated on plastic film at low temperature. Sci. Rep. 3, 1-9 (2013).
13. X. Zhuang et al., Frequency-Agile Low-Temperature Solution-Processed Alumina Dielectrics for Inorganic and Organic Electronics Enhanced by Fluoride Doping. J. Am. Chem. Soc. 142, 12440-12452 (2020).
14. Chung, D. S. et al. Low voltage, hysteresis free, and high mobility transistors from all-inorganic colloidal nanocrystals. Nano Lett. 12, 1813-1820 (2012).
15. Kim, H.-S. et al. Density of states-based design of metal oxide thin-film transistors for high mobility and superior photostability. ACS Appl. Mater. Interfaces 4, 5416-5421 (2012).
16. N. Koslowski, S. Sanctis, R. C. Hoffmann, M. Bruns, J. J. Schneider, Synthesis, dielectric properties and application in a thin film transistor device of amorphous aluminum oxide Al x O y using a molecular based precursor route. J Mater. Chem. C7, 1048-1056 (2019).
17. N. Koslowski, V. Trouillet, J. J. Schneider, Solution-processed amorphous yttrium aluminium oxide YAl x O y and aluminum oxide Al x O y, and their functional dielectric properties and performance in thin-film transistors. J Mater. Chem. C 8, 8521-8530 (2020).
18. W. Cai, H. Li, Z. Zang, One-volt, solution-processed InZnO thin-film transistors. IEEE Electron Device Letters 42, 525-528 (2021).
19. A. Mancinelli, S. Bolat, J. Kim, Y. E. Romanyuk, D. Briand, Deep-UVEnhanced Approach for Low-Temperature Solution Processing of IZO Transistors with High-k ALO x/YAIO x Dielectric. ACS Appl. Electron. Mater. 2, 3141-3151 (2020).
20. J.-S. Seo et al., Solution-processed flexible fluorine-doped indium zinc oxide thin-film transistors fabricated on plastic film at low temperature. Sci. Rep. 3, 1-9 (2013).
21. W. Cai, H. Li, M. Li, Z. Zang, Performance enhancement of solution-processed InZnO thin-film transistors by Al doping and surface passivation. J. Semicond. 43, 034102 (2022).
22. K. Banger et al., Low-temperature, high-performance solution-processed metal oxide thin-film transistors formed by a ‘sol-gel on chip’ process. Nat. Mater. 10, 45-50 (2011).
23. W. Lim et al., Indium zinc oxide thin films deposited by sputtering at room temperature. Appl. Surf. Sci. 254, 2878-2881 (2008).
24. S. M. Kim, H.-W. Choi, K.-H. Kim, S.-J. Park, H.-H. Yoon, Preparation of ITO and IZO thin films by using the facing targets sputtering (FTS) method. J. Korean Phys. Soc. 55, 1996-2001 (2009).
25. E. Carlos et al., Printed, highly stable metal oxide thin-film transistors with ultra-thin high-κ oxide dielectric. Adv. Electron. Mater. 6, 1901071 (2020).
26. Y. Liang et al., Direct electrohydrodynamic patterning of high-performance all metal oxide thin-film electronics. ACS nano 13, 13957-13964 (2019).
27. J. S. Heo et al., Suppression of interfacial disorders in solution-processed metal oxide thin-film transistors by Mg doping. ACS Appl. Mater & interfaces 11, 48054-48061 (2019).
28. S. R. Bhalerao, D. Lupo, P. R. Berger, Flexible, solution-processed, indium oxide (In2O3) thin film transistors (TFT) and circuits for internet-of-things (IoT). Mater. Sci. Semicond. Processing 139, 106354 (2022).
29. E. Yarali et al., Low-voltage heterojunction metal oxide transistors via rapid photonic processing. Adv. Electron. Mater. 6, 2000028 (2020).
30. P. He et al., Enhanced stability and mobility of solution-processed oxide thinfilm transistors with bilayer terbium-incorporated indium oxide channel. Appl. Phys. Lett. 121, (2022).
31. S.-P. Jeon, J. S. Heo, I. Kim, Y.-H. Kim, S. K. Park, Enhanced interfacial integrity of amorphous oxide thin-film transistors by elemental diffusion of ternary oxide semiconductors. ACS Appl. Mater. & Interfaces 12, 57996-58004 (2020).
32. W. Xu et al., Fully solution-processed metal oxide thin-film transistors via a low-temperature aqueous route. Ceram. Int. 43, 6130-6137 (2017).
33. M. G. Kim, M. G. Kanatzidis, A. Facchetti, T. J. Marks, Low-temperature fabrication of high-performance metal oxide thin-film electronics via combustion processing. Nat. Mater. 10, 382-388 (2011).
34. J. H. Noh et al., Indium oxide thin-film transistors fabricated by RF sputtering at room temperature. IEEE Electron Dev. Lett. 31, 567-569 (2010).

1. A method for fabricating a metal oxide (MO) thin film for an electronic device, comprising the steps of:
providing a plasmonic material on a metal oxide (MO) precursor film; and
illuminating the plasmonic material with a laser source to convert the underlying MO precursor film to an MO film.

2. The method of claim 1, wherein the plasmonic material comprises plasmonic nanostructures, preferably silver nanostructures, or more preferably silver nanowires.

3. The method of claim 1, wherein the MO film comprises a conductor, an insulator or a semiconductor.

4. The method of claim 1, wherein the MO film comprises indium tin oxide (ITO), alumina (AlOₓ), indium-gallium-zinc oxide (IGZO), indium-zinc oxide (IZO), or indium oxide (InOₓ).

5. The method of claim 1, wherein the step of illuminating the plasmonic material is conducted under room temperature and ambient conditions.

6. The method of claim 1, wherein the laser source comprises a femtosecond (fs) laser.

7. The method of claim 6, wherein the laser source provides a mixed laser beam.

8. The method of claim 7, wherein the mixed laser beam comprises 800 nm+400 nm fs laser beam.

9. The method of claim 1, wherein the step of illuminating the plasmonic material comprises manipulating size and displacement of laser spot to control size and shape of the MO film.

10. The method of claim 1, wherein the step of providing the plasmonic material on the MO precursor film is conducted by spray coating.

11. The method of claim 1, further comprising, before the step of providing the plasmonic material on the MO precursor film,
patterning the MO precursor film.

12. The method of claim 1, further comprising, before the step of illuminating the plasmonic material,
patterning the plasmonic material to manipulate pattern of the MO film.

13. The method of claim 1, wherein electrical performance of the MO film is adjusted based on one or more of laser source type, wavelength of the laser source, intensity of the laser source, laser scanning step length, spot dwell time per step, and/or thickness of the plasmonic material.

14. The method of claim 13, wherein the electrical performance of the MO film comprises conductivity, dielectric property, or semiconducting performance.

15. An electronic device, comprising:
one or more thin films of a metal oxide (MO) fabricated by the method of claim 1.

16. The electronic device of claim 15, wherein the electronic device comprises an MO thin film transistor (TFT).

17. A method for fabricating metal oxide (MO) thin film transistor (TFT) arrays, comprising the steps of:
(a) fabricating indium tin oxide (ITO) gate array;
(b) fabricating dielectric layers of alumina (AlOₓ); and
(c) fabricating semiconductor layers of indium-gallium-zinc oxide (IGZO) to provide IGZO based TFTs,
wherein each step (a), (b) and/or (c) is conducted by the method of claim 1.
